(19) United States
(12) Patent Application Publication
(10) Pub. No.: US 2010/0307798 A1
(43) Pub. Date: Dec. 9, 2010

(54) UNIFIED SCALABLE HIGH SPEED INTERCONNECTS TECHNOLOGIES

(76) Inventor: Jamal S. Izadian, San Jose, CA (US)

Correspondence Address: MAXVALUEIP CONSULTING, 11204 ALBERMYRTLE ROAD, POTOMAC, MD, 20854, US

(21) Appl. No.: 12/477,853

(22) Filed: Jun. 3, 2009

(51) Int. Cl. H05K 1/03

(52) U.S. Cl. 174/255

(57) ABSTRACT

Traditional High Speed Electronic Systems Interconnect experience several bandwidth bottlenecks along the multiplicity of signal paths that limits the information throughput. Here we build upon the cellular interconnect concept of PMTL, the Periodic Micro Transmission Line which was introduced in an earlier patent application, and provide a new type of transmission line VMPL, as the Vertical Micro Transmission Line approach to make all the elements of a high speed interconnect wideband, unified, scalable, and practical for high volume manufacturing. This provides total connectivity improvements from end-to-end of electronic systems that demands higher bandwidth, and increased information throughput, thermal management, and impeccable signal integrity. The technologies introduced here provide solutions for any level of the fan out from chips to systems, in CMOS, or Packages, and PCB's.

### INTRODUCTION

### A Review of Prior Art

The objective of carrying signal from one point to another on an electronic system requires a unified approach to the wiring and interconnect. One of the ways that this goal has been achieved between electronic systems separated by large distances has been through twisted pair copper wires, or indeed what has been used since the days of the POTS and Alexander Graham Bell. Although many variations and evolutions has been implemented, the basic technique and the premise stays the same, new innovations merely have tried to package them differently or bundle them as the one cited by U.S. Pat. No. 5,883,334, Newmoyer et al., who discloses a new bundling scheme to try to pack more twisted pairs into the cable. Yet, in another, U.S. Pat. No. 7,449,638 B2, the objective of providing better isolation between quad twisted pairs is addressed, to attempt to limit the intra-interference between the differential twisted pairs of the same cable. Further attempts to change the relative topologies and bundling configurations are also presented. (All with attempt of providing more lanes per bundled cable.) The aforementioned patents concentrated on the old fashioned technology of UTP (Unshielded Twisted Pairs), cabling which use the tradition extrusion manufacturing process, but with means to provide similar functionalities on printed circuit boards. For example, Gandarud in U.S. Pat. No. 3,761,842, discloses a printed circuit version of a twisted pair by crisscrossing that attempts to achieve the twisting of the differential transmission lines with cross over sections that are compensated electronically to achieve continuity in the line. This disclosure however achieves more of zig-zagging rather than twisting.

In yet another U.S. Pat. No. 5,036,160, Jackson, presents another method of achieving twisting of printed transmission line strips. In this embodiment, the twisting is achieved by strategic arrangement of top and bottom strips and a series of PTH (Plated Through Holes) via holes that achieves the moving of currents from one strip to another, a method similar to flip-flopping of current flow direction.

Additionally, Muyshondt et al., in U.S. Pat. No. 5,646,368, employ a similar technique to achieve the twisting of currents, whereby they use strips and via up and down for achieving a forward twisting, but provide some ground guard rails for better isolation. Although the two previously mentioned patents provide twisting through means of a multi-layer PCB, In U.S. Pat. No. 7,061,771 B2, Miller provides a means of crossing over edge couple differential pairs in the same layer, but with a cross-over mechanism that allows impedance matching and parasitic reduction. It is clear from these inventions that provision of twisting of currents in differential pairs is very key in the ability to provide alien interference rejection in the communication systems. This type of interference or cross-talk can be equalized on the two lines by the proper twisting on the lines, and since the differential lines terminate in a 180-degree hybrid that inverts one line, and adds them, the results is the desired differential mode providing twice the energy, while the interference energy on the common mode subtract out completely, and the more these lines' interference is equalized, the more noise cancellation can be achieved, and thus, demonstrating the need for the critical use of twisted pairs to improve signal to noise ratio S/N.

In addition to twisting, shielding can also help achieve avoid excessive interference. For example, this is the drive behind the movement from CAT 5, to CAT 6 and 7 cabling, in the Ethernet interconnects, as the former is UTP (Unshielded Twisted Pairs), and the latter is in the processing to provide STP (Shielded Twisted Pairs) cabling, now being required for 10GBase-T and other higher speed Ethernet technologies. Although there are many ways to achieve shielding in traditional extruded cables, as was mentioned previously, there is a need to implement differential Pairs with shielding on printed circuit boards. A published patent application US 2008/0230252, by Cheng, provides one possible way of producing shielded twisted pairs transmission lines using printed circuit technology. The essence of this invention is generally the shielding effectively provided by side-by-side strip line differential pairs from each other, by providing a set of grounding guards in between. The shielding of the twisted pairs is highly desirable to avoid the coupling of external noise to the desired signals. As the speed of transmission moves from a few 100's of bps to 100's of Gbps, in the Ethernet networks and advanced routers to support the new systems, the need for these innovations become much more critical.

For example, one of the most critical elements of Internet-based world of today is the working around the clocks of many computer nodes and millions of routers everywhere. As the appetite for more content connectivity continues to climb, the demand for higher speed and throughput follows, and puts a huge burden on the router system, architecture, topology, and internal designs and technology, and specifically, on the Backplanes and cards and connectors to perform at higher and higher data rates. A typical router today, performs routing of terabits of information from many dozen of line cards running at many 10's Gigabits per seconds. Indicating that these speed and throughputs will increase multiple 10 times in the not too far future.

One of the major bottlenecks in the backplanes of high speed routers is the old fashioned microstrip and stripline transmission lines dominant in the internal circuitry of these systems. These old technologies are facing new challenges. D'Agotino (in U.S. Pat. No. 6,227,897 B1) provides a good summary of challenges from a mechanical interfacing point of views for these backplanes. Mills et al. provide further innovations for connecting a multiplicity of line cards to a backplanes, and in U.S. Pat. No. 7,088,711 B2, Goregen et al., provide an extensive embodiment of signal paths through the backplane and from Line cards to switch fabric and then to other line cards, showing several typical and critical differential pairs paths, and providing means of interconnecting them in various layers, and between layers using some suggested arrangement of dual PTH signal and PTH ground reference in the stack. This patent addresses many problems and issues that need to be addressed in the move towards a multi-Gigabit backplanes. This invention, however, remains in the realm of edge coupled differential pairs like Stripline type. But, clearly, it points out the need for further innovation to move to new frontiers and new types of transmission lines, such as the PMTL that is further introduced in the current disclosure.

It is obvious from these patents and many more not cited here that Backplane data routing on copper is hitting a limit, and there is some movement toward going completely optical on the backplane. But that will have its own problems. One such an optical backplane technology is disclosed by Glebov et al. in U.S. Pat. No. 7,418,165 B2, as an optical routing backplane technology. But, optical components are very expensive, and high precision, and it will require many years of development before it reaches a level of maturity at which copper has reached. So, it is much more preferable to squeeze more performance out of copper backplanes, rather than going to optical backplanes at near future.

In the present invention disclosure, we provide a unified end to end copper interconnect solution to this problem, to achieve higher speed backplanes connectivity of an array of line cards and daughter boards, and an array of switch fabric cards. To achieve this flawlessly, we require impeccable board to board connectors with the same level of signal integrity performance as the signals in any of the module boards and backplanes. After all, the system will be only as good as the weakest link, or connection with lowest signal integrity. So, many innovations in the connector technology and sockets and interface cards are needed. Traditionally, connectors have been based on male and female type pins and sockets, and those are hitting a bandwidth limit, but there are some innovations that are taking place, and more will be coming. Amano et al., in U.S. Pat. No. 4,568,133 provide one possible connector mechanism, and Stragne et al., in U.S. Pat. No. 6,062,872 provide another type of bus connector module that uses a membrane bus to provide connectivity between a mother board and daughter board with potential for high speed performance, but the membrane technology is the limiting bottleneck. Yet, in U.S. Pat. No. 6,582,255 B2, Simmons et al., provide another type of plug and receptacle assembly that can be used for connecting twisted Pairs that provide some level of shielding. And finally, Harris et al., in US 2006/0061959A1 provide a system of multi-gigabit connector that attempts to mitigate some of these issues. In all of these inventions, the urgent need for signal improvement at all levels and all stages of system hierarchy and development is evident with some partial solutions in each, but in this invention, we consider the signal from end to end and provide an integrated unified and scalable total solution system to connectivity to achieve highest signal integrity across the interconnect, for chip, the package, the PCB cards, the daughter board, the motherboard, the backplane, the connector, and of Tx Rx pairs, such as the 10GBase-T twisted pairs for 10's of meters long. All made possible by the embedded PMTL technologies which was introduced in the USPA 2008/0265919A1 by Izadian and introduction of new Vertical Micro Transmission Line (VMTL) using 3D via technologies. The aforementioned patent disclosure application provided total testing connectivity solutions through scalable wideband probes, fixtures, and sockets for high speed IC testing and interconnect, using the embedded PMTL (Periodic Micro-Transmission Lines) technology, here we provide the total interconnect solutions from end to end with high fidelity and signal integrity connectivity using PMTL+VMPT technologies.

Furthermore, some of the urgencies of the backplane design challenges is addressed in the paper by Grisin et al. And the basic elements of multi-gigabit connector are outlined in application note by Tyco, and the standards publications of VPX Draft Standards VITA 46.0-200x. Publication Izadian also outlines the state of the art in the proven measured data of the PMTL transmission lines and compares to microstrip line, stripline, coaxial lines, and micro coaxial lines that helps shed some light on the promise of the PMTL as a platform connectivity solutions for 100 Gbps of the future, and improvements of the current systems and infrastructures and routers.

In addition, some review articles about the background for our technology are:
“Design Advances in PCB/Backplane Interconnects for the Propagation of High Speed Gb/s Digital Signals”, Frans Guisin, Zorica Pantic-Tanner, Microwave Review, September 2003, pp 11-18
“Multi-Gig RT Signal Connector, Application Specification 114-1305, 4 Apr. 2008, Rev C. Tyco Electronic Report.
“VPX Draft Standard VITA 46.0-200X, Draft 0.16 21 Feb. 2006, VITA standards organization, Foutina Hills, Ariz. 85269.
PMTL™ A new Transmission line for High Speed digital Circuits, J. S. Izadian. Microwave Journal, Nov. 30, 2008.
Multi-Gig RT-2 Connector Routing, Report #22GC009-1, Mar. 26, 2003 v1.0, Tyco Electronic Report.
Izadian, “Microwave Transition Design”, book published by Arteck House, 1988.
“Design Considerations of Differential Inductors in CMOS Technology”, H. Y. D. Yang, Dept. ECE, University of Illinois, Chicago.

### BACKGROUND

One of the greatest impediments to increasing the information throughput in modern networked electronics systems is the limitation of bandwidth of the weakest link in the interconnect chain. A viable end to end interconnect philosophy solution enables the use of full bandwidth of the interconnect system and removing the limiting bottlenecks, such as connectors and via structures in all levels of die to system fan out. This present unified and systematic approach provides possibilities for many improved interconnect products, including, cabling, backplane, Sockets, connectors, packaging, PCB, and MCM, SiP, PoP, and subsystems, and systems.

### SUMMARY

The invention, in several embodiments, described here pertains to the field of high speed digital transmission across an array of subsystems. Furthermore, the basic Periodic Micro Coaxial Transmission Line (PMTL) described here can provide Confined Field Interconnection (CFI) between devices in wafer and on a high speed board, thus practically eliminating cross talk and parasitic, and allowing much higher speeds and wider bandwidth. An expansion of the idea of PMTL has been made by introducing of Vertical Micro Transmission Line VMTL using a array of 3D vias PTH and NPTH to provide true 3d signal flow with highest signal integrity. Throughout this disclosure, PTH refers to Plated Through Hole, and NPTH refer to via holes not plated, and either left empty of filled with air/gases or other materials.

In describing the embodiments of this invention, we use the numbering convention of FIG. number followed by the element number. For example, 7-21, means that element 21 in FIG. 7. This helps keep track of elements in many embodiments introduced in the disclosure. Furthermore, where multiple elements with similar functionality are present in different locations of a FIG. or embodiments, we use the postfix, T, B, L, R, and C, or a combination to indicate, to the Top, Bottom, Left, Right, and Center. For example, 9-11-TR means in FIG. 9, item 11 on the Top Right.

FIG. 1A shows a simple way of describing the interconnects of the electronics systems is a bidirectional signal flow of fanning out, or fanning in, the former being of signal flowing from devices with micron features, progressively to devices and interfaces with mm, and cm, dm, and meters dimensions, this is the fan out, and on the other hand, the signal flow can be from the larger world to the micro scale world. All other combination of signal flow are possible. The ultimate interconnect system provide efficient interconnection in all these possibilities, and one that this disclosure will address.

At the heart of an electronic systems there is usually at least one very small semiconductor chip that has been designed and produced by the well known CMOS process, in most cases. These chips are processed on thin wafers of only a few micron thick, and of diameters approaching 300 mm. Thousand of chips are printed on these wafers and processed, and separated. The patent application Izadian provides clear path for testing connectivity to these devices. But the chip, in order to be useful, must be connected to increasingly larger scale interfaces, for example, the chip in the Micronics scales of interfaces, must then interface with packages or chip carrier.

At one extreme of a fan out, the signal originates from the chip, with micron features and fans out to an interface with mm dimensions, like the package or chip carrier. The chip carrier itself now fans out (Some times called Breakout Region, BOR) the signal to a next dimension features like a PCB of cm dimension. The circuit board, i.e. Daughter board to interface through connectors to a Mother board with dimensions in dm, and the motherboard get integrated into system with multiple racks of metric dimension. All throughout the journey, the signal must maintain its integrity over the entire spectrum of up to 10's of harmonics of the useful frequency and data rate Gbps of signal, and near the inverse of sharpest digital pulse rise or fall time. The journey is long, and the possibilities of signal failure are numerous. This disclosure provides a unified and integrated approach to the modern electronic interconnects to ensure the integrity and safe journey of the signal throughout all the fan out and fan in and any combination thereof the signal(s). The techniques provided here adhere to the current photolithographic PCB and CMOS processing at board level and at the chip level. The objective is to provide technologies that can be readily implemented without any process changes and using the existing manufacturing capabilities.

In achieving this goal, we build upon the PMTL transmission line technology to develop various configuration of low loss and highly confined field transmission lines, of single ended, and differential Pairs, or a combination thereof as was disclosed in Izadian earlier patent application. A new type of TEM transmission line referred to as VMTL Vertical Micro Transmission Line is disclosed here. This technology uses an array of 3D PTH and NPTH vias in the packaging and PCB applications, and Through Silicon vias (TSV) in CMOS and packaging processes to provide high speed signal transmission between vertical layers and together with PMTL provides a unified systems of 3D high signal Integrity transmission line technology.

In developing highly efficient interconnect systems, transmission lines can be developed that act in a manner consistent with the Heaviside condition. A simple interpretation of this condition is the ability to design the transmission line in a way to equalize the R/L<=G/C (R, L, G, and C are the per unit length series Resistance, Inductance, and shunt Conductance, and Capacitances of a unit cell of transmission line which periodically repeat along the PMTL and VMTL) This can be achieved in the process introduced here for the PCB and CMOS transmission lines. Essentially, this translates into two possible objectives, mainly, the conductor thickening, and dielectric thinning. This is consistent with the well known effect of signal loss in transmission lines dominated by conductor loss R/L at low frequencies, and dielectric losses at higher frequencies (G/C). In pursuit of our total interconnect solution, we provide a cellular building block in the form of a smallest unit of PMTL horizontally and VMTL vertically that can be used as building blocks for any interconnectivity devices. In the process of presentation of various embodiments of the invention, it will become clear to one skilled in the art, that any type of interconnect can be developed that can perform to many 100 GHz bandwidth, and that can interface with any other interconnects.

This way, we will show that in addition to high performance transmission lines, we also provide connectors to efficiently connect these PMTL to existing world of interconnects, such as connectors and microstrip, stripline, and coaxial lines. For the purpose of backward compatibility with the existing circuitry and systems, while at the same time providing means to improve the future systems thus providing an evolutional pathway forward to 100's of Tbps systems of the future, on copper.

It is a well-known fact that one of the major impediments to increasing signal speeds on copper transmission lines is the signal loss over frequency which exhibits a low pass filter characteristics. As previously mentioned, there are essentially two main mechanism of signal loss, conductor loss which varies as inverse of square root of frequency, and propagation losses which varies as inverse of frequency. Other secondary losses mechanism such as current bunching also effects losses. The inventions disclosed here provides techniques that help mitigates these losses and provide optimally low loss transmission line media that can be realized on CMOS or PCB, hard or soft, and at every level and hierarchy of fan out and fan in signal flow. A published report by Izadian has shown excellent performance from DC to 50 GHz of samples of several flexible PMTL transmission line in a series of measurements and evaluation data carried out by highly reliable Signal Integrity Laboratories. In addition, extensive Electromagnetic simulation suggests that the technology can work to THz frequencies with current state of the art manufacturing, and with process improvements to ultimately to light frequencies.

Perhaps, the best metal based TEM transmission line is the coaxial line. In a coaxial line, the near perfect TEM mode of propagation allows for low signal loss to great frequencies of nearly 500 GHz, for most practical application. But, the coaxial lines are usually manufactured by extrusion and are not very useful in PCB and COMS scales. The PMTL-VMTL however provides a means to achieve a nearly coaxial line transmission efficiencies but using CMOS or PCB processes, and promises to provide ample possibilities for high volume manufacturing as cables, as well as for interconnect means for PCB and CMOS applications. The original PMTL was covered in the Izadian patent application; here we expand on that idea to disclose a vertical TEM transmission line VMTL to provide high speed inter-layer vertical transmission through a strategic application of an array and topology of vias in the stack thus providing a true 3D unified scalable high speed interconnect system for any level of the interconnect fan out.

In summary, the Traditional High Speed Electronic Systems Interconnect experience several bandwidth bottlenecks along the multiplicity of signal paths that limits the information throughput. Here we build upon the cellular interconnect concept of PMTL, the Periodic Micro Transmission Line which was introduced in an earlier patent application, and provide a new type of transmission line VMPL, as the Vertical Micro Transmission Line approach to make all the elements of a high speed interconnect wideband, unified, scalable, and practical for high volume manufacturing. This provides total connectivity improvements from end-to-end of electronic systems that demands higher bandwidth, and increased information throughput, thermal management, and impeccable signal integrity. This is achieved by providing a viable unit cell of high signal integrity TEM transmission line employing the VTCTD, Virtual Thickening of Conductor and Thinning of Dielectrics, of reducing conductor and dielectric losses for high speed connectivity, and using these PMTL-VMTL unit cells as the building blocks of various interconnect components, such as transmission lines, shielded or unshielded, twisted pairs, single ended, differential pairs, cables bundles connectors arrays, 3D via structures, in a logical, systematic, and incremental manner that allows development of proven design manufacturing and testing techniques. This will revolutionize the backplane, motherboard/daughter board interconnect systems, and provide new possibilities for new higher speed topologies and architectures for routers, computers, servers, switches in the communication infrastructures. The technologies introduced here provide solutions for any level of the fan out from chips to systems, in CMOS, or Packages, and PCB's.

### BRIEF DESCRIPTION OF THE DRAWINGS

FIG. 1A, illustration of generalization of the concept of fan out from a chip scale of few microns, to packages, mm, to daughter board PCB of cm, to back plane of dm, and assembly of meter scales.

FIG. 1B (Prior Art) Basic nomenclature of the PMTL single ended transmission technology, made from four metal layers and three insulator layer, and a set of PTH blind and through PTH via columns and NTPH vias.

FIG. 2A Basic nomenclature of the PMTL Differential transmission technology, made from four metal layers and three insulator layers, and a set of PTH blind and through PTH via columns and NTPH vias.

FIG. 2B, Illustration of a Quadaxial PMTL transmission line constructed with slight variation of FIG. 2A, by not plating some central vias.

FIG. 3 Basic nomenclature of the PMTL Single ended transmission technology, made from three metal layers and two insulator layers, and a set of single central strip and through PTH via columns and NTPH vias.

FIG. 4A Basic nomenclature of the PMTL Differential transmission line technology, made from three metal layers and two insulator layers, and two central differential strips and PTH via columns and NTPH vias.

FIG. 4B Nomenclature of a 2×2 array of PMTL Differential 1 transmission line technology, made from four differential PMTL of FIG. 4A made from five metal layers and four insulator layers.

FIG. 5A Basic nomenclature of the PMTL broadside Differential transmission technology, made from four metal layers and three insulator layers, and a set of PTH and through PTH via columns and NTPH vias.

FIG. 5B Nomenclature of a 2×2 array of broadside PMTL Differential transmission lines of FIG. 5A, each made from four metal layers and three insulator layers, and a set of PTH and through PTH via columns and NTPH vias.

FIG. 6A, Illustration of the Twisted Pair Differential PMTL transmission line, using a zig zag type twisting, useful for equalization of common mode noise and interference for Ethernet cabling. The currents in this case don't change layer, and thus there is no vertical current flow.

FIG. 6B, Illustration of the Twisted Pair Differential PMTL transmission line, using PTH via arrays type twisting, useful for equalization of common mode noise and interference for Ethernet cabling. The currents in this case change layers, and thus provide vertical current flow to provide true current twisting.

FIG. 7A, Three views of cross sections cuts along the twisted pair PMTL differential transmission line of FIG. 6A demonstrating the criss crossing of current at three sectional cuts of AA′, BB′, and CC′ along the transmission line.

FIG. 7B, Three views of cross sectional cuts along the twisted pair PMTL differential transmission line of FIG. 6B demonstrating the true twisting of current flow at three sectional cuts of AA′, BB′, and CC′ along the transmission line.

FIG. 7C, A 2×2 array of the twisted pair PMTL transmission lines of FIG. 6, showing that a printed PMTL UTP (Unshielded Twisted Pairs) or STP (Shielded Twisted Pair) transmission line can be constructed from a seven metal layers and six insulator layers. Any combination of symmetry of asymmetrical topology, or a mix combination of single ended or differential arrays can be developed.

FIG. 7D. Illustration of the current flow convention into and out of the plane of paper for illustration of current flow and twisting in FIGS. 6, and 8.

FIG. 8A, Illustration of an alternative Twisted Pair Differential PMTL transmission line, using a combination of PMTL transmission lines of FIG. 2, FIG. 5, and FIG. 6. and showing the nature of current twisting and cross over sections. PTH via arrays type twisting, useful for equalization of common mode noise and interference for Ethernet cabling. The currents in this case zig zags in the parallel sections and change layers through the cross over areas as illustrated in the cross sectional cuts AA′, BB′, CC′, DD′, EE′, FF′, and GG′, and thus provide twisting current flow, shows also how a cross-over for PMTL can be implemented.

FIG. 8B, A 2×2 array of the twisted pair PMTL transmission lines of FIG. 8A, showing that a printed PMTL UTP (Unshielded Twisted Pairs) or STP (Shielded Twisted Pair) transmission line can be constructed from seven metal layers and six insulator layers. Any combination of symmetry of asymmetrical topology, or a combination of single ended or differential arrays can be developed. This type of PMTL can replace CAT 5, UTP, and CAT 6 and 7 STP Ethernet cables.

FIG. 9A. Illustration of basic modular connector concept for attaching two PMTL sections. This FIG. shows the concept of a Signal Continuity Module (SCM) that provides continuity between the signal layers and ground layers of two PMTL.

FIG. 9B. Illustration of basic modular connector concept for two PMTL sections. This FIG. shows the concept of a Ground Continuity Module (GCM) that provides continuity between the ground layers of two PMTL. The similar concept is used as a Dielectric Continuity Module (DCM).

FIG. 10A. Illustration of basic modular connector concept for two PMTL sections, showing three basic continuity modules, for Signal, Dielectric, and Ground that can be used to construct any connectors for single ended or differential or a combination of PMTL transmission lines.

FIG. 10B. (Exploded view) Illustration of basic modular construction of PMTL connector for a single ended transmission line made by use of various continuity modules, for Signal, Dielectric, and Ground in the order of Ground, Dielectric, Signal, Dielectric, and Ground.

FIG. 10C. 3D view of a basic modular construction of PMTL connector for a single ended transmission line made by use of various continuity modules, in the order of Ground, Dielectric, Signal, Dielectric, and Ground.

FIG. 10D. 3D view of a basic modular construction of PMTL connector for a Differential transmission line made from continuity modules in the order of Ground, Dielectric, Signal 1, Dielectric, Dielectric, Signal 2, Dielectric, and Ground.

FIG. 11A. Illustration of connectivity modules Ground, Dielectric, and Signal, with using PCB fabrication techniques. Each module provides the corresponding connectivity region similar to those of FIGS. 9 and 10A.

FIG. 11B. Illustration of the configuration arrangement of various continuity modules Ground, Dielectric, and Signal, PCB modules of FIG. 11A to construct a single ended PMTL connector (At the left) and differential PMTL connector (At right).

FIG. 11C. A unit of step and repeat for fabrication of a large number of connector using the multilayer PCB process, consisting of various continuity modules Signal, Dielectric, and Ground PCB modules of FIG. 11A.

FIG. 11D. An array of units of step and repeat pattern of FIG. 11C for fabrication of a large number of connector using the multilayer PCB process, consisting of various continuity modules Signal, Dielectric, and Ground PCB modules of FIG. 11A.

FIG. 12A. Illustration of top view of a Single ended PMTL connector module connecting two PMTL single ended transmission lines, and corresponding top view of a differential PMTL connector connecting two Differential PMTL lines, using the connector concept of FIG. 11. The figure also shows corresponding end view.

FIG. 12B. Illustration of top view showing an access channel for connecting to the Signal strips of two Single ended PMTL transmission lines, and also corresponding top view showing access channels for the two signals of a corresponding differential PMTL lines, using the connector signal continuity module concept of FIG. 11. The figure also shows a typical side view of a signal continuity module.

FIG. 13A Various views of one possible embodiment demonstrating the method of interface of a coaxial connector and PMTL transmission Line, showing the cross section of a coaxial probe and its details and the top side, and cross section views of a PMTL with access channels for the Center conductor strips.

FIG. 13B A cross sectional view of one possible assembly of FIG. 13A to demonstrate the method of interface with a coaxial connector and PMTL transmission, Line, showing the cross section of a coaxial probe and its details, and cross section views of a PMTL with access channels for the Center conductor strips, the mechanical notches and holes for snapping into position and holding.

FIG. 13C A top view of one possible assembly of FIG. 13B to demonstrate the method of interface with a coaxial connector and PMTL transmission, Line, showing the details of via hole arrays with PMTL with access channels for the Center conductor strips, the mechanical notches and holes for snapping into position and holding, and coax probe flanges with various extended fingers for ground and dielectric continuity, and mechanical capture.

FIG. 13D A top view of one possible assembly of coaxial probe of FIG. 13C and coaxial probes flange and its various fingers for ground and dielectric continuity.

FIG. 13E Top and cross sectional views of a possible foot print for bringing the center conductor to the surface for easy access for the coaxial probe connection. This can be made possible on both top and bottom of the PMTL by a PTH vias.

FIG. 13F-H, F) Some views of a additional methods of interfacing a Coaxial Probe with PMTL, also showing some possible embodiments for metal tabs and ground tabs to improve continuity and mechanical aspects. G), Additional Approaches for extending the coaxial probe region over the PMTL to improve match, H) a approach for single ended PMTL to Differential PMTL transition and using coaxial probe interface.

FIG. 14A A method for connecting PMTL to top or bottom of a multilayer PCB. To the left, is a rectangular pattern of PTH via holes and pads for shield, and two central via PTH for differential signals, to the right is shown a corresponding via rectangular PTH vias pattern surrounding a central signal PTH via for a single ended PMTL transmission line connection.

FIG. 14B shows the bottom of connector pattern for a differential pairs on left, and single end on right that can be matched with Foot prints of solder bumps of FIG. 14A, to connect to the PMTL ends to surface of a PCB.

FIG. 14C, similar to the FIG. 14B, but with thin grounds module, the metallization on the outer top and bottom serves as ground.

FIG. 14D shows the supper imposing of the solder pads and patterns of FIG. 14A and the foot prints of FIG. 14B, or 14C, and more specifically that of FIG. 12A AA′ cut, to demonstrate how the PCB solder bump patterns can be matched with those of a PMTL connector for connectivity to PCB's with embedded PMTL transmission line technologies.

FIG. 15A Demonstration of construction modules of a PCB top connector socket type, for Ground, Dielectric, and Signal Continuity modules, which is half of the corresponding modules introduced in FIG. 11.

FIG. 15B. The concept of high signal integrity vertical TEM transmission line on a multi layer PCB stack. Showing to the left, a rectangular array of PTH via holes surrounding two central vias PTH for differential signals, Between the shield and signal via, an array of NTPH vias to achieve the PMTL thinning. To the right a corresponding single ended via assembly is also shown.

FIG. 15C. Similar to FIG. 15B, with possible variation of via types, slots instead of circular vias, PTH, and NPTH. (Can also be of slots or other shapes).

FIG. 15D Top view of via pattern similar to that of Single ended 3D via stack of FIGS. 15B and 15C, (right side), demonstrating a circular array of shield PTH vias surrounded a circular array of NTPH vias surrounding a central signal via, as one possible embodiment of a 3D coaxial via arrangement for vertical TEM VMTL transmission line for connecting two PMTL's at different layers of stack.

FIG. 15E sectional view cuts of AA′ for FIG. 15D, showing the stack of the 3D TEM via VMTL transmission line embodiment. Showing PTH vias stack array and pads, and NTPH vias stack.

FIG. 15F Further illustration of method of connectivity of single and differential PMLT on various layers of multi layer PCB stack using a 3D vias embodiment VMTL of FIGS. 15D and E, with cross section views of vias that could resemble 15 B, C or D. This FIG. demonstrates complete end to end connectivity from a single ended PMTL on the left, and differential PMTL on the right from a lower layer to a higher layer of stack through corresponding 3D via structure.

FIG. 15G. Demonstration of the way the combination of embodiment of FIGS. 14 and 15 and connector structure of FIGS. 9 and 10, and 11 can provide means of PMTL connectivity of a mother board (backplane) and a daughter board through a connector with embedded PMTL transmission line technology.

FIG. 15H. Various possible embodiments of VMTL multi lane vertical transmission lines.

FIG. 16A An alternative type of SE-PMTL to SE-PMTL connector embodiments, showing the use of in-plane multi-layer PCB with embedded PMTL. This FIG. shows a Jack, or male connector end. Differential PMTL connector is similar.

FIG. 16B An alternative type of SE PMTL to SE PMTL connector embodiments, showing the use of in-plane multi-layer PCB with embedded PMTL. This FIG. shows a plug, or female type connector as a through connector. Differential PMTL connector is similar.

FIG. 16C Shows the Jack and Plug connectors of FIGS. 16A and 16B in an engaged manner.

FIG. 16D Shows the Jack and Plug connectors of FIGS. 16A and 16B in a engaged manner, but with additional mechanical clips and notches for snapping into position. This is accommodated by adding another metal sheets on top of the connector assemble as shown.

FIG. 16E Showing the embodiment of FIG. 16D, with connectors and PMTL's disengaged to show the details of electrical and mechanical connectivity.

FIG. 17, shows several possible connector array foot prints for making various PCB socket for connecting External PMTL's and PCB's in a manner similar to that of FIG. 15G. These pattern include differential, single ended, and a combination thereof.

FIG. 18. Demonstration of versatility of PMTL and VMTL connector arrays (Sockets) of various types and various possible interconnection topologies, for PCB connection, edge to edge, end connection, and PCB stacking, and many other possibilities.

FIG. 19A, 3D view of single ended PMTL connector modules made from Ground, Dielectric, and Signal continuity modules as demonstrated in FIG. 9.

FIG. 19B, showing a single ended PMTL connected to a connector of FIG. 19A.

FIG. 19C, showing the PMTL connector assembly of FIG. 10B connecting to another PMTL section thus demonstrating connection of two PMTL's with a connector of FIG. 19A.

FIG. 19D, showing a linear array generalization of the FIG. 19B with side by side PMTL's and connectors arrays.

FIG. 19E, showing a 2D arraying generalization of the FIG. 19B or 19D with side by side and stacked PMTL's and 2D connectors arrays.

FIG. 20A, 3D views of a differential PMTL connector modules made from Ground, Dielectric, and Signal continuity modules as demonstrated in FIG. 9.

FIG. 20B, showing a differential PMTL transmission line terminated to a differential connector.

FIG. 20C, showing a differential PMTL connector connecting two differential PMTL transmission lines together.

FIG. 20D, showing a 2D generalization of PMTL differential connectors and transmission lines, side by side and stacking to accommodate a bus, or a very large number of connections.

FIG. 21A, Illustrating the adaptation of PMTL connector modules of FIG. 20A, in an existing avionic type connector in a plug configuration.

FIG. 21B, Illustrating the adaptation of PMTL connector modules of FIG. 20A, and short sections of PMTL in a existing avionic type connector socket to provide a male type connector (Jack).

FIG. 21C, showing the nature of internal part of connectors of FIGS. 21A and B, and a parallel plate grill with connectors modules removed for illustration.

FIG. 21D, Showing the front view of the grill of FIG. 21C with connector elements in place.

FIG. 21E, Same as FIG. 21D with the grill elements removed to show the arrangement of the connector elements and its array positions with respect to aperture holes in the grill.

FIG. 21F, a close up of part of the array of FIG. 21E to better show the elements of the differential PMTL connector elements and the 2D array topology.

FIG. 22A. Generalization of the concept of FIGS. 19 and 20, A demonstration of development of linear connector array and a flexible PMTL array strips to provide high speed flexible jumpers, for PCB edge to edge, and or point to point connectivity.

FIG. 22B, an alternative flexible bus, and jumper for edge to edge connection that can be twisted with two connectors in two orthogonal planes so to connect PCB's on twisted planes.

FIG. 22C, close up of the linear array of PMTL connector array attached to a flexible PMTL bus or jumper.

FIG. 23A, generalization of the connector concept of FIG. 21, with an array of PMTL strands to form a PMTL flexible jumpers bus currently in use for avionics type connectors possible with jack on one side and plug on the other side.

FIG. 23B, alternative view of FIG. 23A, showing the Plug side.

FIG. 24A. Further generalization of the connectors and arrays of FIG. 22. Showing a 2D connector array integrated with a matching 2D array of flexible PMTL strands to make a 2D jumper.

FIG. 24B, showing front view of the 2D PMTL connector array of FIG. 24A.

FIG. 24C, showing the side view of the connector array of FIG. 24B.

FIG. 24D, showing a close up of part of the connector array of FIG. 24B, showing the nature of each elements and the array configuration. In this case the connector elements are single ended type, but differential will be similar and any combination can be achieved.

FIG. 25A, Demonstration of fan out of a PMTL 2D flexible bus from a small area decimeter side, to an area of about meter side through meter height, with bus strands fanned out with delay adjustment loops.

FIG. 25B, close up of top of fan out of FIG. 25A, showing the neck and fan out region.

FIG. 25C, 3D view of a fan out of PMTL bus with a top PMTL connector array.

FIG. 25D, close up of the top of FIG. 25C with connector array, and neck, and fan out region of flexile PMTL bus.

FIG. 25E, further close up of the top of the fan out embodiment of FIG. 25D, showing the connector array.

FIG. 25F, further close up of the connector array on top of FIG. 25E. showing more details of connector element.

FIG. 26A, illustration of an application of the fan out of FIG. 25, for a ATE (Automatic Test Equipment) tower top, showing the top external to the ATE test head, and fan out below the internal to the ATE tower. With a connector interface on top, and UTS, Universal Test Socket for DUT connection.

FIG. 26B, 3D view of FIG. 26A fan out.

FIG. 26C, close up of the top of FIG. 26B showing the detail of external and internal parts of ATE tower top.

FIG. 26D, with UTS removed to show the connector array on top for connectivity to a large family of UTS sockets.

FIG. 26E, showing a close up of the 2D array of connector on top of ATE of FIG. 26D.

FIG. 26F, close up of detail of connection of the bottom connector of the UTS of FIG. 26C, and the top connector array of the FIG. 26D.

FIG. 26G, close up of the top of the UTS of FIG. 26C, without the DUT and calibration devices, showing the areas for DUT installation and placement.

FIG. 26H, close up of top of UTS with DUT BGA type in place.

FIG. 27A, A 4×4 array of sockets for testing packages on top of ATE, using an orthogonal array of vertical wafer cards with embedded PMTL in a special shaped pattern and opening.

FIG. 27B, Illustration of FIG. 27A with packages DUT removed to show the socket area and the orthogonal wafer cards bundles.

FIG. 27C. Illustration of FIG. 27B, with the wafer cards removed to show the embedded PMTL connectivity array mechanism.

FIG. 27D, showing the FIG. 27C, but with test packages arrays in place, to illustrate the way the connector pads on DUT package connect to the test pattern on the top of ATE.

FIG. 27E, illustrating of FIG. 27C with the connecting PMTL mechanism removed to show the connectivity pad on the Test card.

FIG. 27F, illustrating the principal of the extending the array connector of PMTL's to a wafer probe surface.

FIG. 27G, the concept of a 2D connector array and the principle of providing connectivity to a 2D array of test socket of FIG. 27A-E.

FIG. 28A, a close up of central region of a package test socket with an array of orthogonal wafer cards made from anisotropic elastic material with embedded PMTL arrays providing connectivity to the test board connection pattern pads, and package connectors pads, shown with a test package inside the central opening.

FIG. 28B, a zoomed out view of FIG. 28A, showing the star shaped holding flanges, with tope layer removed.

FIG. 28C, another view of FIG. 28C with another holding flange removed to show the nature of the wafers and alignment and holding mechanism.

FIG. 28D, close up of central socket of FIG. 28C when is the lowest flange is removed, showing the nature of notches and wafer shaping for alignment and holding, as well as the area where the DUT package is placed, and also showing the embedded PMTL lines that connect the pads on bottom of the package to the connection pads on ATE top.

FIG. 28E, on the left, showing the package on top of connection pads with wafers card removed from FIG. 28D. on the right showing the package removed.

FIG. 28F, on the left, further views of FIG. 28E, by removing the package and PMTL connector lines to show the connection pads on the test bed and location of the DUT package pads, and on the right the package pads and ground removed.

FIG. 29, illustrating one aspect of Reel-to-Reel (R2R) manufacturing process for high volume production of all variations of PMTL transmission lines introduced in this disclosure.

FIG. 30A, illustrating the concept of VITA connector wafer cards connectors for connecting daughter boards to mothers boards with a array of 7×16 pins, and skew problem.

FIG. 30B, illustrating the concept of VITA array of 7×16 pins, with differential grouping with skew problem (on the left) as it is now, and with proposed skew free connection differential grouping and VITA connector development based on PMTL flex ribbons (on the right) FIG. 30C, illustrating of two types of PMTL based VITA connector, one to the left, with PMTL flex ribbon bus each housing 1×16 PMTL's and seven ribbons all together to provide a skew-less VITA type connection of 7×16 pins. To the left, a concept with multilayer (7 PMTL ribbons in shaped 90 bends, with pins arrays of 7×16 for connection to daughter board and mother boards and VMTL 3D via technologies.

FIG. 30D, illustrating the concept of a PCB socket similar to DDR3 DIP sockets for PMTL, on the left, one with PCB technology, disengaged, and engaged, on the right, a similar concept with spring pin membranes for connectivity using existing connector technologies, disengaged, and engaged PCB connectors. (Dip socket using PMTL)

FIG. 31A, at left illustration of a typical chip package, with chips profile, chip wire bond pads, and package wire bond pads, on the right, with fan out wire bonds connecting the chip to package pads.

FIG. 31B, left, illustration of a package and chip wire bonds patterns, center, a typical wire bond pattern fan out on a single quadrant, right, a topology of wire ribbons fan out.

FIG. 31C, (left) illustrating top and side views of, a new concept of flexible membrane with embedded PMTL fan out transmission line with matching chip side and package side bonding pads, center, a single wedge-shaped fan out fan out PMTL membrane with a wire bond pad patterns, right, a four separate fan out to connect the chip to package,

FIG. 31D, illustration of the use of a single membrane PMTL fan out to achieve the traditional wire bond fan out to connect the chip to the package, top view of membrane is shown. Thermal compression can be used. This replaces the need for automated wire bonding of millions connection into a single action.

FIG. 32 A-D: Illustration of the way the PMTL twisted pairs introduced here can replace the UTP or STP CAT 5, 6, and 7, and the way the RJ45 connector is implemented using the PMTL. A) illustration of various parts of a existing UTP/SUP cables, B) the existing RJ45 connector pin out, C) the PMTL STP, and D) the corresponding RJ45 PMTL STP connection concept. (Note: 8P8C Wiring (TIA/EIA-568-A T568A), pins numbered from left to right 1-8.)

FIG. 33 A-D: A) Illustration of a typical router architecture comprised of a backplane, and line cards and switch fabric. B) Close up, illustrating the operation of a line card and switch fabric cards. C) Proposed new star super router architecture taking advantage of the teaching of this patent, to provide equal line length and minimal line loss and low latency and skew. D) Simplified side view showing the stack of the super router topology of C).

FIG. 34. Application of the PMTL to low loss, high Q lumped inductor technology.

### DESCRIPTION OF SOME EMBODIMENTS

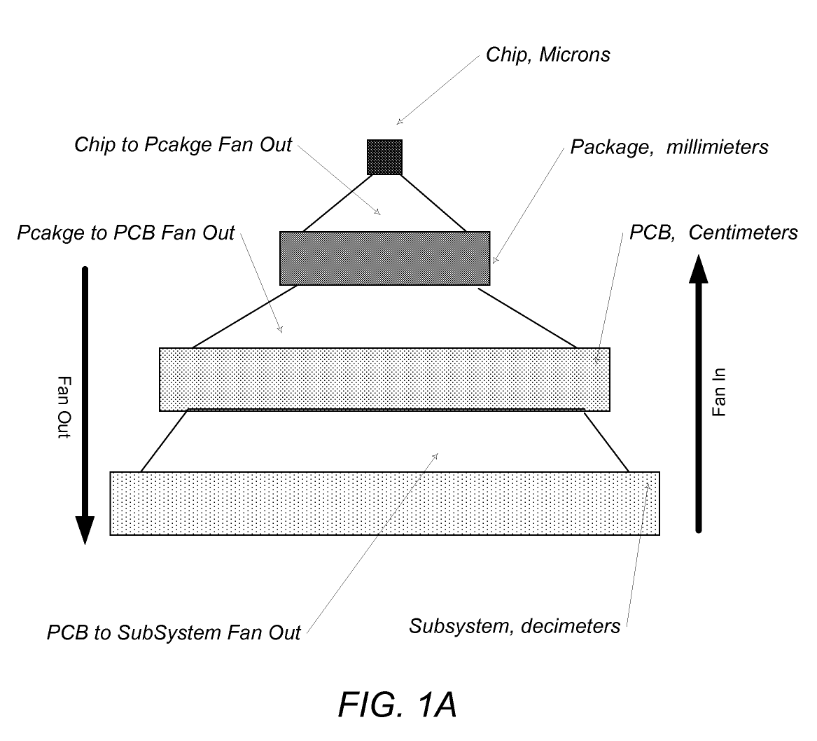

FIG. 1B shows a cross section of one possible embodiment comprising of four layer PMTL transmission line as was disclosed in Izadian. As is shown, the PMTL can be constructed from strategic use of several dielectric layers, in this case three, designated by 1-7,1-9, and 1-11, and four metal layers, designated by 1-6-T, 1-8, 1-10, and 1-6-B. and a set of Plated Thorough Holes arrays, (PTH) as well as a set of VIA NPTH arrays. (not plated, filled with air or such) strategically arranged. One of the objectives of this arrangement is to emulate the behavior of coaxial transmission line. The PMTL 1-1 of FIG 1B shows a central PTH 1-5 that electrically connects the two central traces 1-8C and 1-10C together thus substantially providing a fat center conductor type assembly. The PMTL also comprise of shield around the center conductor comprised of ground plane 1-6-T on top, and 1-6-B on bottom, which are interconnected through two PTH via stacks of 1-2-L on the left, and 1-2-R on the right. These PTH also connect the strips 1-8L, and 1-10L on the left, and 1-8R, and 1-10R on the right as is shown. While these metal structures provide means for central signal and shield signal flow, the NPTH array comprising of 1-3-L, 1-4-T, 1-3-R, 1-4-B, vias strategically located around the 1-5 center conductor, can serve at lease one purpose of thinning the dielectric loss effect for reducing the propagation losses at higher frequencies as well as increasing the VOP, the Velocity of Propagation.

In addition to providing a high efficiently coaxial type TEM printed transmission line, this embodiment provides at least two other advantages, mainly, it provides virtually a fatter conductor assembly and cross section which helps reduces the conductor losses, while using only 10% of copper required for an equivalent coaxial line, and also provides thinning of the dielectrics density by the volume ratio of vias before and after (Vb/Va), thus reducing its effective dielectric constant (Thus increasing velocity of propagation, and thus reducing propagation delay), while at the same time reducing the effective loss tangent of dielectric materials used. Note that many different martial and fillers can also be used to achieve even further improvements. For example, in one embodiment, the empty vias can be filled with NRI martial, thus even further reducing the loss and delay.

These techniques are consistent with the physics of signal propagation. For example, in typical coaxial lines, in lower frequency the skin depth is large, and so there is significant current flow in conductors, but in higher frequency, skin depth is very small, and thus only a thin sheet of current flows on the surface of conductor, in fact, at higher frequencies, the conductors can be hollowed and the effect would not be felt. And in fact, the conductors can be made to appear fatter in lower frequencies to project a bigger cross sectional area, thus helping reduce signal loss due to conductors.

The techniques introduced here can be taken to extremes of simplifying further down in structure of FIG. 1A or making it much more elaborate to achieve the same goals of signal integrity across the spectrum and for various manufacturing processes, as will be illustrated later.

Furthermore, the techniques introduced here are consistent with the Heaviside condition for optimal signal transmission. For example, Air vias (we use air as a generic to distinguish them form PTH plate vias., and can be any thing else too) 1-3-L and 1-3-R on Left and right, and vias 1-4-T-B are shown at top and bottom centers. By strategically designing these vias, and the plated PTH, and the cross section, we can achieve a coaxial-like printed transmission line that we can control the R, L, G, and C strategically to meet Heaviside's condition and provide an ideal printed confined field transmission line. Furthermore, it may be possible to incorporate a high pass filtering functionality as an integrated part of the printed PMTL to act as an equalizer to flatten the response of PMTL to improve ISI in high speed digital systems.

FIG. 1, was described originally in Izadian patent application 1, and many variation of this is possible. It is highly desired to also have differential pair transmission line, and or twin ax, or quad axial transmission lines, which will be described later.

In contrast to single ended transmission lines, a differential pair transmission line, provides two internal conductors usually surrounded by an external shield. In such a transmission line, two mode of operation is possible; one is called the differential mode, where the currents in each conductor are antipodal. The other is called the common mode, where the currents on both conductors are in phase. The common mode normally relies on the shield for efficient propagation, while, the differential model, mainly is concentrated between the two conductors, and relies to a lesser extend on the shield. In fact, the degree of this coupling to shield can be a design variable to achieve a set of objectives.

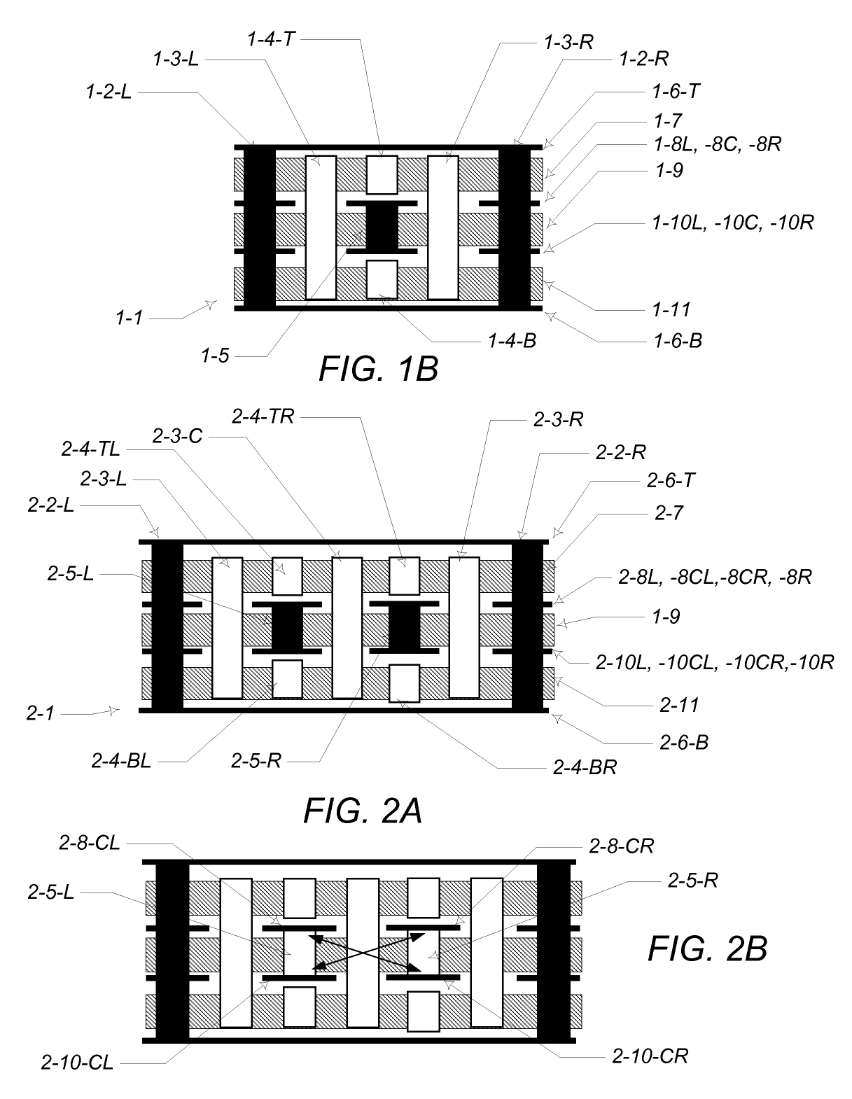

FIG. 2A shows a PMTL implementation of the differential transmission line or a twin-ax. It can be readily viewed that some basic elements of the PMTL of FIG. 1B is used as modules of construction of the Differential PMTL of FIG. 2. As is shown in FIG. 2A, the differential PMTL is comprised of at least three dielectric layers 2-7, -9, and -11, with four metal layers 2-6-T, 2-8, 2-10, and 2-6-B. The top and bottom metal layer 2-6-T and 2-6-B constitute the top and bottom ground planes which are connected together on the left with PTH stack comprised of 2-2-L, Strip 2-8L, 2-10L, and on the right 2-2-R, Strips 2-8R, and 2-10R. which together provide a complete shield for the transmission line. The two differential pairs conductor assemblies are comprised on the generally central left, the Strips 2-8CL, PTH 2-5L, and 2-10CL, and on the generally central right Strips 2-8CR, PTH 2-5R, and 2-10CR,

As is shown, the thinning process is achieved by the NPTH vias from left to right 2-3-L, 2-4-TL and 2-4-BL, 2-3-C (only one is shown but can be more), 2-4-TR, and 2-4-BR, and finally 2-3-R, on the right. This assembly behaves similar to a twin ax differential coaxial line.

FIG. 2B shows another alternative to differential PMTL pair of FIG. 2A, by a simple modification of the process, on not plating the via holes 2-5-R and -L, the quad axial PMTL transmission line can be obtained where the traces 2-8CL, and 2-1 OCR can be driven as one pair of differential lines, and 2-10CL, and 2-8CR can be driven as another pair of differential lines, and these two differential modes are completely orthogonal and thus the structure of FIG. 2B can be operated as a quad axial lines with two orthogonal differential modes, which can replace many of similar quad-axial transmission lines in use today.

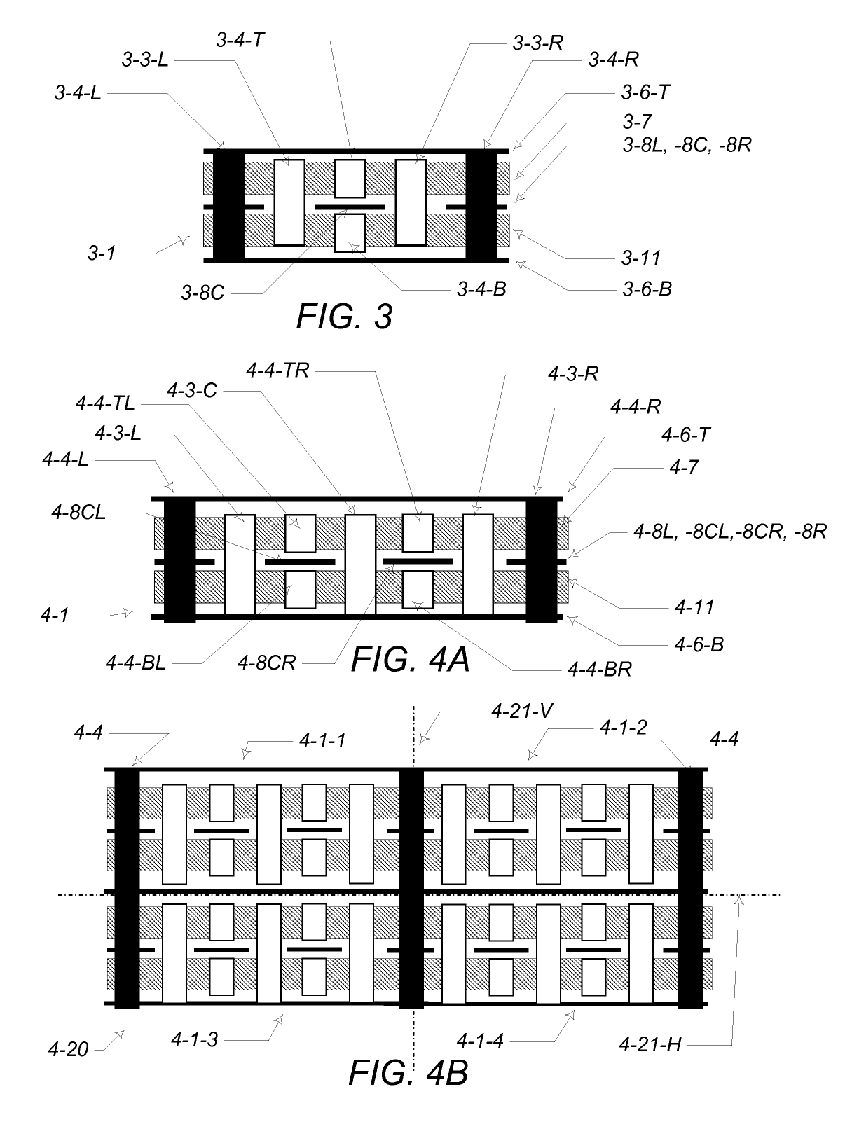

There are many possible alternative configurations to this basic realization of FIGS. 1B and 2 PMTL. One possible way to achieve this is by reducing the layer count from four metal layers to three, as shown in FIG. 3. in FIG. 3 a single ended stripline-like PMTL transmission line is illustrated. The PMTL-SL configuration shown in FIG. 3 comprises of at least two dielectric layers 3-7, and 3-11, and three metal layers 3-6-T on top, 3-8, and 3-6-B on bottom. The main signal strip is shown as 3-8C, the top and bottom ground metals 3-6-T and 3-6-B are connected through the PTH stack vias 3-4-L and 3-8L, on the left, and the PTH via stack 3-6-R and 3-8R strips on right. The thinning is achieved by the 3-3-L on left, 3-4-T via on central top, and 3-4-B on bottom, and 3-3-R on right. Again, many variations of this is also possible, and falls within the scope of this inventions.

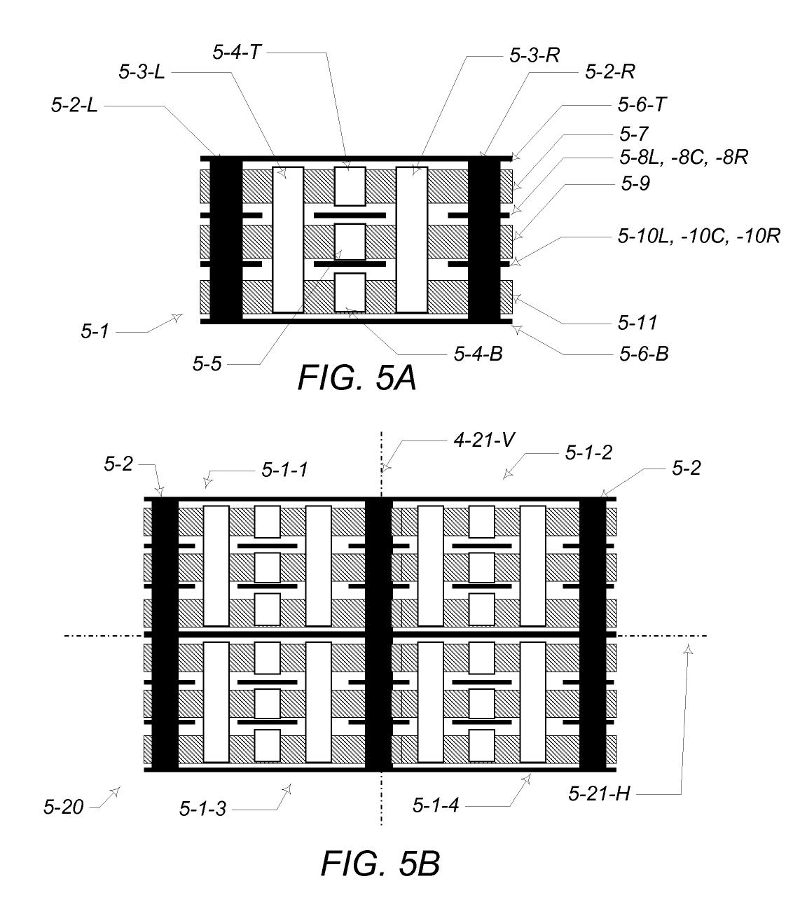

FIG. 4A illustrates a differential pair PMTL transmission line. As is shown, it is comprised of dielectric layers of 4-7 and 4-11, and three conductive layers of 4-6-T on top, 4-8 in middle, 4-6-B on bottom. The two differential signals are supported by traces 4-8CL, on center left, and 4-8CR, on the central right. The shield comprises of the conductor layers 4-6-T and 4-6-B, connect though PTH via stack 4-4-L, and 4-8L strip, on left, and PTH via stack 4-4-R, and 4-8R strip, on the right. The thinning of dielectric is achieved by the vias NPTH 4-3-L, 4-3-C, and 4-3-R, on left, center, and right, and the other vias 4-4-TL, 4-4BL, 4-4-TR, 4-4-BR. These vias are representative, and the thinning functionality can be achieved by vias of any shape, like slots, and many other mechanisms.

The differential PMTL of FIG. 4A can be further generalized into a quad axial transmission line, by stacking two of the embodiments of 4-1 on top of one another. This can be achieved with or without an intermediate ground plane 4-6-B. In general, this geometries of FIGS. 3 and 4A can serve as cellular building blocks of a hybrid array transmission lines comprised of plurality of single ended and differential pairs, of twin-axial, tri-axial, or quad axial printed transmission lines. Although all combination is possible, only one is illustrated here in FIG. 4B as an example.

For illustrations of one possible configuration, a 2×2 array of the configuration of differential pair PMTL 4-1 is shown in FIG. 4B, as a four differential lane bundle similar to the CAT 5, 6 and 7 twisted pairs currently in use in Ethernet networking connections. As is shown in FIG. 4B, the 2×2 array comprises of four units 4-1-1, 4-1-2, 4-1-3, and 4-1-4 replica's of 4-1 of FIG. 4A. PTH via stack of 4-4 can ensure ground plane continuity for all layers. The configuration shown illustrates symmetry about the axis 4-21-V and 4-21-H. but any unsymmetrical combinations are also possible. In this configuration, all the differential pairs are fully shielded and therefore, cross talk and interference will be none existent or minimal.

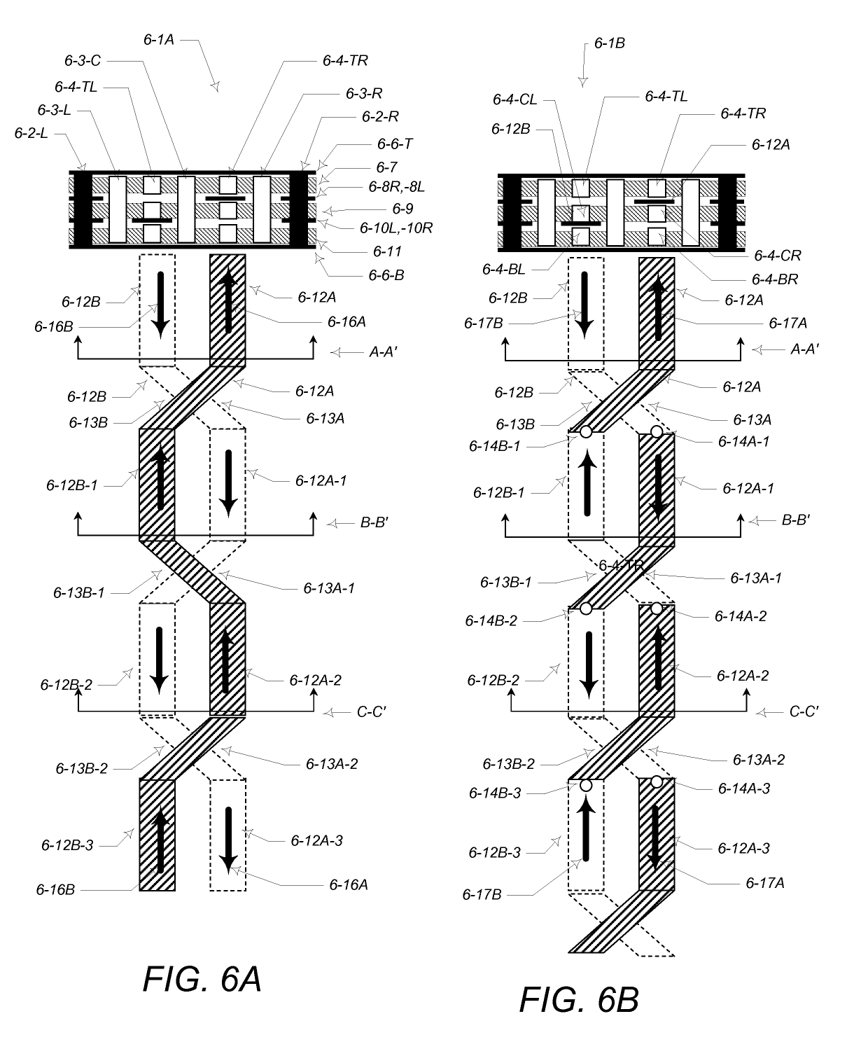

So far, we have illustrated the edge side differential pairs of FIG. 4A and the array of 4B. There are some advantages to this configuration, but one possible draw back is the current bunching at the inner edges of the coupled strips, this is undesirable as it introduces signal loss along the path. For this reason, it is desired to develop broad side differential lines. One possible configuration of implementation of a PMTL differential pair using broad side strips is shown in FIG. 5A. The nomenclature of the configuration 5-1 in FIG. 5A is very similar to that of single ended PMTL of FIG. 1B. The only major difference is that the central via 1-5 in 1-1, corresponds to 5-5 in FIG. 5A is not plated through thus turning it into a air via. This is shown in FIG. 5A 5-5, all the remaining elements are similar to that of FIG. 1B and stack 1-1. This could be very useful in manufacturing process, as only by elimination of one plating step of a via, could turn the Single Ended PMTL 1-1 to a Differential PMTL transmission line. In addition, the broad side differential pairs of 5-1 will provide more uniform current flow, and thus will provide lower signal loss, and therefore much higher speed signal transmission across the spectrum (As will be shown later, this also provides means to develop PMTL cross-over bridges).

So, the broad side differential PMTL of FIG. 5A comprise of three insulator layers 5-7,-9, and -11, and four conductor layers 5-6-T, 5-8, 5-10, and 5-6-B, PTH via stack 5-2-L, 5-8L, 5-10L, on the left, and 5-2-R, and 5-8R, 5-10R, on the right. The dielectric thinning is achieved by NPTH vias 5-3-L, and 5-3-R, and 5-4-T, 5-4-B, and 5-5.

We can now further generalize the differential PMTL structure of FIG. 5A. An arraying of this 5-1 stack can provide multiple transmission lines bundles. An example is shown in FIG. 5B, as a 2×2 array of 5-1, consisting of 5-1-1, 5-1-2, 5-1-3, and 5-1-4. to provide a four lane differential Pairs transmission line channels 5-20. The ground stack 5-2 can be used to provide continuous grounds. For the example shown in FIG. 5B, a symmetric configuration is shown, with respect to vertical and horizontal symmetric lines 4-21-V, and 4-21-H, but any other combination is possible, for example removal of any ground plane, or via stack can produce some other desirable embodiments but with less shielding. The stack of 5-20 shows at least one way to manufacture Ethernet cables that can replace the existing CAT-5, and CAT-6, and CAT-7 lines, or provide those capabilities on the PCB backplanes. However, in these types of transmission lines a criss-crossing or twisting of currents flow is introduced to provide an equalization of the common mode interference and noise into differential lines, so that when they are connected to balanced lines, by a hybrid, the interference is canceled, while the desired signal is doubled. Next we provide some possible ways of achieving twisting of PMTL technology through printing method in PCB's and in CMOS processes, using the existing manufacturing processes in wide use today.

We will demonstrate at least three possible ways of achieving the functionality of twisting pairs using PMTL technology employing a stack similar to 5-1 of FIG. 5A, and a variation of stack of embodiment 2-1 of FIG. 2, which includes a simple twisting, mainly comprised of a zig zagging of the conducting strip in balanced line, another a true twisting of printed strips, and yet, one with variation of the four layer PMTL of 2-1 of FIG. 2. Each will have their own attributes that may be used for high speed signal transmission with highest signal integrity, in the 10GBASE-T, 100GBase-T, and XAUI, PCI Express, Infini-Band, I2C, USB, DVI, Fire wire, GBe, F.C., and other backplane high speed transmission protocols and others that are still in development.

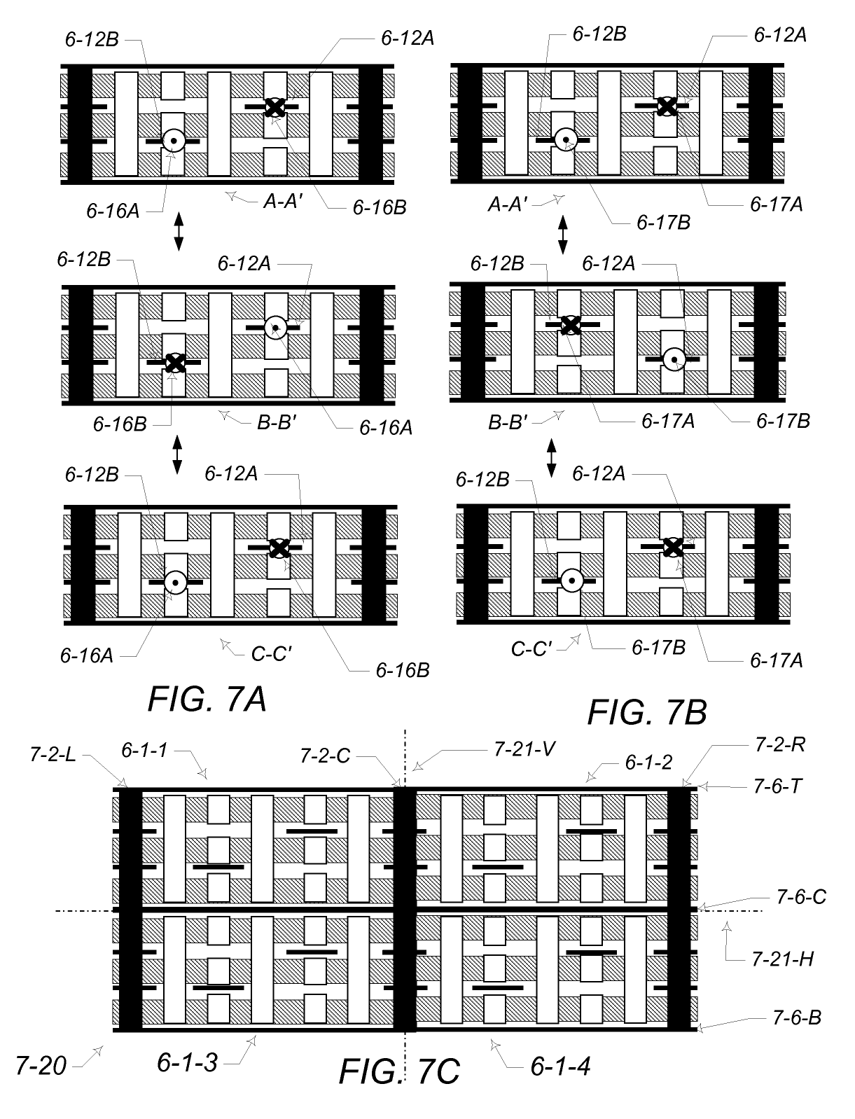

One relatively inexpensive way to implement the functionality of twisting pairs is through a zig zagging or criss-crossing techniques illustrated in one embodiment in FIG. 6A. As is illustrated, the stack 6-1A is an offset variation of the stack of 5-1 in FIG. 5A and that of 2-1 in FIG. 2, with strips offset from one another. The stack of 6-1A comprises of three insulator layers 6-7, -9, and -11, and four conductive layers 6-6-T, 6-8, 6-10, and 6-6-B. The ground shield is comprised of the top and bottom metal layers 6-6-T and 6-6-B, connected through PTH via stacks 6-2-L, 6-8L and 6-10L auxiliary ground strips, on the left, and 6-2-R, 6-8R and 6-10R auxiliary ground strips, on the right. The conductive differential strips (Shown in FIG. 6B, and stack 6-1B, to avoid crowding of call outs) 6-12B and 6-12A are offset both horizontally and in layers. The thinning of the dielectric properties is achieved as normally by the NPTH vias arrays (into and out of the plane of paper) from left to right 6-3-L-n, 6-4-TL, 6-4-CL, 6-4-BL, 6-3-C-n, 6-4-TR, 6-4-CR, 6-4-BR, and 6-3-R.

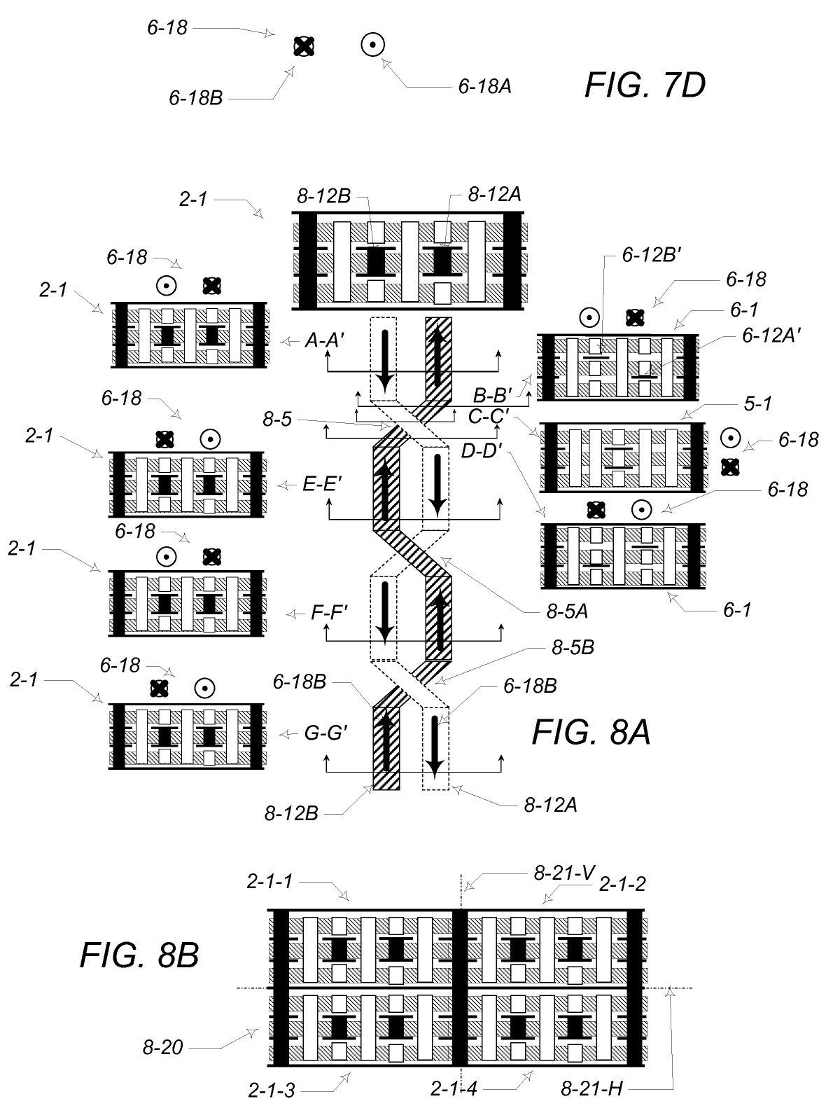

To properly describe the twisting techniques proposed here, we provide a top view of the traces configuration 6-12A and 6-12B, in a simplified manner, with all the via arrays, layers and ground layers ignored for simplicity. In these two traces, we show the direction of current follow in each strip as 6-16A and 6-16B. The twisting signal trace pairs is illustrated by the zig zagging of the traces 6-12A and -12B left and right as is shown by the cross over bridges 6-13A and 6-13B of the corresponding traces, each section of a twist is designated at 6-12B-1, -2, -3, . . . etc. . . . , 6-12A-1, -2,-3, . . . etc. . . . as a period of the twisting. To further illustrate the nature of the twists and current flow, we provide three strategic cross sectional cuts AA′, BB′, and CC′ along the current path in FIG. 6A. In the configuration of FIG. 6A, the traces 6-12A, and -12B remain in the same vertical stack layer, and the current flowing on them remain the same current, only their position of flow zig zags in the same stack position. This is further illustrated in FIG. 7A with the cross sections cuts and current flow illustration. FIG. 7D shows the conventional arrow head 6-18A and arrow tails 6-18B, in 6-18 pairs to illustrate the current flow direction out and into the plane of paper respectively.

With the convention of current flow 6-18, we can now examine the three cross sectional cuts of FIG. 6A in FIG. 7A. The top part of the FIG. 7A shows the AA′ as can be seen from the two strips 6-12 A and B. As is shown by 6-18B arrow tail, the current flows into the plane of paper on strip 6-12A, and the current flows out of the plane of paper on the strip 6-12B as is illustrated by the arrow head 6-16A. The center part of FIG. 7A shows the BB′ cross sectional cut corresponding to that of FIG. 6A, in the second twist period, that shows current flow on Strip 6-12A is out of the plane of paper as is shown by arrow head 6-16A, but on strip 6-12B flows into the plane of paper as shown by the arrow tail 6-16B. The bottom part of FIG. 7A shows the cross sectional cut CC′ corresponding to that in FIG. 6A, and shows the current flow is a repeat of the one at top part of FIG. 7A as in Cross section AA′, and show the nature of periodicity of the twisting and zig zagging of this type of current twisting. Note that, in this type of configuration of FIG. 6A, and FIG. 7A, no current flows vertically, only zig zags left and right and left, in a simple criss cross manner, etc. . . . .

Next, in FIG. 6B, we illustrate a current twisting very similar to the way it is achieved in the CAT 5 and 6, and 7 cables, as has been done from the time of Alexander Graham Bell. The stack 6-1B in top of FIG. 6B is very similar to that of its counter part in FIG. 6A, the difference is along the path of current propagation along the PMTL. Similar to FIG. 6A, the top view of a section of the strips 6-12A and -12B is shown. Below the 6-1B embodiment, a length of transmission line is shown for four twisting periods. The strips 6-12A on the higher layer is shown in darker hatch while that of 6-12B, on the lower layer is shown in dotted lines, for clarity.

The two strips of 6-12A and 6-12B in FIG. 6B cross over one another at 6-13A and 6-13B as shown, by the cross over sections terminate at two vias PTH holes 6-14B-1, and 6-14-A1 at which point these trace ends are connected to beginning of another trace Pairs of 6-12B-1 and 6-12A-1, at this point, the current 6-17A that flows on 6-12A strip continues over the cross over 6-13A, and flows on the PTH 6-14-B-1 and then flow onto strip 6-12B-1, and the current 6-17B that flowed on strip 6-12B flows through cross under 6-13-B and then to via PTH 6-14A-1 and then flows on strip 6-12A-1, thus switching of the current flow from one strip to another and the cross over repeats over the next periods of the strips, as shown by the cross over 6-13A-1, and 6-12B-1, -2, -3, etc. . . . , and PTH via Pairs 6-14 A and B, Pairs -1, -2, -3 etc. . . . thus providing a true twisting spiraling current along the propagation paths of the 6-1B transmission line.

To further illustrate this current twisting mechanism, we provide cross sectional cut views of AA′, BB′, and CC″ of FIG. 6B in FIG. 7B. Again we use the current flow convention of arrows head 6-18A and arrow tails 6-18B of FIG. 7D, as current flowing out and into the plane of paper. As is shown in FIG. 7B, The top shows the view of cross sectional cut AA′, that shows that the current on strip 6-12A flows into the plane of paper as shown by arrow tail 6-17A, and on strip 6-12B, current flows out of the plane of paper as shown by the arrow head 6-17B. at the cross section views of BB′ at the center figure of FIG. 7B, corresponding to that of BB′ of FIG. 6B, the current flow on strip 6-12A is out of the plane of papers at shown by the arrow head 6-17B, and on strip 6-12B, the current flows into the plane of paper as shown by arrow tail 6-17A, and at the CC′ sectional cut of FIG. 6B, illustrated in lower Figure of FIG. 7B, the current flow is back to that of AA′. So, that it repeats on and on over the periods of the twist along the transmission line.

Now that we have demonstrated how to develop these two types of thin strip twisting pair differential transmission lines, of 6A and 6B, we can further generalize that they can be mixed and matched and made into array of conductors and buses or groups. One such an example is shown in FIG. 7C, as a quad pairs of twisted Pairs lanes. This is essentially similar to the CAT 5, 6, and 7 Unshielded Twisted Pairs, or Shielded Twisted Pairs UTP and STP in extensive use in Ethernet wiring. The embodiment of 7-20 of FIG. 7C can therefore serve as replacements for these type of Ethernet wiring on flex material printed in mass volume using reel to reel as will be illustrated later, or as high speed data lanes on the PCB, CMOS, and backplanes, mother board, daughter boards and all system levels, in a fan out from a chip scale to package scales, to PCB scale, and systems scale. Thus providing the echo system for copper based 10GBase-T and 100GBase-T's and others yet to be developed. As is shown in FIG. 7C, the 7-20 quad lane twisted pairs is comprised of four 6-1A, or 6-1B, or a combination as 6-1-1, -2,-3, and -4, that can provide complete shielding by top 7-6-T middle 7-6-C, and bottom 7-6-B, ground planes and left 7-2-L, middle 7-2-LC, and right 7-2-R PTH vias stacks. The embodiment as shown is symmetric about axis 7-21-V and 7-21-H, but any other variation or asymmetry is possible. Furthermore, the shields can be removed thus providing further simplifications.

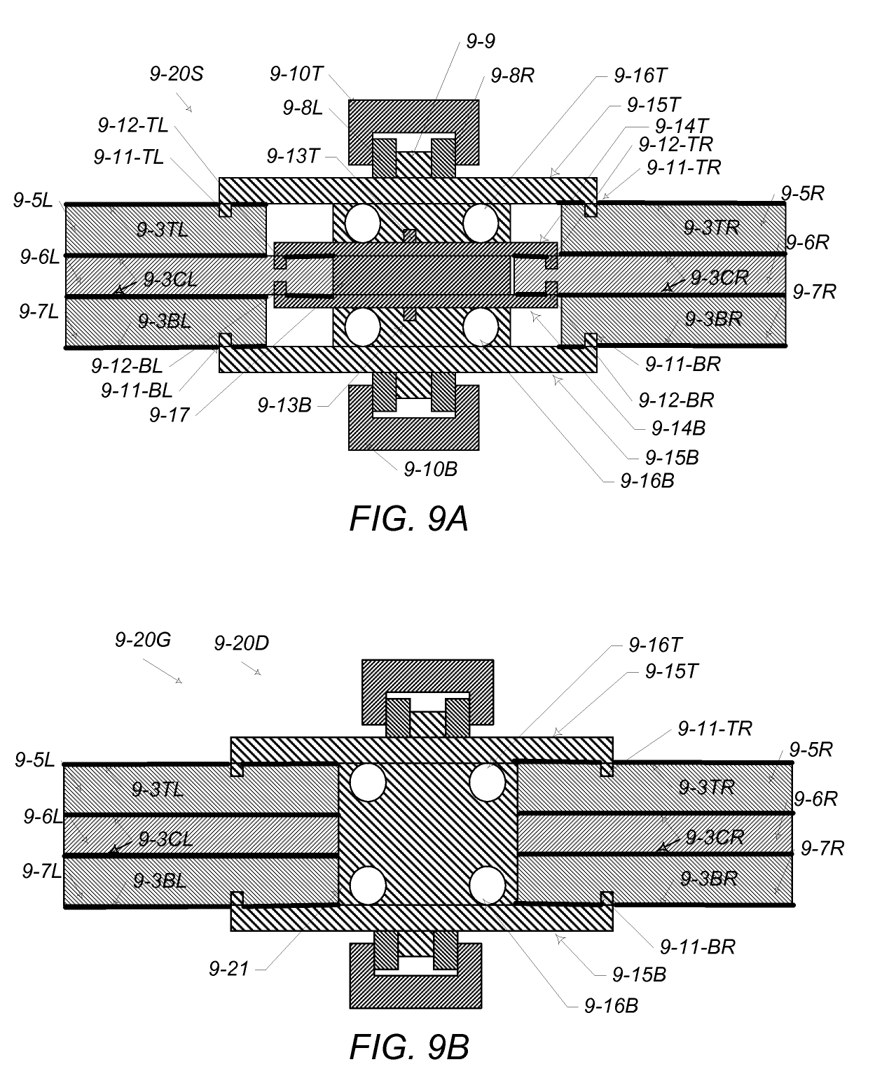

Next we illustrate how to develop a twisted pair differential PMTL of the type illustrated in FIG. 2 with fattened center conductors. It may be more desired in some cases for improving the copper loss performance of the transmission line differential pairs to employ this type of lines instead of the thin strip differential twisted pairs illustrated in FIGS. 6 and 7. To illustrate the way twisting is achieved for the differential Pairs 2-1 of FIG. 2A, we provide the process illustrated in FIG. 8A. First on top of the FIG. 8A we provide the stack 2-1 of the differential pair twin-axial line. Below it, we provide the simplified top view of the conductor assemblies 8-12A and 8-12B. The conductor mechanisms 8-12 A and B are generally fat along the length of transmission line, i.e., at the cross sectional cuts AA′, EE′, FF′, and GG′, but in the region of cross over (X-shaped region) 8-5, 8-5A, and 8-5B, . . . etc. . . . the current is carried by thin strips such as those shown in Cuts BB′, CC′, and DD′. This is one possible way of twisting the current flows 6-18 A and 6-18B between the two conductors and achieving a true current twisting. This mechanism can also be used to make a cross over bridge for PMTL lanes on the same level.

The nature of current twisting mechanism is further illustrated by examining the cross-sectional cuts corresponding to those along the length of transmission line and along the cross over sections of FIG. 8A. For example, the cross sectional cut view AA′, on the top left of FIG. 8A, shows that the current on 6-12A flows into the plane of paper as shown by the arrow tail 6-18 above it, and on trace 6-12B, flows out of the plane of paper as is shown by arrow head above it.

Next, moving along the length of the PMTL transmission line of FIG. 8A, we arrive at the 8-5 cross over regions. The first cross section view cut of BB′ shown to the right illustrates that in the X-cross region, the conducting mechanism are similar to the twisted offset transmission lines 6-1 of FIG. 6, and the current flow direction into the plane of paper is shown above the BB′cross sectional view by arrow head and tails 6-18, as in AA′, 6-12B′ still out of the plane of paper, and in 6-12A′, into the plane of paper as shown by the arrow head and arrow tails pair 6-18 above it.

The next cross sectional view cut is taken exactly in the center of X shaped cross over area 8-5. This is designated by CC′ view shown to its right. In this case, the two thin strips 6-12B′ and 6-12A′ are precisely broad side as in 5-1 stack in FIG. 5A. Note that at this stage, the currents are consistently flowing on 6-12B′ and 6-12A′ out and into the plane of paper as illustrated by the arrow head and arrow tails pairs 6-18 shown to its right, The center of cross over where CC′ cut is made, is the point at which the currents switch sides, as the offset of two conductors is continued along the X-cross section, as shown in DD′ sectional cut of the bottom of X-cross over area 8-5 shown to the lower right of the DD′. In fact at DD′the differential pairs resemble that of 6-1 in FIG. 6. As is shown, the current flow on the DD′cross section shows the current flow on 6-12B′ and 6-12A′ are out and into the plane of paper as illustrated by the arrow tail and head of 6-18 above it. By comparing the two sectional cuts BB′ and DD′, it is apparent that the current flow has switched from left to the right, and thus the twisting (Cross Over) of current flow has been achieved. So, if we examine further the cuts EE′, and AA′ to the left, we can see that the twisting of current from one period to the next of the twist has been achieved, and if we further examine FF′ and GG′, we see that this is also achieved along the path after every cross over 8-5A and 8-5B, etc. . . . on and on and on . . . .

We can now generalize this twisting concept beyond the single twisted pairs illustrated in FIG. 8A. One skilled in the art can readily deduce that any combination of array of twisted and untwisted differential pairs and single ended PMTL transmission lines can be realized. Here we illustrate a 2×2 array of the twisted differential pairs made from 2-1 of FIGS. 2 and 8A, as shown in FIGS. 8B, 2-1-1, -2, -3, and -4 in embodiment of 8-20, the total shield can be achieved by top, center, and bottom ground plane and left, center, and right PTH via stacks. Although, any unsymmetrical array of 2-1 is possible, in 8-20 we illustrate an embodiment with symmetries about 8-21-V and 8-21-H symmetry axis. Note that the configurations of FIGS. 6B and 8 can also serve as PMTL cross over bridges that can be used to cross over any two PMTL's on the same layers. In the embodiments presented cross over method, R, L, R, C, and Zo, are per unit length for each cell of PMTL, and vias arrays are into and out of plane of paper, and in any strategic arrangement, in this case each via array is staggered.

So far, we have presented several configurations of the PMTL transmission lines to provide an efficient high speed signal transmission. We now present several ways of interconnecting them in various configurations. In a typical system fan out, it is necessary to interconnect various modules with highest signal integrity. For this reason proper connection is very critical to the overall system performance. So, in order to connect any two PMTL's transmission lines together for the best continuity, we must ensure (see Izadian's book) the fields, voltage, and current continuity first in order to obtain proper impedance continuity along the path of the fan out, or across various sub modules in the same level of hierarchy. In achieving these goals, we introduce several connector modules that their sole purpose is to provide all these continuities in three possible regions of PMTL, ground, signal, and dielectric. We will refer to these as continuity modules throughout the rest of this disclosure (DCM, GCM, and SCM). If the individual modules are designed properly to provide impeccable continuities in each region of interest, then we use several of these modules to construct a full fledge connector ensemble which will have impeccable High Speed performance. We provide these processes in a configuration substantially orthogonal to the plane of PMTL, first.

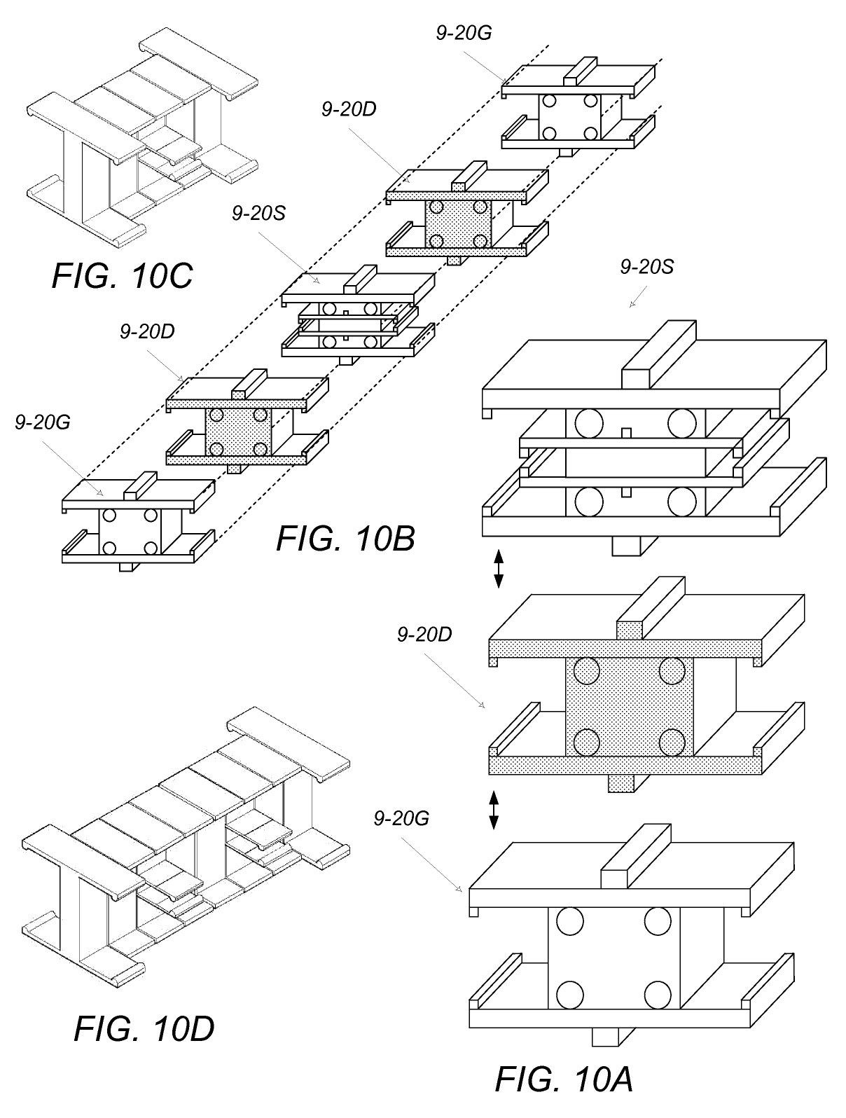

FIG. 9 presents a basic nomenclature of continuous field and currently connectivity for the PMTL. If we divide the continuity of the media from one PMTL to another PMTL into three basic categories, of Ground, Signal, and Dielectric regions, we provide the basic Modular building blocks to ensure the current and field connectivity individually in these three categories, then the entire connection can be made with highest efficiency. Although, there are many possible ways to achieve this end, we provide as a typical example, the configurations of FIG. 9. If we assume that we want to connect two PMTL similar to 1-1 in FIG. 1B, shown in FIG. 9A, one on the left side comprising of three dielectric layers 9-5L, -6L, and -7L, and one on the right comprising of three insulator layers 9-5R, -6R, and -7R. with the top and bottom grounds and signal on top and bottom of middle layers.

One embodiment of the Signal Continuity Module (SCM) connector assembly is shown in FIG. 9A. This embodiment comprises of a vertical assembly 9-20S of two essential parts of 9-15T and -15B, on top and bottom that are designed to connect the two surface grounds 9-3TL, and 9-3TR, of tops of insulators 9-5L and 9-6R, and the grounds 9-3BL, -3BR on bottom of insulator 9-7L and -7R, in a smooth continuous manner. The notch and pin mechanisms 9-11-TR, -TL, -BL, -BR provide a mechanism for clicking into position for holding the two connected PMTL's together securely.

In the same manner, the elements 9-14 connects the two PMTL central conductor on Right and Left together by 9-14T connecting the 9-3CR and 9-3CL, and 9-14B for connecting corresponding bottom signals in bottom of 9-6 insulator in a continuous smooth manner. And, notch and pin locking mechanism 9-12-TR, -TL, BR, and -BL provides a means to hold the connection secure. The central part of the connector 9-17 could be metallic and could connects the 9-14T and -14B together electronically. Many variations of this is possible. For example, in present embodiment, the area between the 9-15 and 9-14 can be air or dielectric. In the dielectric areas, in the same manner as for the PMTL, an array of via holes 9-16 can be implemented for thinning.

Note that although the FIG. 9A illustrates a single ended PMTL Signal Connector, with slight modification, it could also be used as a Signal Continuity Module for broadside differential PMTL 5-1 FIG. 5A., the top and bottom strips on middle layer 9-6 are connector by PTH similar to 1-5, 1-8C 1-10C of FIG. 1B, these strips in fact can be two elements of a balanced broad side line as in FIG. 5A 5-5, 5-8C, 5-10 C. In this case, the top and bottom parts of the center conductor connector 9-14T and -14B could be conducting while the central section 9-17 could be made of insulator.

Tab mechanism 9-9 on top and bottom are one possible means to secure the connector assembly 9-20S in a larger Screen or grill represented by 9-8 to allow assembly of a plurality of the connector 9-20S in an array for connecting a multiplicity of PMTL cables, bundles, or bus as will be illustrated later. The holding mechanism 9-10 represents the concept of an outer frame of such a connector array assembly that holds the two screen grills halves 9-8L and -8R together with tab 9-9 sandwiched in between snuggly. So, for a large array, the 9-8 will be perhaps a large screen or grill type parallel plates with opening apertures to accommodate the plurality of 9-20S sandwiched between 9-8L and 9-8R, that is held together by a properly sized outer frame 9-10.

A notch and pin mechanism 9-13T and -13B are also possible to keep the central condor connecting element securely in position.

The embodiment 9-20S in FIG. 9A can be considered as a Signal Continuity Module (SCM) which provides excellent signal continuity between the two PMTL's center strip, and ground continuity for the shields (and therefore excellent field continuity), as well as impedance continuity across the two connecting PMTL's on left and right. This module can be used as a basic building block to construct a large family of connectors, and used for any number of signals paths. For example, it can be used once for a single ended PMTL, and twice for a differential PMTL as will be illustrated later, or as was mentioned with 9-17 insulated as a broadside PMTL differential pair connector.

We can now generalize the modular continuity concept for the Dielectric Continuity Module (DCM) and Ground Continuity Module (GCM) Regions of PMTL as embodiments 9-20D and 9-20G, presented in FIG. 9B.

FIG. 9B shows one possible implementation of DCM and GCM modules for the PMTL. As is shown, the mechanism 9-15T provides continuity between grounds 9-3TR and -3TL, and 9-15B provides continuity between grounds 9-3BR, and -3BL, for a Dielectric or a Ground Regions. The central part 9-21 of the connector can be made of insulator with typical NPTH vias 9-16 as thinning mechanism, or for dielectric region, and conductive material, with or without PTH vias for the ground sections. In addition to this type of ground continuity element 9-20G, it may be possible to provide a section such as the 9-12 central conducting to provide even ground continuity for the auxiliary ground strips such as those 1-8L, 1-8R, and 1-10L, and 1-10R in FIG. 1B, here too. For better high frequency continuity and providing higher speed digital transmission. The rest of the notch mechanism, the holding screen mechanism, and holding frame mechanism can be the same for all elements as was illustrated in FIG. 9A.

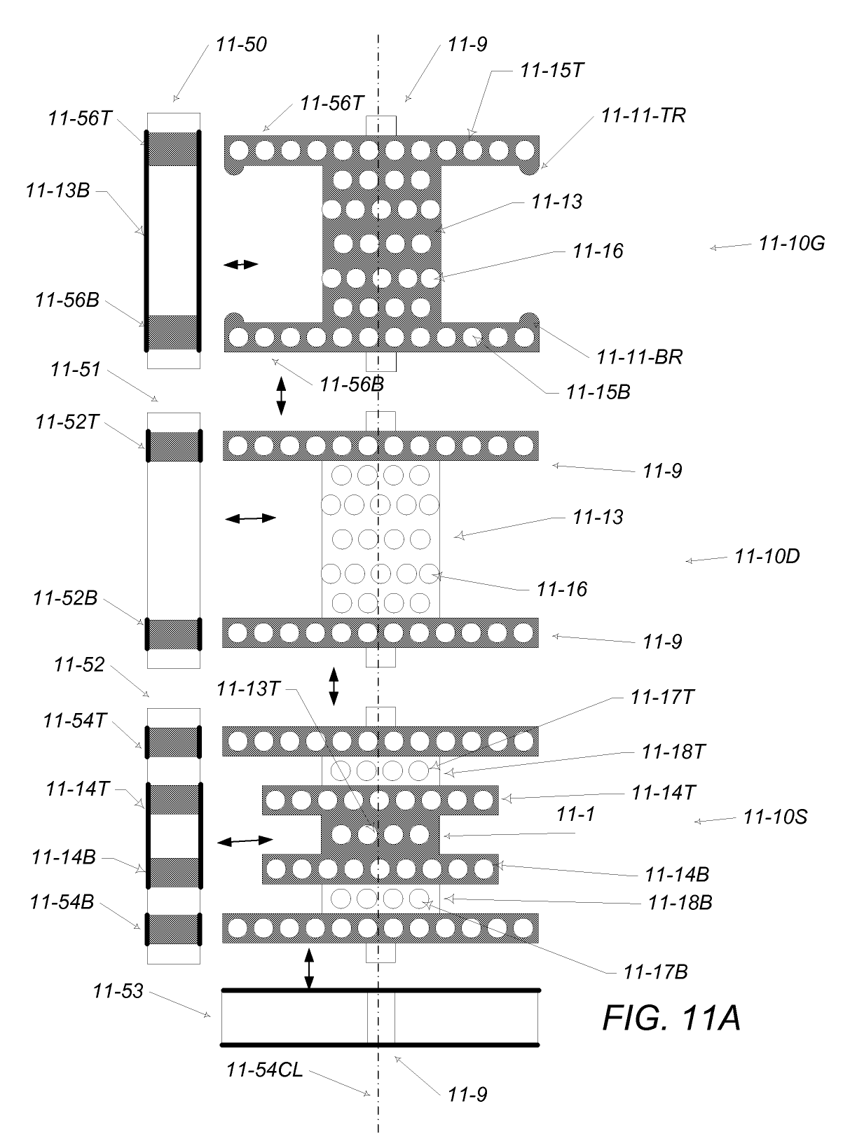

The Modules 9-20S Signal Continuity Module (SCM), 9-20D Dielectric Continuity Module (DCM), and 9-20G Ground Continuity Module (GCM) introduced in FIG. 9 now can be used to provide smooth continuity of Signal, Dielectric, and Ground regions of any two connecting PMTL transmission lines. One such a possible connector is illustrated in FIG. 10. FIG. 10A shows 3D views of the three basic modular elements for 9-20S, 9-20D, and 9-20G for Signal, Dielectric, and Grounds. FIG. 10B shows exploded vies of one possible modular construction of a single ended PMTL connector for connecting PMTL's of 1-1 of FIG. 1B. As is shown in FIG. 10A, the connector is constructed by using a 9-20S (SCM) sandwiched between two 9-20D (DCM), and then sandwiched between two 9-20G (GCM). FIG. 10C shows a 3D view of one possible connector made in this manner for a single ended PMTL transmission line. And FIG. 10D shows a corresponding connector made for a differential pairs of PMTL end to end connection. Some basic applications of such connectors will be shown later in the disclosure.

The modular connector concept introduced in FIGS. 9 and 10 can be manufactured using the current processes in the connector production, namely a combination of stamping sheet metals for the ground modules 9-20G, and a combination of insulator sheet cutting or stamping, with metal paint, or metal depositions and patterning, and a combination thereof to manufacture 9-20D, and 9-20S modules. Furthermore, traditional plastic molding with metal patterning, as well as a combination of needles pins, and springy connector capabilities can be utilized to provide the notch pin spring functionalities of the 9-15, and 9-14 membrane, and notch pin 9-11 and 9-12 mechanisms. These connectors modules and their assembled connectors therefore can be mass manufactured with low cost using existing manufacturing capabilities.

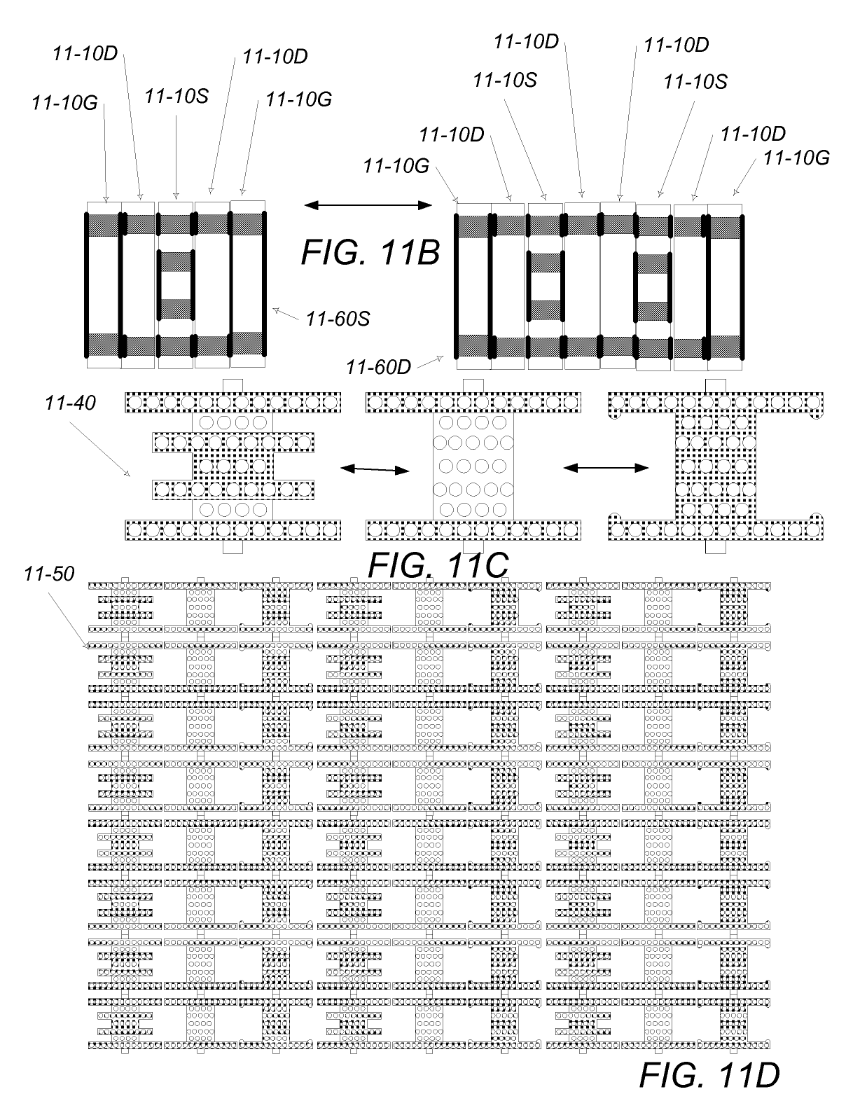

One other way to manufacture the continuity modules of FIGS. 9 and 10, is by the traditional photolithographic PCB processes. This is introduced in FIG. 11. We only need to manufacture the modules 9-20S (SCM), 9-20D (DCM), and 9-20G (GCM), in a desired PCB form factor. As one possible embodiments, we show the elements of FIG. 11A from top to bottom of the Figure as elements 11-10G, as the Ground Continuity Module (GCM), 11-10D as the Dielectric Continuity Module (DCM), and 11-10S, as the Signal Continuity Module (SCM) respectively.

On top of FIG. 11A, the ground continuity module 11-10G is shown in side view 11-50 to the left. It can be seen that it can be made from a dielectric laminates with two metal surfaces, normally copper. The front view of the connector resembles an “I” shape. The I shape is comprised of the stem 11-13, Top 11-15T and bottom 11-15B horizontal beams, notch-pin mechanism 11-11 TR, TL, BR, and BL, and central alignment tabs 11-9 on axis of symmetry. There are an array of PTH vias 11-16 rows and columns along the beam 11-15, and the stem 11-13 of the I shaped connector module to provide ground continuity between the two metal layers of laminate. On the side view, these ground continuity tabs are designated as 11-56 T and 11-56B. This element 11-10G essentially is a printed circuit implementation of the 9-20G element of FIG. 10.

The element 11-10D, shown in Middle of FIG. 11A, shows a way to fabricate Dielectric continuity module (DCM) using PCB techniques. All the elements of the I-shaped connector module are the same as 11-10G above, except that the metal pattern is different, as shown. There is no metal on the stem part of the I shaped element 11-13, but a similar NTPH via holes are provided for thinning the electrical effect of the insulator. So, the side view 11-51 shows the corresponding connector tabs 11-52T and 11-52B to provide continuity between the ground layers of the PMTL, in the similar manner as 9-20D provided.

Bottom section of the FIG. 11A shows the element 11-10S as the way to implement a Signal continuity module (SCM) using PCB processes. In this Figure, one can visualize a tall I and short I embedded in between. The metallization pattern is modified to provide the signal connectivity paths 11-14 in the central regions in the form of short “I”, while still provide ground continuity region 11-9T and -9B on top and bottom of the tall “I”. There is also the insulator region 11-18 with NTPH via 11-17 used for thinning the effects of the dielectric. The side view 11-52 to left shows the metal pattern 11-54 T and B for Ground continuity, and 11-14T and B for Signal continuity. Therefore, the module 11-10S provides the same type of ground and Signal continuity functionality as 9-20S in FIGS. 9 and 10. Note that central region 11-1 between 11-14T and -14B can be made with no metallization, thus providing a connector for the broadside differential PMTL 5-1 of FIG. 5A SCM.

11-53 at the bottom of FIG. 11A shows the bottom view of the continuity modules 11-10, G, D, and S. with a symmetry axis 11-54CL.

A strategic assembly of these modular elements provides various types of connectors. FIG. 11B shows two connectors developed from these modular sections. As shown on the left side of FIG. 11B, A connector for the Single ended PMTL is shown to be constructed from a 11-10S sandwiched between two 11-10D modules, which are then sandwiched between tow 11-10G modules, designated by 11-60S.

On the right side of FIG. 11B, a similar construction is shown for the differential PMTL connector. As it illustrates, two 11-10D elements are sandwiched between two 11-10S elements, which in turn are sandwiched between two 11-10D elements which in turn are sandwiched between two 10-10G elements designated by 11-60D. The connectors of FIG. 11B, can be manufactured using the multilayer PCB technology, in large panels and separated into individual connector or arrays.

FIG. 11C shows one possible arrangement of a three basic elements needed to construct the connectors 11-60S and -60D of FIG. 11B using PCB fabrication technologies, designated as 11-40. This pattern of 11-40 can be stepped and repeated many times in an array shown as 11-50, in FIG. 11D to provide a large pattern for PCB processing. This allows for mass fabrication of a large numbers of these elements in a single process. Strategically, these can be separated, or kept together with tabs in a linear strand, to be stacked and arranged as shown in FIG. 11B, to develop very large 2D connectors array. as will be shown later. For example, in FIG. 11D, all the columns represent a single element, from left to right, 11-10S, 11-10D, 11-10G etc. . . . which can be kept at columbes and stacked according to FIG. 11-B to construct large connector arrays very inexpensively, but with very high signal integrity and bandwidth. Many other variations of the mass production techniques can be implemented which falls within the scope of this invention.

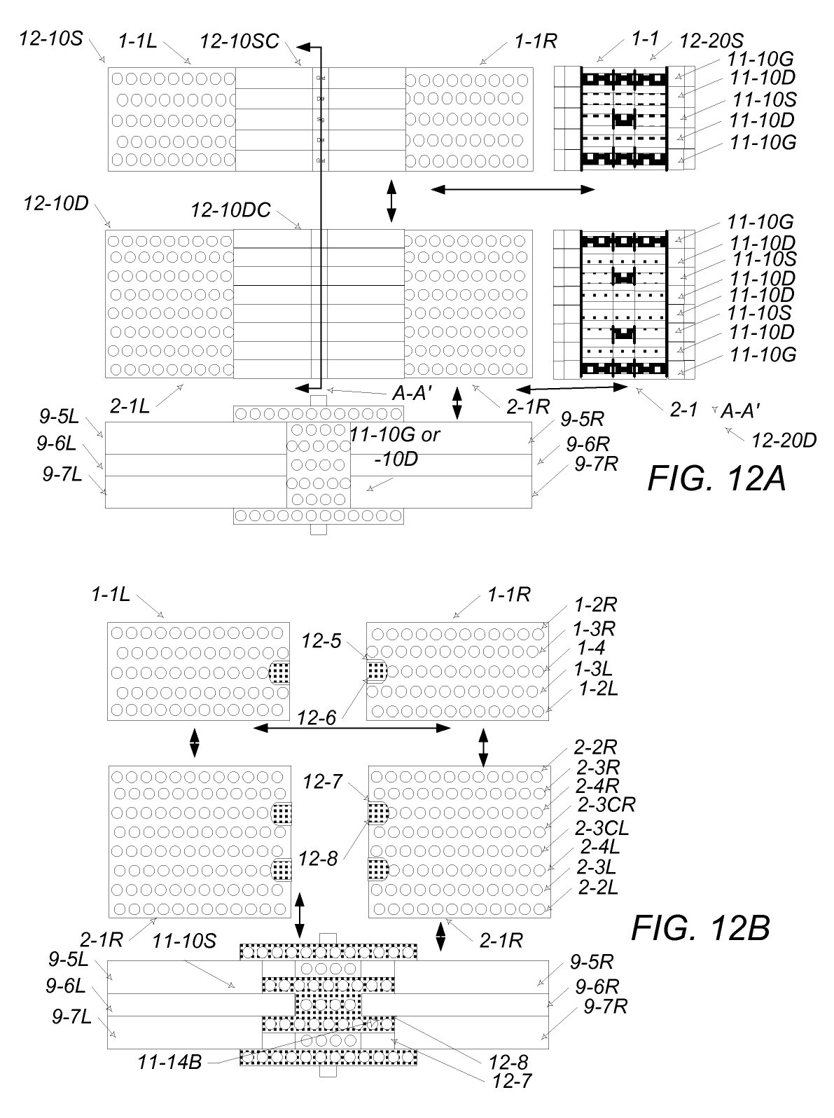

To further illustrate the modular nature of connector of FIGS. 10 and 11, we provide a couple of possible ways the connector can be used to connect two PMTL's together. This is shown in FIG. 12. In FIG. 12A top views of a pair of Single Ended PMLT 1-1L, and 1-1R connected by a central connector 12-10SC. The entire assembly is designated 12-10S, An assembly connecting a pair of differential PMTL lines 2-1L, and 2-2R, connected by a central connector assembly 12-10DC is also shown. This entire assembly is designated as 12-10D. At the bottom of FIG. 12A, a side view is shown for a typical module such as 11-10G ground module, with the stack 9-5,-6, and -7. To the right of the FIG. 12A, a sectional cut view of AA′ is shown to illustrate the sectional and modular nature of the connector and its relationship with the conductors and shield of PMTL, designated as 12-20S, and 12-20D for single and differential connectors respectively. As is shown, the assembly 12-20S comprises of continuity modules 11-10G, 11-10D, 11-10S, 11-10D, and 11-10G, and the differential connector module 12-20D comprises of continuity modules 11-10G, 11-10D, 11-10S, 11-10D, 11-10D, 11-10S, 11-10D, and 11-10G.

FIG. 12B shows a reduced version of the assemblies of FIG. 12A, except the central connectors 12-10SC, and 12-10DC removed to reveal a possible way of accessing the central conductors of the Signal regions of the 1-1 and 2-1 Single and differential PMTL's on the ends for interface to the connector assemblies 12-10SC, and 12-10DC, and specifically the module units 11-10S, and 11-10D. As is shown in FIG. 12B, the top view, in the central region, a cut out 12-5 on the top layer 9-5 is shown that exposes the central Signal strip 12-6. As it is illustrated, the PMTL 1-1 illustrate rows of vias 1-2R, 1-3R, 1-4, 1-3L, and 1-2L along the length of the PMTL, and comparing this view with that of FIG. 1B, one can see the linear arrays of vias geometries into and out of the plane of paper.

In a similar manner, in FIG. 12B, the corresponding case for the Differential PMTL is shown below the Single ended PMTL, with opening end cutout 12-7, to reveal the signal strip 12-8 which is then used to connect to the signal module 11-10S at both signal Pairs. Again, the array of the via along the length of the PMTL is shown as 2-2R,2-3R, 2-4R,2-3CR, 2-3CL, 2-4L, 2-3L, and 2-2L, corresponding to those via arrays whose cross sections are shown in FIG. 2. The bottom of the FIG. 12B shows the side view of an assembly for a cut through the 12-5 and 12-7 section to show the way the continuity module 11-10S connects the two strips 12-6 of 1-1L and 1-1R together, and in the same way those of 12-7 strips of 2-1L and 2-1R differential signal strips to establish signal continuity between the two corresponding PMTLs.

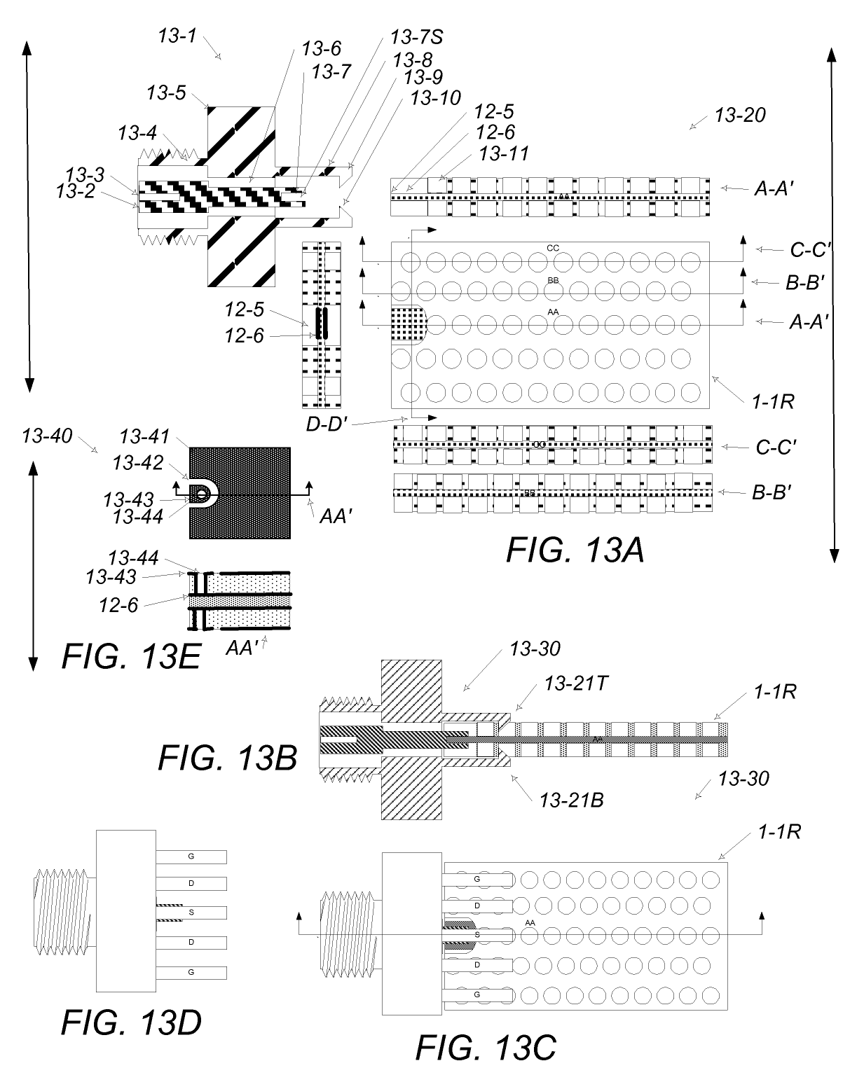

Now that we can connect any two like PMTL's together, as illustrated in FIG. 12, it would be useful to connect them to the coaxial connectors, as currently most high speed digital and analog and RF microwave connector are of coaxial nature. FIG. 13 illustrates one possible embodiment of connecting the PMTL to a coaxial connector. FIG. 13A shows the nomenclature of the two media to be connected. On the left side of the FIG. 13A, various elements of a typical coaxial connector is shown as the 13-1, comprised of the central conductor 13-2, with slit 13-3, the outer shield 13-4 threaded for mechanical fastening, the flange part 13-5 for securing it to the panels or chassis of PCB, assembly, On the other side of the connector, 13-6 as the insulator or dielectric support for center conductor 13-7, the slit designated by 13-7S. The 13-8 as the extension beam of the flange or extended out shield, and 13-9 as the notch and pin holding mechanism, with the pin 13-10 designed to snap snuggly in a matching hole 13-11 for mechanical securing of the Flange to PMTL.

The right part of the FIG. 13A shows the typical Single ended PMTL section such as 1-1R. The side view to the left shows the view of a DD′ cut which illustrates the opening cut out 12-5 to allow access to, and the conducting strips 12-6. Also shown are three strategic sectional cuts AA′, BB′, and CC′ to illustrate the nature of the connectivity of Coaxial Probe to the PMTL and a mechanical means to securing the connection.

FIG. 13B shows the side view of the assemblies of FIG. 13A when the assembly 13-1 and the PMTL assembly 13-20 are engaged in one possible embodiment. 13-21T and 13-21B, show the nature of the snapping notch and pin hole to keep the assembly snuggly together.

FIG. 13C shows the top view of the assembly of the coaxial connector and the PMTL, and clearly illustrates the relative positing of the various coaxial probes flanges and AA′ cut is shown in FIG. 13B. The embodiment of the FIG. 13 is only one possible method of interface of PMTL to coaxial connectors. As it was demonstrated for a single ended PMTL, it is possible to implement this configuration for a differential pairs PMTL, with utilizing two such coaxial connectors one for each single strips.

FIG. 13D shows the top view of one possible embodiment of the coaxial probes with multi figures to allow connection continuity for each of Ground, Dielectric, and Signal regions without the PMTL.

Although the configuration illustrated in. FIG. 13 A-D suggest mechanical means to secure two media together, other possible means can be implemented such as soldering and providing solder pads on top or bottom areas under the pin, One way to implement this is to provide solder pads as shown in FIG. 13E. Instead of opening 12-5 cutout of FIG. 13A, a PTH via from the strip 12-6 can connect to a via pad on the surface of PMTL in a pattern matching the coaxial probe. Such a configuration is illustrated in FIG. 13E. various pin geometries for the coaxial line can be developed to accommodate this efficiently. Many variations of these are possible. To improve this type of coax to PMTL transition, it helps to provide semi-coaxial regions at the probe end and provide additional ground tabs of various shapes to ensure better impedance continuity and match. FIG. 13-F-G illustrates some possible embodiments. FIG. 13G shows a way to connect to differential PMTL via coaxial probes.

So far, we have illustrated how to connect two's PMTL's of the same kind, single ended or differential type, and also how to connect PMTL to the coaxial connectors and thus to the existing world of connector and cabling and instrumentation, mainly for backward compatibility. If however, the PMTL is to be used on the PCB materials such as FR4, and like, it would be necessary to provide connectivity to and from PCB boards as well as connecting various PCB cards together, such as Mother board, to daughter board, and mother boards to mother boards and backplane in various topologies.

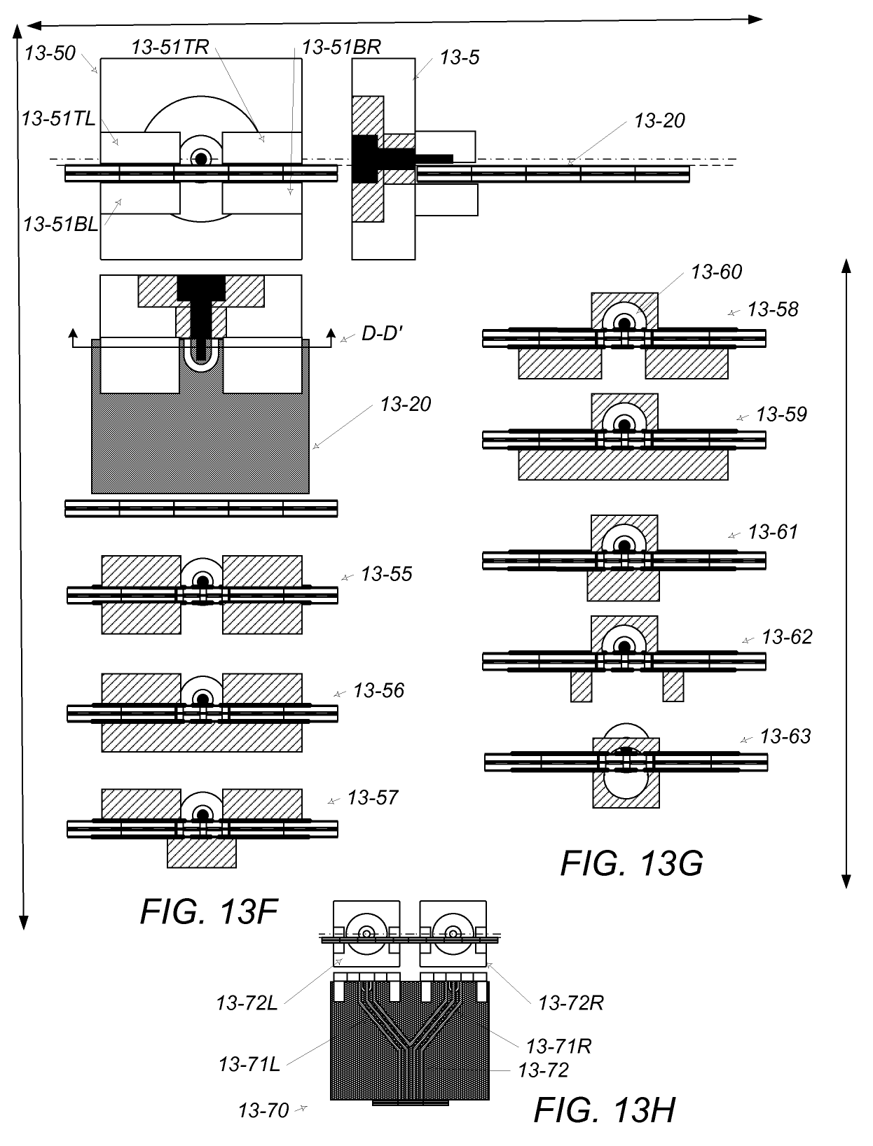

In order to achieve this, it is necessary to provide a practical footprint for PMTL connectivity on PC boards so that connections to and from it can be made using the existing manufacturing processes and practices. FIG. 14 shows some possible ways to implement this on a PCB. FIG. 14A shows the footprint for solder mask or pin/socket that can be used to connect a PMTL to the surface of a PCB assembly. On the left the 14-1D shows a pattern of via hole and pads as it would be on top view of a multi layer PCB board. As is illustrated, the differential pair can be accommodated generally by two via holes and pads designated by 14-2DP, and 14-2DN (Differential Negative, and Differential Positive. These signal PTH vias are surrounded by a pattern of ground vias 14-3D matching the shield of the target PMTL.

In a similar manner, the single ended PMTL can be accommodated by the central PTH via designated by 14-2S shown in the right of the FIG. 14A, and the surrounding ground via array PTH vias 14-3S. This foot print assembly for the single ended PMTL is designated as 14-1S. FIG. 14B shows the end view of a differential connector assembly 11-60D, and 11-50S, for differential and single ended PMTL as was illustrated in FIG. 11. FIG. 14C shows a similar connector footprints with a thinned out ground modules, i.e., using only a conductor sheet as the ground plane. This could be useful to make the structure of potential connector arrays to the PCB more compact. FIG. 14D, shows a supper posing of the patterns of FIG. 14A, and the PMTL connectors foot prints of FIG. 14B (or 14C), (14-20D and 12-20D Pairs, and 14-20S, and 12-20S Pairs) to illustrate that they can be matched precisely for the best signal and ground and impedance connectivity and continuity, thus providing a very viable technique to connect external PMTL's to PCB's. And since it is possible to implement PMTL in the PCB's, this techniques provides means of interface with PCB's with or without embedded PMTL's. Furthermore, existing PCB design tool, CAD, and layout, and manufacturing process can be used to design these PMTL elements into the PCB's, thus requiring no new or special changes to the design, and development, and manufacturing process, for early adaptation of the PMTL into PCB's.

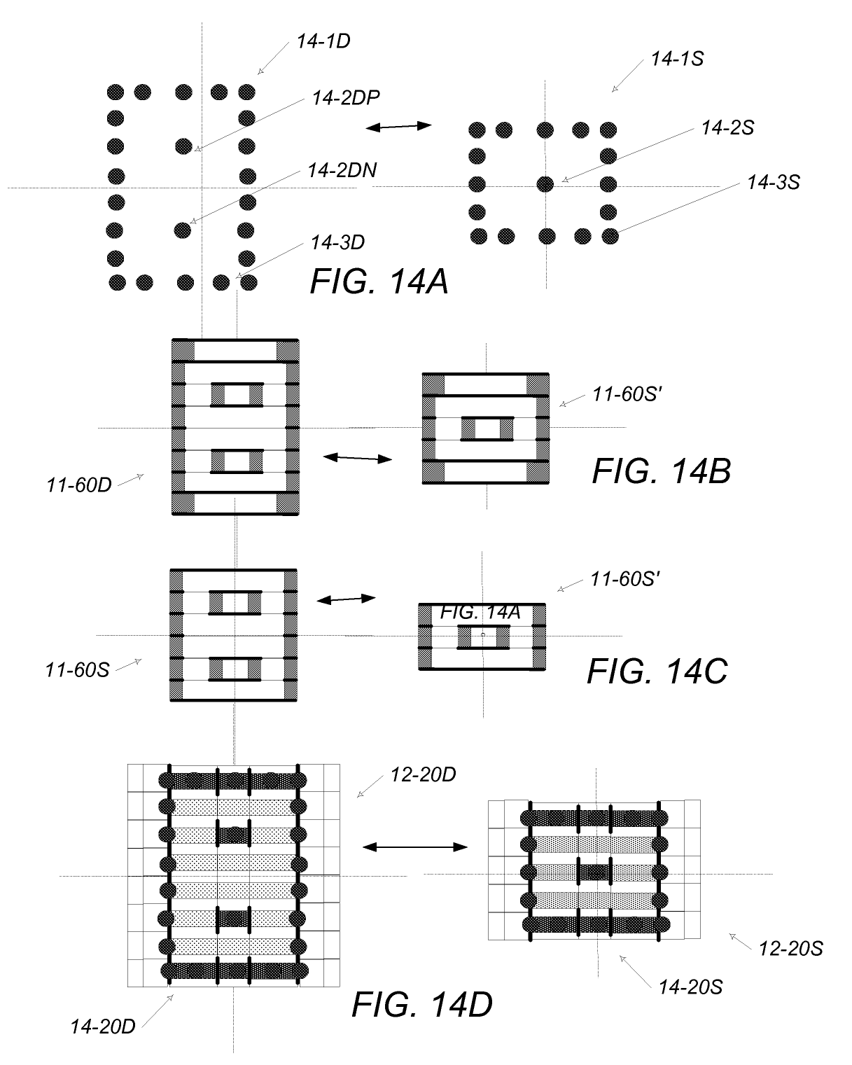

The PTH via and pad foot print presented in FIG. 14 show a way to directly connect PMTL's to surfaces of PC boards. The foot prints also provide a means to interface with connectors that we introduced in FIG. 9 through 12. But, in order to provide a connector interface for the PMTL on top of PCB (like a socket), one can use only half of the connectors mechanism that has been introduced, to mount on top of the PCB. FIG. 15A illustrates this. The PMTL connector modules presented in FIG. 11, are split in middle along the line of symmetry to provide only half of the configurations for the modules 11-10G, -10D, and -10S, for Ground, Dielectric, and Signal continuity modules, GCM, DCM, and SCM respectively. As these modules are assembled in the manner demonstrated in FIG. 11B, the resulting foot prints can be readily superimposed on top of PTH via patterns of FIG. 14. So, this method can be extended to any PMTL connectors that can be developed, including but not limited to those in FIG. 9-11 that has been demonstrated here, to provide very high speed PCB connectors sockets.

However, from a signal integrity point of view, it is insufficient to just provide connectivity from high performance PMTL, to low speed lines on PCB such as traditional micro strips and striplings or CPW. This will be analogues to driving a Ferrari behind a VW, in a single lane highway. This can be mitigated by implementing the PMTL in the PCB, and therefore providing end to end high speed performance with continuous signal integrity from source to destination.

An example of this is in the DDR3 memory board which connects to the PC board mother board via a 240 pin connector socket. So, even if the performance of the DDR3 module is improved, the bottle neck will be the connector socket that is used to mount the DDR3 board on the motherboard. This is why development of PCB based PMTL and connectors are very critical in realizing the full potential of wide bandwidth and high speed provided by the PMTL technology.

So, one of the impediments to realizing the higher speed connectivity on the PCB and for that matter, on CMOS is the lack of high speed wide bandwidth vias. So, here we introduce the basic principal of the PMTL technology to implement much more predictable and much higher speed via holes across the stack of multilayer PCB's. With this 3D via technology we develop VMTL, Vertical Micro Transmission Line technology, with vertical coaxial-like TEM propagation, no matter how high the stack may become, the transmission of signal from any layer to any other layer on the stack will perform to the full bandwidth supported by the printed PMTL embedded in the PCB. This unifies the end to end connectivity with highest signal integrity.

FIG. 15B illustrates one possible implementation. As it has been mentioned previously, the most ideal and wideband transmission lines are those that behave in dominate TEM mode and that can be designed and implemented in accordance with the Heaviside condition which governs the equalization of ratios of R/L and G/C, as mentioned previously. The PMTL achieves these objectives in a practical manner in which it makes applicable to current design, development and manufacturing process. As was mentioned, the loss mechanism primarily broken into the copper loss and propagation loss are controlled by geometry, topology, and in PMTL by virtually fattening of conductors, and virtually thinning of the dielectric, the former contributes to R and L, and the latter to the G and C, thus attempting to achieve Heaviside condition for optimal transmission lines, and as well as maintaining a robust TEM propagation Mode to THz frequency bands. Thus being able to accommodate sub ps rise time pulses and ultimately Pbps information throughput. All bottlenecked at the via holes and connectors up to now. VMTL provides the Vertical TEM propagation while PMTL provides horizontal TEM propagation, thus together enabling true THZ 3D interconnect.

In FIG. 15B, we use the same basic TCTD, principal of Thickening the Conductors and Thinning the Dielectric we used in development of PMTL to develop a Vertical PMTL-type via stack or a VMTL with same superior transmission performance. As it is illustrated, in FIG. 15B, the vias hole pad pattern of 14-1D and 14-1S are matched to the PMLT pattern in a first attempt to match, field, voltage and currents, and therefore impedance to provide low loss connectivity. It is necessary to take additional steps to improve this interface. One step is thinning of the dielectric which can be provided by an arrays of strategically designed and located NPTH vias along the path of the via and in parallel to the PTH vias. In FIG. 15B, these are demonstrated by vias 15-6V-m, and 15-5V-n vias array for the 14-1S and 14-1D via patterns for single and differential pairs respectively.

This concept can be highly generalized. For example, instead of using an array of circular vias, we can implement vias of various shapes and structures to achieve the same goal. For example, FIG. 15C, shows a similar 3D via stack with PMTL performance which uses and array of slots as shied. The same can be applied to signal and air vias, but not shown here, without loss of generality. Also, many cross sectional shapes are possible.

To demonstrate this concept for VMTL, consider FIG. 15D which provides an efficient vertical coaxial-like transmission across the stacks of multi layers of the PCB assembly. In fact, a coaxial type stack of the circular arrangement is shown in FIG. 15D. As shown, the PTH vias array 15-3S-n arranged in a circular pattern can be used as a coaxial shield, while the 15-2C can be used a center conductors (Obviously, could be more than one center conductor tied together, following the TCTD principle), and array of air vias circularly arranged 15-4V-m in between them serving as the dielectric thinners. A view of sectional cut along the AA′ of FIG. 15D is shown in FIG. 15E, which further clarifies the nature of the via stack, comprised of coaxial shield via array of 15-3S-n, and air vias array 15-4V-m, and center conductor via 15-2S. Also shown, along the vertical path, are via pads 15-28-1-j, -2-k, -3-p, etc. . . . , where indices j,k,p, etc. . . . represent array elements around the circular path in each layer. In each layers, all these via pads are tied together electrically in the form of circular ring to connect all circumferential vias arrays together, i.e., 15-3S-n, to improve TEM wave propagation. So, in this case, all the via 15-3S-n can be tied electrically by a single ring strip. In the same manner, for a configuration of FIG. 15B, the pads rings could be in shape of a rectangle to match the footprint of the 14-1S, or 14-1D of FIG. 14A (and FIGS. 15B and C). Although the center conductor vias are shown as a single via, they could also be an array, that can be tied together in the same manner in the same layers horizontally, and in vertical direction for best performance according to TCTD. In fact, this presents yet another way to achieve a wide range of impedances using this via technology, and or develop co-centric multi coaxial via lanes to transport high fidelity signals across many PCB layers efficiently. It is instructive to note that, the objective of building vertical vias cages is to emulate the best TEM axial transmission line, and therefore, any variations of the described embodiments of FIG. 15 will fall under the realm of this invention of the true VMTL technology. In a report entitled “Multi-Gig RT-2 Connector Routing, Report #22GC009-1, Mar. 26, 2003 v1.0”, attempts has been made to improve the performance of vias, without much understanding of the mechanism, in a brute force manner. The embodiments of 3D VMTL via structure here provides a true teaching of a coaxial-like vertical VMTL transmission lines implementation that can be designed to precise impedance and for any type of signaling, be it single ended, or differential or combination thereof that can revolutionize the interconnect technologies into a THz 3D, high speed, scalable, and unified interconnect system.

Now we further generalized this method. In FIG. 15F, we provide a couple of VMTL vertical transmission line stacks that can efficiently transmit a single ended signal and a differential signals from corresponding PMTLs in lower layers of the stack to higher layers of the stack with optimum signal integrity over very large spectrum. This mechanism essentially illustrates the vertical VMTL stack, of vias cage, comprising of an array of PTH surrounding an array of NPTH vias, surrounding an array of center conductors, as was shown in FIGS. 15D and E, and now will be illustrated in FIG. 15F. While taking advantage of the VMTL technology and the principle of TCTD (Thickening Conductors, Thinning Dielectrics).

As it is shown on the left side of the FIG. 15-F, the assembly of 15-30 illustrates the embodiment of a single ended VMTL vertical TEM via transmission line, and to the right of the FIG. 15F, assembly 15-40 shows the embodiment of one possible differential VMTL vertical TEM transmission line.

In the embodiment 15-30, the various elements of a TEM transmission mechanism can be readily identified with the embodiments already described previously. For example, the three sectional cuts, DD′, EE′, and FF′ will help to further illustrate the signal propagation nature of this embodiment, generally all vertical structures are VMTL and all horizontal structures are PMTL. At DD′, for example, the cross sectional cut view reveals a single ended PMTL such as that of 1-1 shown in FIG. 1B. The stack of 15-30 in FIG. 15F shows via array 15-3S, via array, 15-4V, and the via (array) 15-2C that corresponds to those VMTL in FIG. 15E. In fact, the cross sectional cut view of EE′ looks like VMTL of FIG. 15D (or right side of FIG. 15B for a rectangular pattern). Other elements of the stack are shown including 15-28-1-j, -2-k, and -3-p, etc. . . . designating array pads in different interfaces 1, 2, and 3 etc. . . . , and in each interface, and array of j, k, and p element surrounding the center conductor 15-2C. Continuing the path upward on the 15-30, we pass the signal bend to the left toward the cross sectional cut FF′, which takes the signal to upper layer PMTL type transmission line whose cross sectional view looks like 1-1 in FIG. 1B. So, the efficient TEM signal transmission from a lower PMTL, to a Higher level PMTL is achieved through vertical vias VMTL transmission line.

If we require a similar differential PMTL transmission path, for a PMTL transmission line type of 2-1 in FIG. 2. The embodiment 15-30 to the left of FIG. 15F can still be used, with two signal paths instead of one. Note that the same pattern can be followed for each signal path. In this case, the cross sectional view at DD′ and FF′ would look like VMTL 2-1 in FIG. 2A, and the EE′ would look like the view of left side of VMTL FIG. 15B And so a transmission of differential signal is achieved with great efficiency in a TEM mode, that provides no skew, i.e., the differential signal in the two conductors will have precisely the same length, and therefore the same time delay, which will provide great signal fidelity and integrity across the spectrum. In general, the technique presented so far will be readily applicable to strip line, microstrips, PMTL, of any type, of single ended, differential Pairs, or a multiple transmission lines such as those shown in FIGS. 3 and 4, 6, and 7 or of any type. However, some type of differential pairs or multi conductor transmission lines require signal flow on two different layers in this case skew could become a problem. We now illustrate a method that provides equal lines even for signal conductors on different layers of the stack. For example, if we require transmission from a transmission line such as that of 5-1 shown in FIG. 5A.

In the case of broad side differential pairs 5-1, of FIG. 5A, the embodiment 15-40 to the right of FIG. 15F can be used. 15-40 illustrates a PMTL via transmission line that connects two such PMTL differential pairs at different layers in the stack by a VMTL in between.

Starting at right of FIG. 15F, at the AA′ sectional cut, the PMTL differential pair 5-1 of FIG. 5A, is revealed. The top and bottom shield 5-6-T and -B, and the two signal lines on top of one another 5-8C, and -10C, establish the broadside differential signals. As the signal propagates to the left from AA′ it arrives at junction where it has to flow upward. The upward transmission line VMTL mechanism comprises of expansion of the embodiment of FIGS. 15E, and 15B or C, as in the sectional cut BB′reveals a pattern similar to those at the left side of FIG. 15B, or 15C, or a variation of FIG. 15D, with two signal conductors, PTH stacks, surrounded by shield PTH arrays and in between with array of NPTH via arrays used for dielectric thinning. These various elements can easily by identified in FIG. 15F, as 15-29 the shield PTH via array stack, 15-31 the NPTH via stack, the signal conductor PTH via stack 15-32, with an auxiliary NPTH via below its bend 15-33, followed by a another NTPH via stack 15-34, and then the second signal PTH via stack 15-35, followed by another array of NTPH via array, and then the 15-36, and finally by the another PTH via arrays shield designated by 15-37.

On top of the 15-40 vertical embodiments, other elements of importance are shown. On top of the signal columns PTH via arrays, to keep the continuity of signal and impedance, and lower the parasitic or eliminate them, strategic NPTH vias are placed as shown by 15-42, and 15-38. These NPTH via stack have their counter parts in the bend junction on the lower level too. As it is seen, the transmission line Signal make a left turn from vertical to horizontal toward CC′, these corner are designated as 15-41 and 15-39 for the two signal strips. These ninety degree bends will have some parasitic effects that can be mitigated by strategic use of the air vias arrays 15-42 and 15-38, and strategic dimensioning of the signal strips and PTH via columns as they join each other at the junction 15-41 and 15-39. The same techniques can apply to the ground shield bends too, but to a lesser extend. And the ground shield can also be strategically managed to provide an overall high bandwidth bend. As the signal moves to the left toward CC′, the signal has been successfully transmitted from a differential pair PMTL at AA′ through the vertical TEM VMTL via transmission line at BB′, to the differential pair PMTL on upper layers at CC′ represented by 5-1 in FIG. 5A. Thus the transmission achieves a very wideband, and high signal fidelity and integrity with no skew, or equal distance signal path for both signals of the differential pairs. This technology can be highly generalized to solve a very large class of signal interconnects problems to very large frequency range of up to THz, in a robust TEM mode of propagation. It solves a very fundamental propagation problem of vertical and horizontal or generally 3D signal paths in highly dense PCB such as Server, router backplanes, and daughter boards, telecommunication routers, and switches with 100's of Terabits per second information throughput, as well as highly congested optical switching. As it provides the solution of bottleneck of copper based high speed signal flow and switching, in PCB and in CMOS devices. This technology solves these problems without requiring any new process changes in the practices in photolithographic PCB fabrication or CMOS. It can be completely implemented in large scale using existing design, development, testing, and manufacturing systems. Additionally, the 3D via VMTL technology is not limited to the advanced transmission lines introduced in the disclosure, it could be implemented for any of existing and popular transmission line in practice, such as microstrip, stripline, CPW, GCPW, slot line, edge coupled differential pairs, offset differential Pairs, and any transmission line that requires vertical high fidelity signal flow can benefit from this technology.

FIG. 15-G shows the nature of connecting a daughter board 15-25 to a mother board 15-27 using a proposed PCB connector 15-26. 15-26 can be an implementation of FIG. 15A. FIG. 15G illustrates how various embodiments of connector can be used to interconnect a daughter board and a mother board. For example, at the junction 15-25J of daughter board with connector 15-26, the elements of FIG. 15A are used for the hosting the edge of the vertical daughter board 15-25 into the slots of the Connector mechanism 15-26. At the junction of the connector 15-26, and mother board 25-27, designated by 25-26J, the foot prints of FIGS. 15-B, C, and D can be used. And directly below the junction 15-26J, the TEM VMTL 3D via structure of FIG. 15E stack, can be used, to provide a continuous, and high integrity signal connection from one board to another. This same concept will be used to connect many more modules together as will be shown later. FIG. 15H shows several more embodiments of a generalization of the VMTL technology. One skilled in the art can readily identify the embodiments of FIG. 15H, 15-50 as a single VMTL structure, with annular pads, and 15-51 one with ground plane opening, all single TEM vertical Coaxial-like TEM channels, and 15-52, as differential twin-ax VMTL, and 15-53, as a combination of two Single ended VMTL channels (like 15-50) embedded within a Differential channels (Similar to 15-52), thus providing a composite VMTL channels of two three lanes, two Single Ended, and one Differential Twin-axial mode. 15-54 shows yet another possible embodiment of a composite multi lane VMTL channel with a central VMTL coaxial TEM mode (similar to 15-50), and another co-centric outer coaxial channel mode, thus establishing at least two VMTL channels, and 15-55 further illustrates yet another possible four lane VMTL channels, of four Single ended modes, as a quad axial VMTL channel, or two orthogonal differential modes comprised of diagonal channels driven against each other, as in quad-axial lines. Although we have illustrated only a few representative examples here, one skilled in the art can developed numerous variations of these embodiments that falls within the scope of this invention.

So far, we have introduced several transmission lines based on PMTL, and strategic connectors to connected to one another, as well as means to connect the PMTL to the current coaxial world through coaxial probes and connectors. We also provided means to connect the PMTL to PCB's directly or through connector sockets in the same manner used in practice to connect daughter boards to mother board, such as that of DDR3 memory module to a motherboard though thru a 240 pin socket connector. Similar to FIG. 15G. The connectors we have introduced has been primarily in a plane substantially orthogonal to the PMTL plane mainly because we wanted to divide them into Dielectric, Signal, and Ground region continuity modules for developing a very large family of connector configurations. These PMTL enabled connectors are suitable for mass manufacturing at low cost but high performance of up to 220 GHz and beyond. This promises high signal speeds of multi 100's of Gbps in seamless fan out and fan in for the development of future high speed electronic systems.

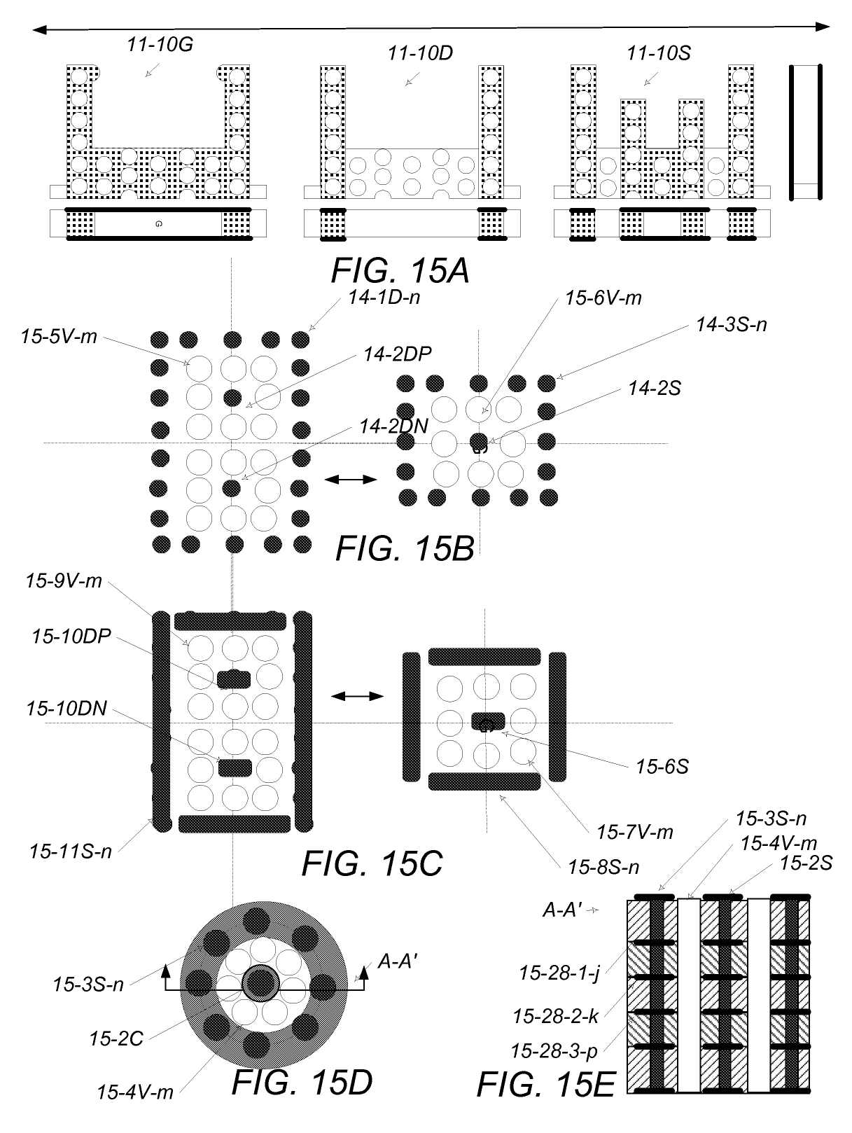

We now focus on a more natural end to end connector of the PMTL type and can be developed in the same planes of the PMTL, that can be implemented using PCB technology perhaps using new material such elastrometers that can be the bases of a new family of connector technologies. For illustration of these concepts we use a simplified representation of PMTL without the vias, without loss of any generality. FIG. 16 introduces such a family of connectors. For example, we can manage connecting two single ended PMTL types of 1-1 of FIG. 1B, in the manner illustrated in FIG. 16A, by truncating the upper and lower dielectric layers 1-7 and 1-11 in FIG. 1B at the end, and extending the central layer 1-9, with a strategic metal pattern as shown in FIG. 16A. As it is shown, the male end connector module 16-9J is comprised of layer 16-5, mid layer 16-6, and lower layer 16-7, with top metal layer 16-4T, and bottom metal layer 16-B, the truncation at 16-8, and central layer extension of 16-9J, the central metallization pattern 16-12J, and outer shield metallization pattern 16-11J and 16-13J, and with edge continuity conductors (Vertical) 16-14. Many variations of this is possible by use of strategic via arrays of FIG. 1, not shown here for simplicity.

The complementary part of the jack is shown in FIG. 16B, as a female type connector section 16-10 that accommodates the 16-9J extension into the slot 16-9P, The corresponding conducting strips 16-11P, and 16-13P grounds connect to the corresponding 16-11J, and 16-13J, and the center conductor 16-12P connects to Center conductor 16-12J in 16-1 to establish a perfect connection for two PMTL parts. The view of assembled parts 16-1 and 16-10 are shown in FIG. 16C, as the assembly 16-20.

This connector concept can also be expanded in two dimensions. First, a small variation of this connector can be made to accommodate differential pairs. Many other variations of this basic concept is possible. FIG. 16D shows one possible implementation of this connector concept that shows some snap on and latching capability to provide secure mechanical coupling. As shown in FIG. 16D, an assembly 16-30 of two PMTL with layers 16-5, -6, and -7 on the right and the left (R and L) can be connected with a module of 16-10 in middle, that is sandwiched between two top and bottom metallic or elastic material 16-15T and -15B, with a pin-like latch at ends designated by 16-13TL, 16-3TR, and 16-3BR, and 16-3BL, that snaps into the hole 16-4TR, 16-4TR, and 16-4BR, and 16-4BL, respectively. while, 16-9JL plugs into 16-9PL, and 16-9JR plugs into 16-9PR (Plug Right). This is shown in FIG. 16-E unplugged for clarification.

These connector concepts can be expanded to two dimensions for stacking in height, and side by side to develop a large array of connectors. The material selection for the plug can be made of hard PCB, and the jack center of elastic material that can be used to plug the two pieces together and engage and disengage with ease and high fidelity to provide impeccable signal integrity to very high frequency and data speeds. The connectors of FIG. 16 are also compatible with a PCB foot prints of FIG. 14, 15, to be able to develop PCB sockets and connector strips for interconnecting daughter boards, motherboards, and modules such as 240 pin socket for DDR3 memory cards and modules similar to them.

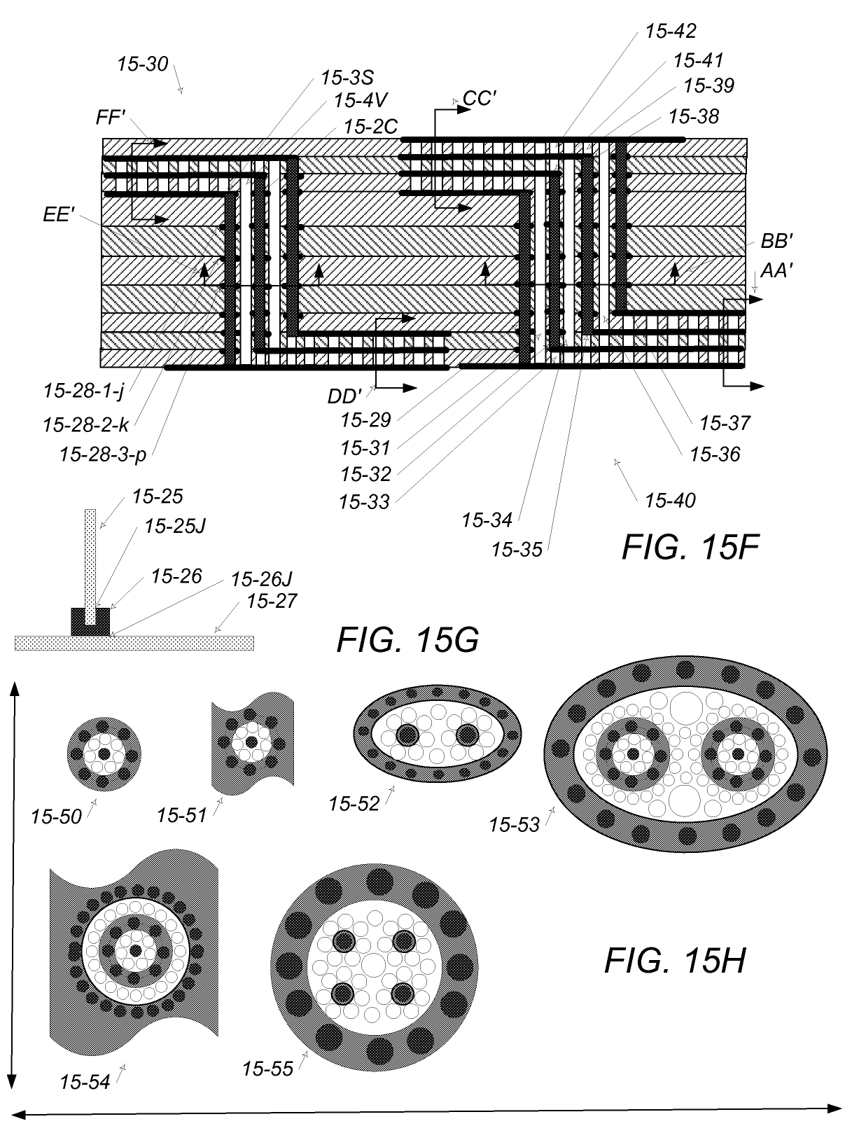

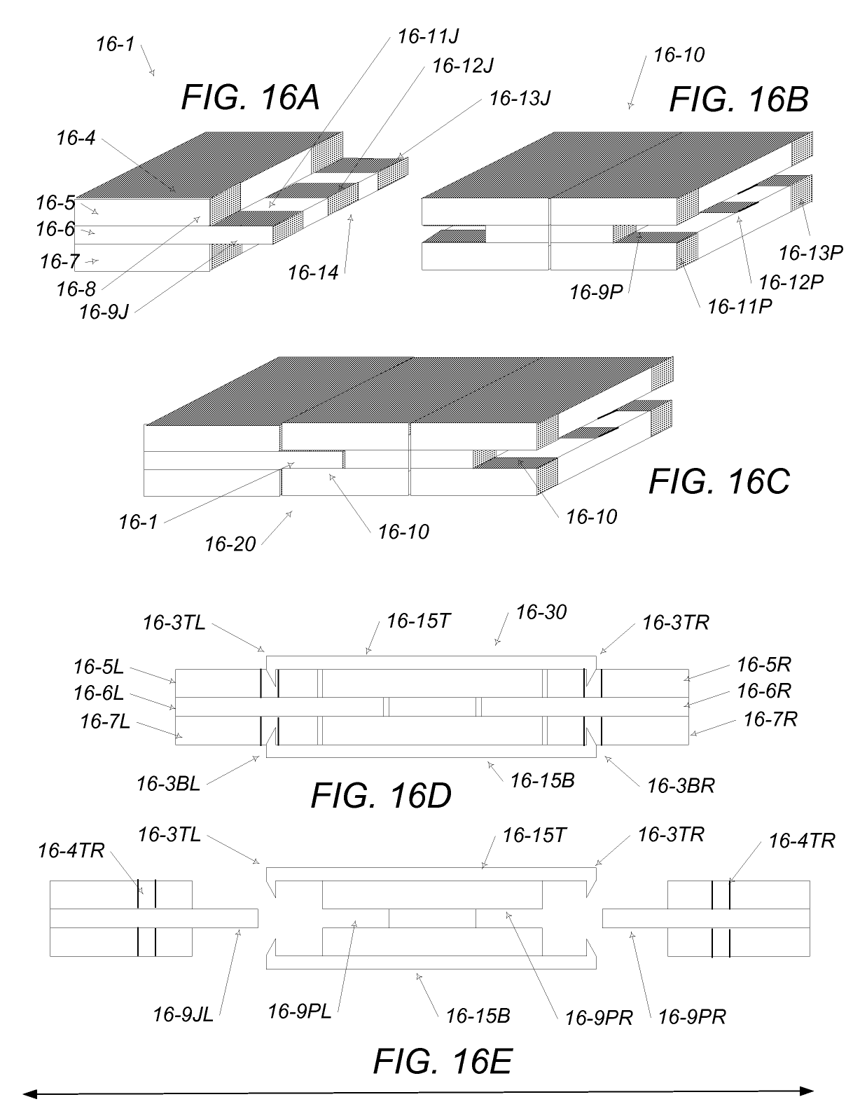

The arrayed foot print of such PMTL connectors are illustrated in FIG. 17. As is shown in FIG. 17, the array foot print of 17-1 illustrates an array of six differential pair PMTL-VMTL connection, foot print 17-10, shows a similar array of six single ended PMTL-VMTL, and foot print 17-20 sows a combination array of 6 differential, and three single ended PMTL-VMTL. The foot print 17-30 shows an array of eighth differential PMTL-VMTL with thin ground, thus providing higher connection density, and 17-40 footprints provide an array of six thin ground single ended PMTL with higher connection density, and any combination of these configurations of FIG. 17 are possible. So, with these footprints, and the knowledge of connectivity to PCB, many connections and connectors can be developed for the PCB's. One possible combination of array of sockets and connectors and a possible topology is shown in FIG. 18 for illustration of applications of PMTL-VMTL connector technologies. FIG. 18 shows two mother boards 18-6-1 and 18-6-2 connected together by a PMTL edge connector socket array 18-13. Furthermore, FIG. 18 shows a number of daughter boards connected to the Back plane 18-6-1, including 18-5-1, and 18-5-2, the former through a special connector 18-11, with direct connection to the top of mother board with foot prints similar to one of or a combination of those in FIG. 17, and side connection to daughter board 18-5-1. Furthermore, the daughter board 18-5-2 is connected to the mother board 18-6-1 through a connector socket 18-12-1, on its center.

Two daughter boards 18-5-3 and 18-5-4 are connected to the mother board 18-6-2 through a top connector 18-12-2 and end connector 18-14 respectively. All of these assemblies are then stacked on top of another mother board 18-7, through a stacking edge connector array and socket 18-8. FIG. 18 illustrates only one possible combination of interconnectivity of very high speed signal lines of 100's Gbps on regular PCB's made from run of mill FR4 and its derivative that use PMTL-VMTL based transmission lines, and supporting connectors and arrays and sockets to route any high speed signal from any point to any other points of a topology of mother boards and daughter board backplane as it is normally the case for modern telecommuting switched router, and supper computers, and data centers and more.

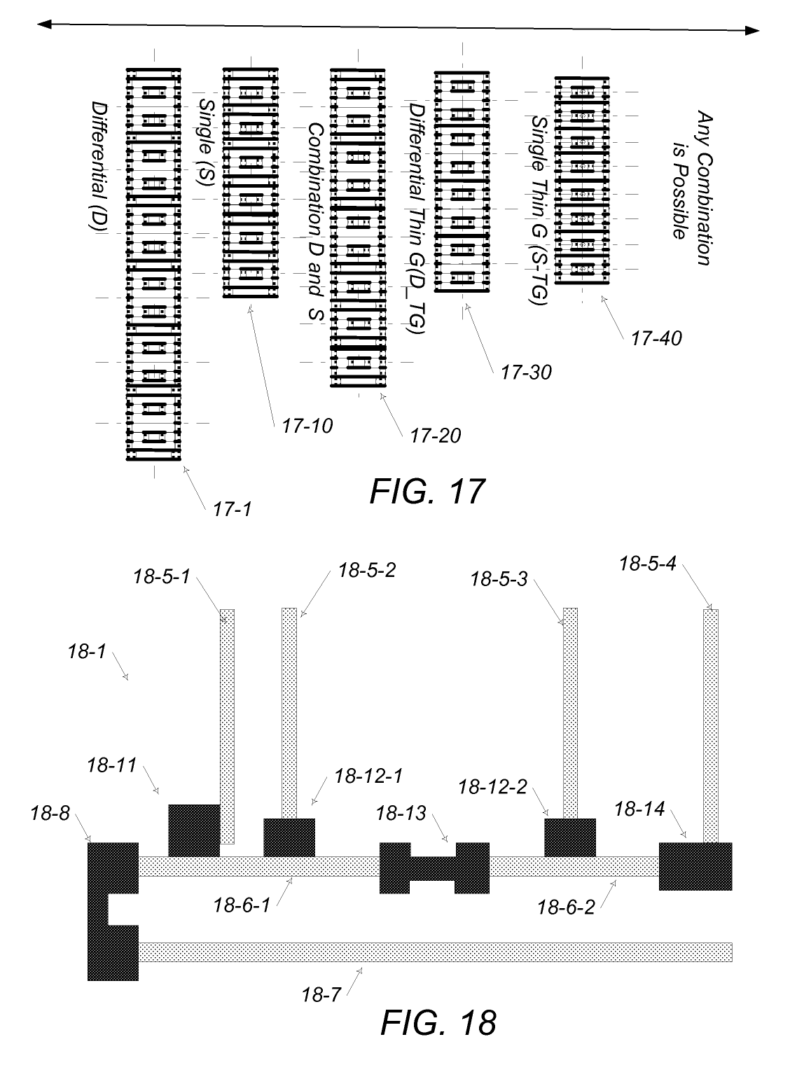

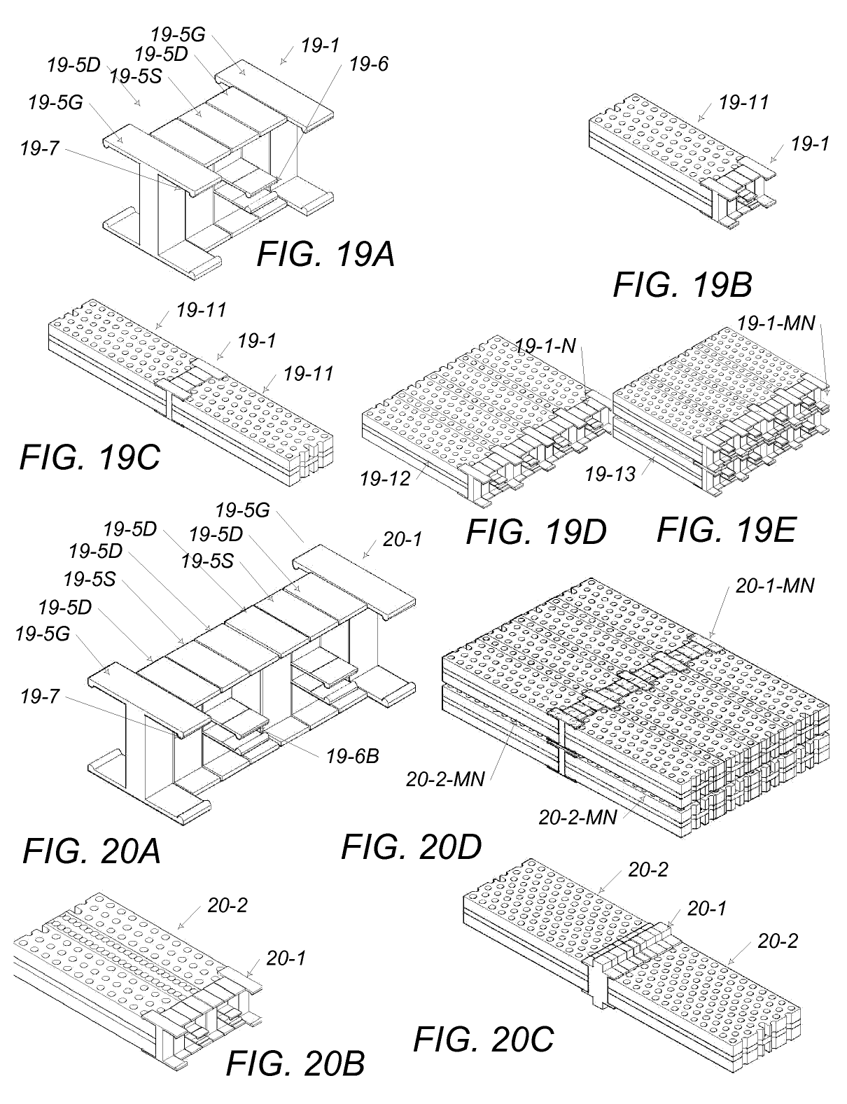

As FIG. 18 shows some examples of application of PMTL-VMTL technology on the PCB boards, and the possible interconnectivity, on hard substrate, FIG. 19 illustrates some possible interconnection and PMTL cabling on flexible and or elastic substrates to provide connectivity form system to systems and test instrumentation and other cabling such as Ethernet cable and data center connectivity. FIG. 19A shows an embodiment 19-1 of a end to end connector of a single ended PMTL, showing the various continuity models as 19-5G, -5D, -5S, -5D, and -5G, with center connector 19-6 and ground connector and snap on tab 19-7, the elements of this connector were introduced in FIGS. 9 and 10. FIG. 19B shows a connection of PMTL single ended 19-11 with a connector 19-1, and FIG. 19C shows the connection of two single ended PMTL's length 19-11 together through a 19-1 connector. FIG. 19D shows a linear array of single ended PMTL's 19-12 connected to corresponding linear array of connector 19-1-N, and FIG. 19E illustrate a two dimension array of stacking of FIG. 19D assembler into a stack of linear strips of SE PMTL 19-13, connector by a 2 array of SE PMTL connectors 19-1-MN. In the similar manner, the interconnectivity of differential Pairs PMTL buses is illustrated in FIG. 20.

FIG. 20A illustrates a differential pair PMTL connector 20-1 comprised of continuity modules 19-5G, -5D, -5S, -5D, -5D, -5S, -5D, and -5G. with signal connector tabs 19-6A and 19-6B. with snap on tab 19-7. FIG. 20B shows differential PMTL line 20-2 connected to a corresponding connector 20-1, FIG. 20C shows two differential PMTL sections 20-2 connected thought a corresponding connector 20-1, and FIG. 20D shows an array of differential PMTL bus 20-2-MN connected to 20-1-MN connectors.

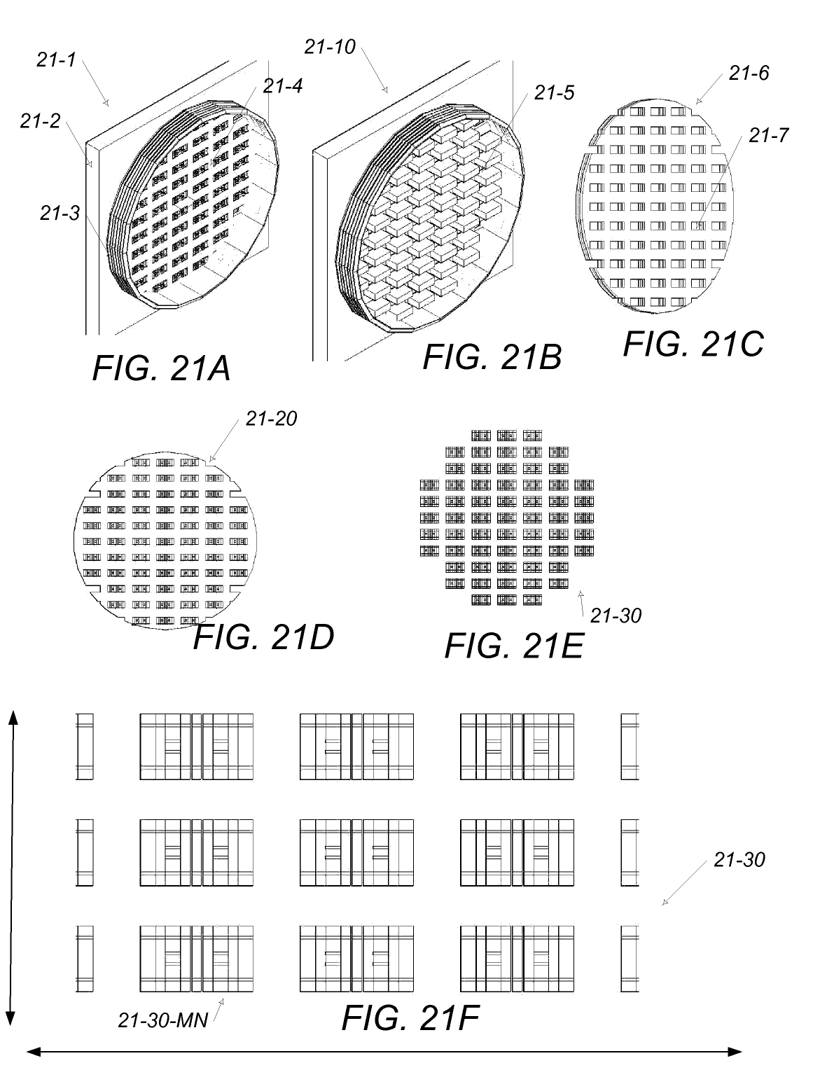

We have already provided several means to develop single modules of connectivity for various types of PMTL presented in FIGS. 9, and 10, and those using printed circuit boards, such as demonstrated in FIGS. 11 and 12, as well as means of connectivity to PCB boards as illustrated in FIG. 15, all of which follow the philosophy of, “divide and conquer”, by developing elemental units of continuities of Ground, Signal, and Dielectric, and yet another means of connectivity as illustrated in FIG. 16. We now demonstrate some further generalization of these concepts and embodiments to developing very large array of connectors, some adapting the existing form factor and flanges, and others with general 2D array of connections in a modular manner. FIG. 21A shows a typical round avionics type connector that traditionally carries a few (i.e., 9) twinax's ports, but is shown with at least 61 PMTL connectivity ports for differential ports. The assembly of 21-1 shows the square flange 21-2, with a round threaded mechanism 21-3 for mechanical coupling to equipment, i.e., a instrumentation panel in a avionic cockpit for example, Inside the circular opening there is an array of differential PMTL connector 21-4. FIG. 21B shows an alternative configuration 21-10, with male type elements connector by simply providing a section of appropriate PMTL shown as 21-5 which changed the sex of the connector. These connectors can also be made sexless. FIG. 21C shows internal part of the connectors with dual parallel grills plates 21-6 with an array of opening aperture 21-7 sized to strategically sandwich a matching array of connectors such as 20-1 in FIG. 20 to form the connector arrays of 21-1 and 10. This parallel plate grills 21-6 serves in a larger scale the action of holding the individual connector elements in place using the tabs of FIG. 9 elements 9-8L and -8L as the parts of parallel plane grill, and tabs 9-9 as the parts that is held in place between the plates 21-6. FIG. 21D shows a front view of the grills plate without the connector elements designated as 21-20. FIG. 21E shows the complementary view of connector grills of FIG. 21D, with only connector elements of the array, designated as 21-30.

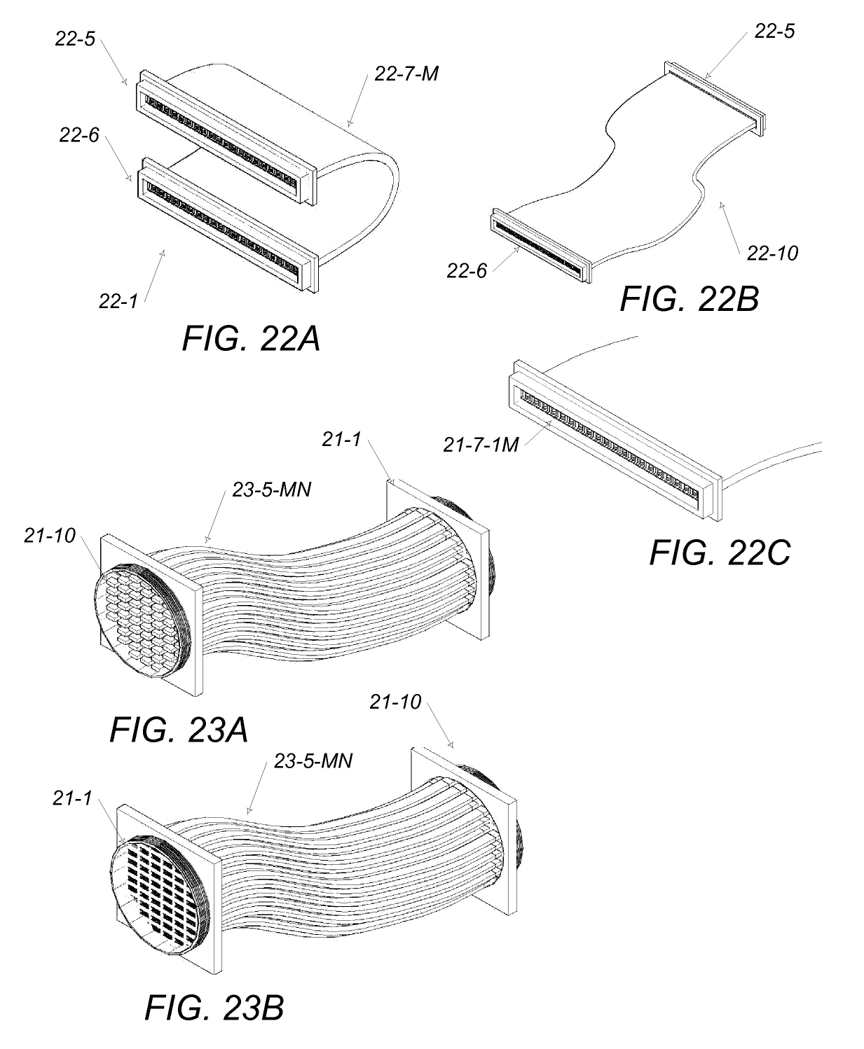

FIG. 21F shows a close up of a section of the connector of FIG. 21D showing a two dimensional array of differential PMTL connectors 21-30-MN, with similar elements to 20-1 of FIG. 20. Some variation of linear array connector are illustrated in FIG. 22. As it is shown in FIG. 22, a flexible bus of PMTL strands 22-7-M is terminated to two bus connector 22-5 and 22-6 on opposite ends. The assembly 22-1 can accommodate array of differential or single ended connectors or a combination thereof. This type of flexible bus can be used to connect a stack of two PCB's with embedded array of PMTL together in a similar manner as the connector 18-8 of FIG. 18, or alternatively jumper connect two areas of a PCB with embedded PMTL strands. Many variations of the bus of FIG. 22 are possible. FIG. 22B shows an alternative connector 22-10 for connecting two PCB's with embedded PMTL arrays together from one edge to another similar to the functionality provided by Connector 18-13 in FIG. 18, in a flexible manner. 22-10 can be twisted so as connector 22-6 and 22-5 are in orthogonal planes thus allowing interface of two PCB's in orthogonal planes. FIG. 22C shows a close up view of the connector array 21-7-1M, as a linear array of 1×M element connector for flexible PMTL bus and jumpers. This connector will be generalized to a two dimensional M×N connector array later.

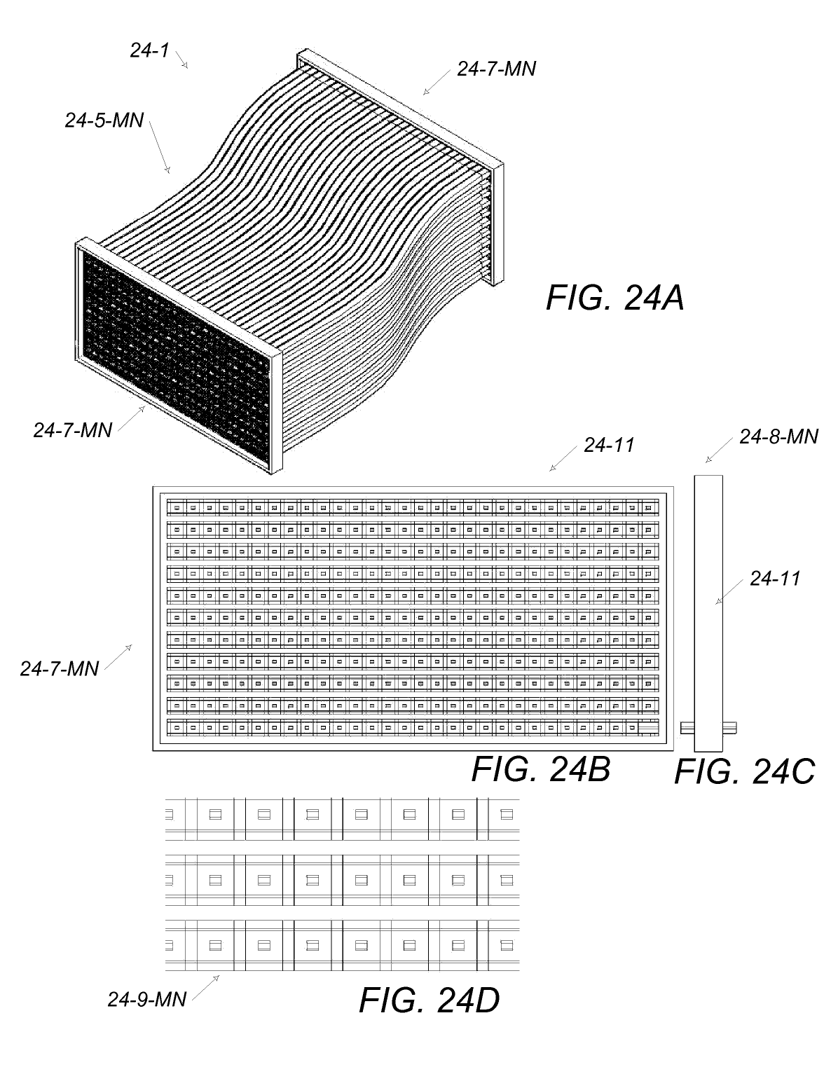

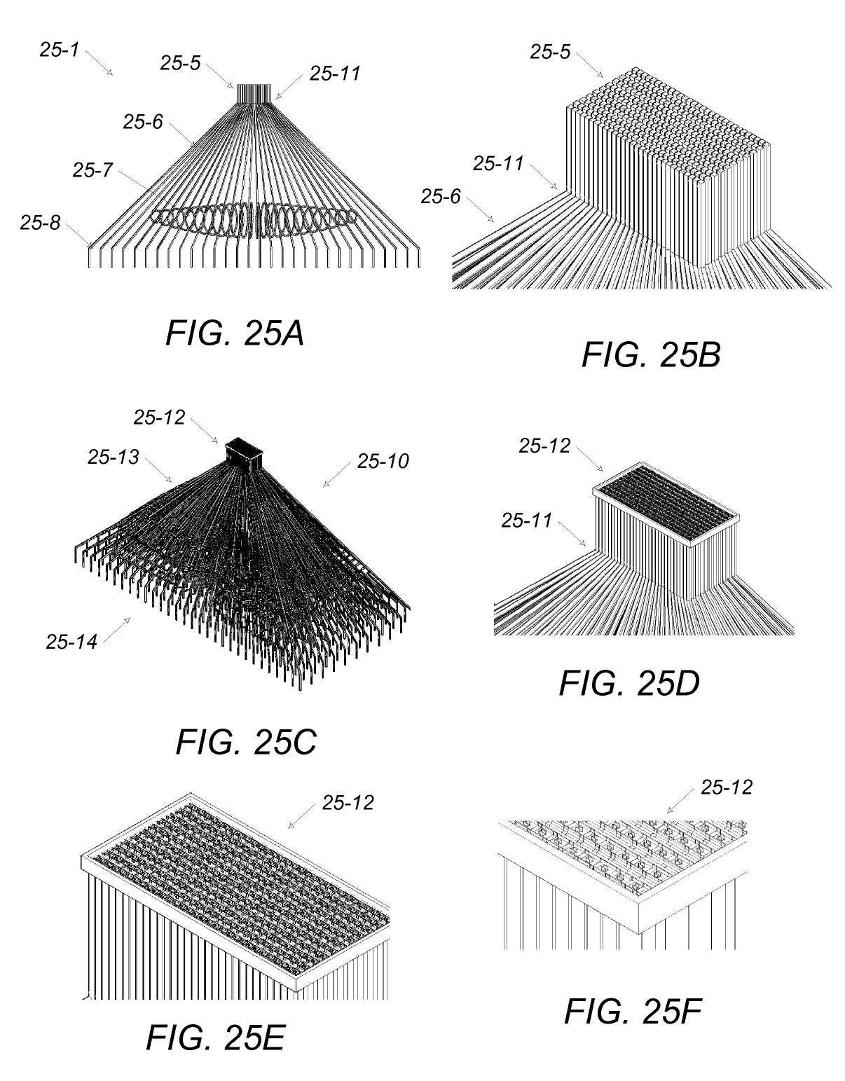

FIG. 23A shows a multi strand PMTL bus 23-5-MN that has the male connector array 21-10 and 21-1 female connector introduced in FIG. 21, on each end to provide a multi lane connectivity bus replacements for those already in use in avionics. FIG. 23B shows the same connector 23-5-MN, but the female connectors 21-1 and male connector 21-10 reversed on position that can show how these two can be coupled together in ends, a 21-1 to 21-10 to extend the length. FIG. 24A shows a generalization of two dimensional connector 24-1 of the linear connectors introduced in 22-7-1M, of FIG. 22, The two dimensional array of flexible strands or sheets (ribbons) of PMTL 24-5-MN. The connector array 24-7-MN on both sides of the 2 dimensional bus 24-5-MN can be used to connect a very large area of one PCB to another or provide a means for connecting test sockets to top of a ATE, as will be shown later. A front view of the PMTL 2D connector array 24-7-MN is shown in FIG. 24B that clearly shows the nature of the way the 2D connector is constructed, with a frame 24-11 (similar to 9-10 frame in FIG. 9) that hold the two parallel plate grill with connector elements in between together, and a side view 24-8 of just the connector is shown in FIG. 24C. FIG. 24D shows a close up view of some elements of the connector array, which shows that the elements 24-9-MN are single ended connectors, but can be single or differential or a combination.

We have demonstrated the ability and techniques to provide generally a very large array of connectors in two dimensions of a combination of single ended and or differential ended PMTL's and PMTL of many different types as has been introduced in this disclosure, as was shown in FIG. 24., we now provide at least one possible application and generalization of fan out and fan in connectivity that is highly desired in development of large scale system, as to provide connectivity to and from Micronics dimension electronic devices, to large scale systems of meters in dimension.

A useful fan out can be from an area of say 10×10 cm for example of top of an ATE to an areas of 1 m×1 m at the bottom of an ATE machine over a distance of about 0.5 meters. This is currently a requirement in automatic testing of semiconductor wafer, chips, packages, and devices that has many challenges.

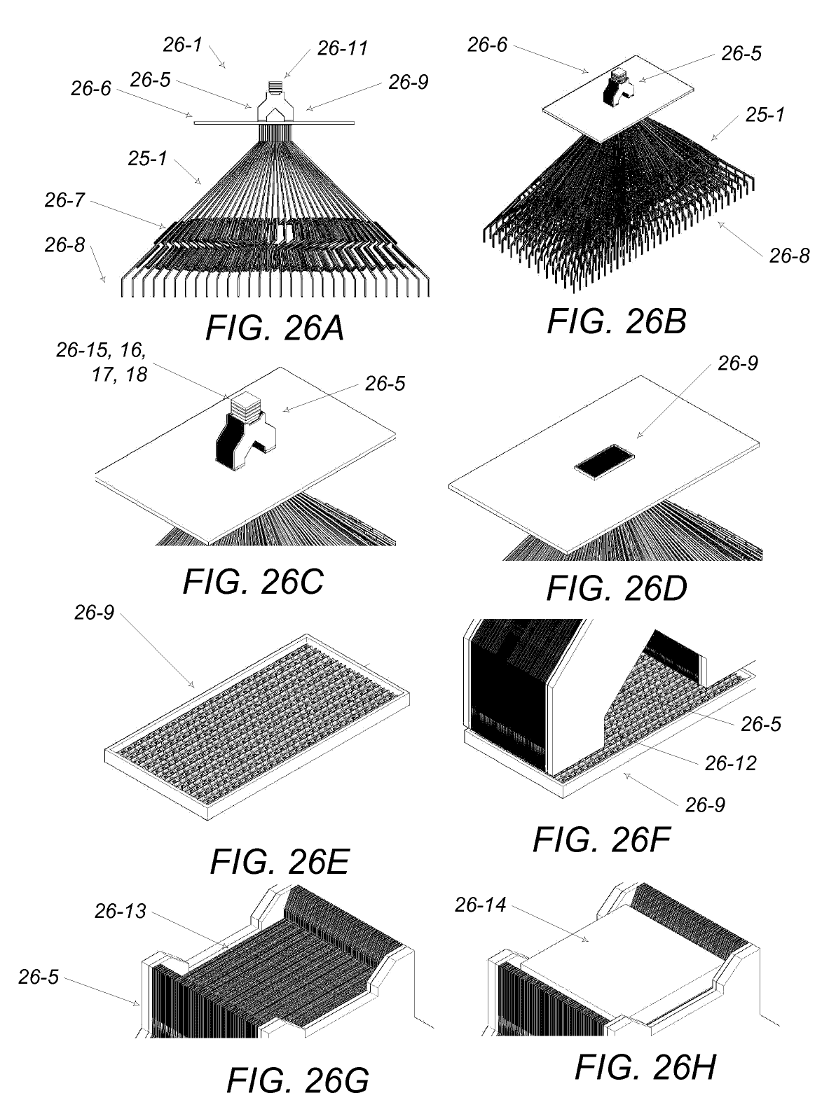

FIG. 25 shows a side view of a possible use of PMTL strands printed on a flexible materials with 10 cm width, of 30 closely spaced on top 25-5, and that can be separated into strands at the neck 25-11 and fanned out as shown by 25-6 into a wider area, i.e., from 10 cm to 1 m, 25-8. In the process of achieving this fan out from a smaller flat region 25-5 on top to a wider flat region 25-8, the strands of PMTL will have equal length to provide equal delay, but the strands near center must be bent or folded into a loop to accommodate the incremental lengths as compared to the strands near the edges, these loops are represented by 25-7, and the loops are larger in the center, become smaller towards the two ends, as become unnecessary at the edge. FIG. 25B shows a close up of the top of the regions 25-5 two dimensional area showing an array of 15×30 strands of PMTL, and the neck 25-11, where the strands are detached from each other and start to fan out as in 25-6.

FIG. 25C shows the fan out configuration of FIGS. 25A and B, but now with an integrated 2D connector arrays 25-12 on top, and fan out region 25-13. The assembly 25-10 shows the fan out of a smaller region on from an area 0.5×10 cm to an area 0.5×1 m on bottom 24-14 through the fan out region 25-13, over a distance of 0.5 m. FIG. 25D shows a closed up of the top region of the 25-10, revealing the connector array 25-12, and the neck 25-11. FIG. 25E shows yet another close up of the top region and connector 25-12(Similar to that of FIG. 24, 24-7-MN), and a further close up of 25-12 is shown in FIG. 25F, revealing the connector elements arrays similar to those of FIG. 24D. Note that for the same area of 2D connector array, the PMTL strands provides a much higher density of signal connectivity compared to equivalent size circular coaxial transmission lines, because of square shape vs. circular shaped of the cross sections.

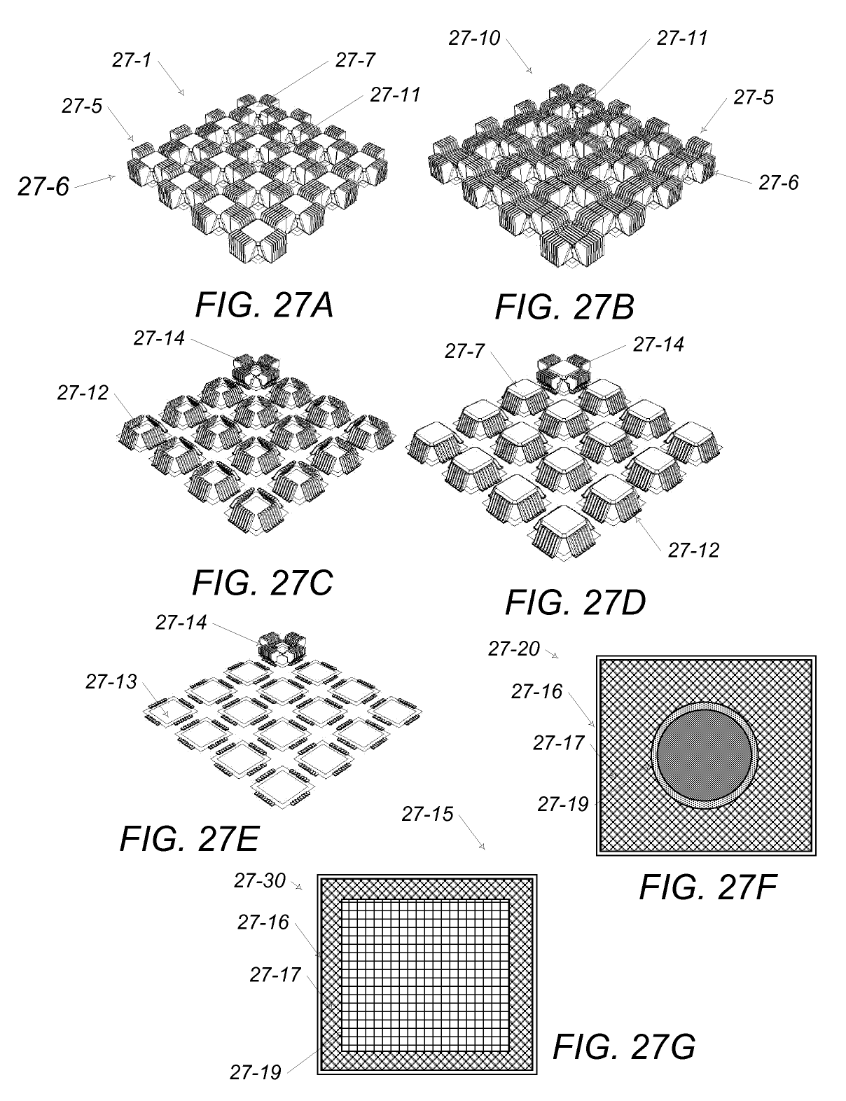

Now, as an example of application of fan out of FIG. 25, we present the embodiment of FIG. 26. FIG. 26A shows a front view of a possible application as it can be applied to ATE (Automatic Testing Equipment) and semiconductor testing equipment and process. If we separated the functionality of the ATE tower top or (sometime called test head) by the 26-6, anything above 26-6 plate is external to the ATE and below it internal to the ATE tower. Below 26-6 plate, is a fan out of all the required connectivity to signal at bottom 26-8 through the fan out mechanism 25-1 with delay equalization bends or loops 26-7. The bottom region provide interface with many test signals, including RF, differential pairs, coaxial line, control lines, that is required to support the test of a device or an array of devices, or chips, or wafers. Above the tower top 26-6, a test socket such as 26-5 is provided to connect to a tower top connector arrays 26-9. Top of the UTS (Universal Test Socket) 26-5, can accommodate a set of test devices DUT such as 26-11. FIG. 26B shows an alternative view of assembly of 26-1. FIG. 26C shows a close up of the top of view of FIG. 26B as it is shown, the test for DUT 26-11 can be comprised of a set of standard calibration components 26-15, 16, 17, 18, as the Load, Short, Open, Line, arrays as normally used in calibration of ATE and VNA's to bring the reference of s-parameters measurement to the device DUT interface.

FIG. 26D shows the view of FIG. 26C with the test assembly UTS 26-11 removed to show the top of ATE tower and revealing connector array 26-9. FIG. 26E shows a further close up of top of tower of FIG. 26D to show the nature of 2D connector of PMTL. FIG. 26F shows a close up of the junction of the connector of the bottom of 26-5, which matches connector of PMTL array at the bottom of 26-12 that mates with the connector pattern 26-9. So, at this junctions, all the signals of the ATE tower at 26-8 are brought via a fan in to the connector 26-9 on top, at 26-6, and is then connected at connector 26-12 at the bottom of the UTS 26-5, and then taken to the top of the UTS 26-5 to its top, as shown in FIG. 26G (Details of this UTS are disclosed in Izadian's previous patent Application), 26-13 where a similar array of PMTL connection array is provided to provide a matching pattern to the package foot print, for examples, a BGA ball pattern, or package device connection pad pattern, etc. as shown in FIG. 26H, and package DUT 26-14 is placed on the top of UTS 26-5 to provide testing connectivity from a very large equipment at large area 26-8 to a tiny devices such as a BGA packaged DUT. This example clearly demonstrates the powerful connectivity of fan in fan out necessary in modern electronic industry, which requires highest signal integrity with highest testing connectivity and fidelity across the spectrum. Something, the PMTL as a building block is designed to provide naturally across all boundaries.

Since PMTL and its variations can be printed almost on any type of material, i.e., hard substrates, soft substrate, flexible, and elastic substrate and mix and matched, this provides a unique opportunity for improving connectivity of various devices for test equipment and to provide connection fidelity. One example of such a required connection is for testing packaged electronic devices in a large scale for production. Currently, the ATE systems provide test signal connectivity, stimulus and response capture of test device, but encounter many issues of reliable connection across the required frequency spectrum with DUT's of miniature dimensions. The process introduced in FIGS. 25 and 26 can be extended to revolutionize this process and provide higher level of testing parallelism to the process and thus reduce time to market while reducing testing cost.

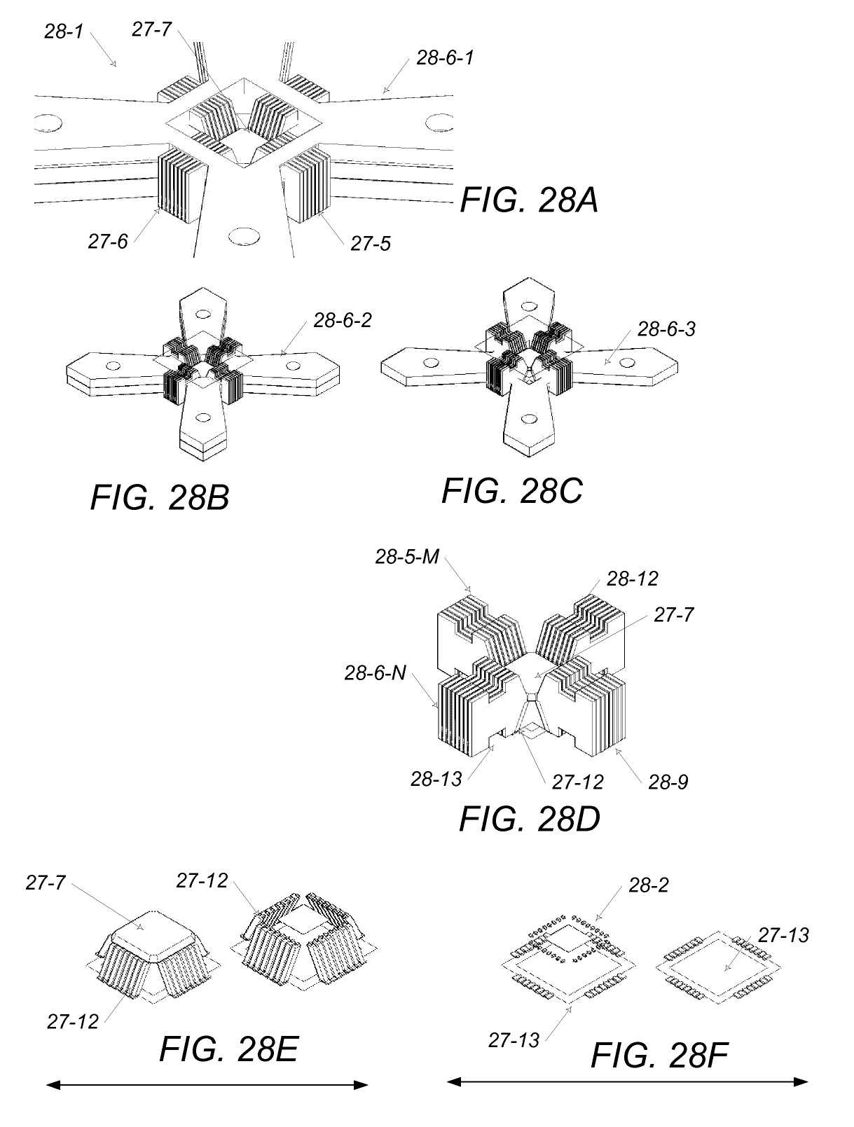

For example, FIG. 27A shows a 4×4 array of connectivity matrix for a 4×4=16 packaged electronic chips currently used for cellular phones which combines GSM, CDMA, and Blue tooth all in one. FIG. 27A shows connectivity to 4×4=16 devices at the same time, in the same foot print area as is currently used for a single such a chip, on ATE machines. The assembly 27-1 comprised of a interlayer arrangements of horizontal wafer cards 27-6 parallel groups and similar array of orthogonal vertical card families 27-5 with special open area 27-11 to accommodate the package DUT 27-7 in every junctions opening. 27-11. as shown in FIG. 27B. In FIG. 27B the package DUT's 27-7 are removed to show how the opening for the DUT are accommodated. The devices 27-7 would be placed by automatic robots on opening 27-11 equipped with connection pads that accommodate those of the DUT 27-7. FIG. 27C shows the wafer cards removed to reveal the connection mechanism 27-12 which are PMTL or some of its variation printed on the wafers 27-5 and 27-6. 27-14 shown one module using the orthogonal PMTL wafers cards in place for comparison of before and after removal. FIG. 27D shown the FIG. 27C, with package DUT 27-7 in place to illustrate the nature of connection of 27-12 array to the bottom foot print of DUT. FIG. 27E shows the connectivity footprint of pads 27-13 on the top of the ATE after connector bars 27-12 and DUT 27-7 are removed. One can imagine that all the connectivity to these pad arrays 27-13 at the top of ATE 26-6 is provided by the fan out mechanism 26-1. Many variations are possible. One possible alternative is the connecting to a wafer probe 27-19, through special connector device 27-16 with a fan in and from the edge and all area of connector 27-16 to the wafer probe elements 27-19. FIG. 27G shows another alternative of matching a connector 26-9 in FIG. 26D with connector array of PMTL 27-16 that is used to fan out connection to a region 27-19 that accommodates an array of devise of FIG. 27A-E.

Although, the connectivity of FIG. 27 showed from a bird's eye view of how to connect on a large scale to at least an array of 4×4 package devices, this concept can be further generalized to connecting thousands of DUT's simultaneously for testing for providing high level of parallelism in packaged device testing. We now focus on an individual package connectivity through a series of wafer cards that provide the bases for the wafer card 27-6 and 27-5 in FIG. 27, as a single socket of 27-14.

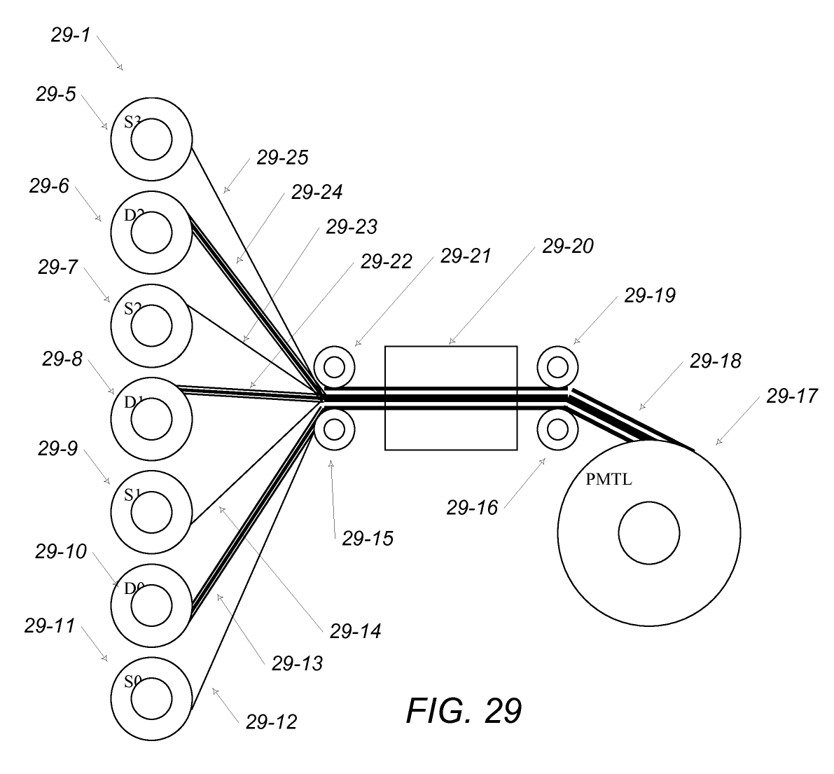

FIG. 28A shows a close up of central part of a Test Socket designed to test a CSM package with 32 connections on bottom edge of 8 pads on each side. The assembly 28-1 is comprised of an array of orthogonal vertical wafer cards 27-5 and 27-6, and with DUT package 27-7 in the central opening designed to house the DUT with corresponding connection pads. The 28-1 is comprised of at least three flange layers 28-6-1, -2, and -3 that is used to hold together the central orthogonal wafer cards 27-5 and 27-6 families. These families are comprised of an array of individual wafer cards of imbedded PMTL that serve to bring the signals to DUT 27-7 connection pads. FIG. 28B shows the wider view of FIG. 28A, with the top flange 28-6-1 removed. FIG. 28C shows the same assembly of FIG. 28B, with the second flange and alignment device 28-6-2 removed. FIG. 28D shows the close up of central part of FIG. 28C after removing the last flange 28-6-3, that more clearly shows the vertical and orthogonal family of wafer cards 28-5-M and 28-6-N arrangements, with DUT 27-7 in place. The FIG. 28D further reveals the notches 28-12 on top of the wafer cards, and notches 28-13 at the bottom of each wafer primarily used in conjunction with holding flanges 28-6-1, -2, and -3, that together serve to hold the entire assembly 28-1 together, and allow installation onto the test system. The embedded PMTL's that serve to connect the ATE test pattern pad to the DUT are also shown as 27-12 in FIG. 28D and FIG. 28E. FIG. 28E, shows the FIG. 28D with wafers 28-5-M, and 28-6-N removed to shows the DUT 27-7 sitting on top of PMTL connectivity fingers 27-12, to the left of FIG. 28E, and to the right of the FIG. 28E, the DUT 27-7 is removed to show the connection pattern 27-12. In right of FIG. 28F the PMTL connectors are removed to reveal the connection pads 27-13 on the test board, and the corresponding connection pads 28-2 for the DUT, and to the right of the FIG. 28F, the 28-2 pads are removed to show the connection pattern for a single DUT and socket 27-13 on the test board.

As it has been shown, the PMTL and its variations can be implemented in several media, CMOS, and PCB with hard substrates, and flexible materials. However, the traditional methods of manufacture of PCB such as photolithographic patterning and etching techniques are highly proven and the PMTL technology is designed to completely take advantages of design rules and process capabilities and process limitations that are presented by the existing manufacturing capabilities.

For a very large family of products with embedded PMTL, this will serve well. However, PMTL can provide many new products that can impact the current state of the art in manufacturing. For example, one area that PMTL will readily impact, is the connectors and cables. In the connector areas, we provide modular units that can be produced using the traditional manufacturing process, such as pins, plastic molding, and metal stamping, chemical etching and patterning, silk screening etc. . . . , as well as PCB processes. In the area of high speed cabling, such as coaxial cables, and twisted pairs CAT 5, 6, and 7, the extrusion method of manufacturing is dominant. These methods are old, reliable, and go back to steam age and perhaps before. Specifically, the twisted wire pairs used on the POTS (Plane Old Telephone Systems) goes back to time of Alexander Graham Bell. However, the PMTL has been designed and developed to take advantage of multi-layer material, and electronic manufacturing technology of modern era. It has been designed to provide impeccable TEM transmission medium with minimal impact on existing production processes.

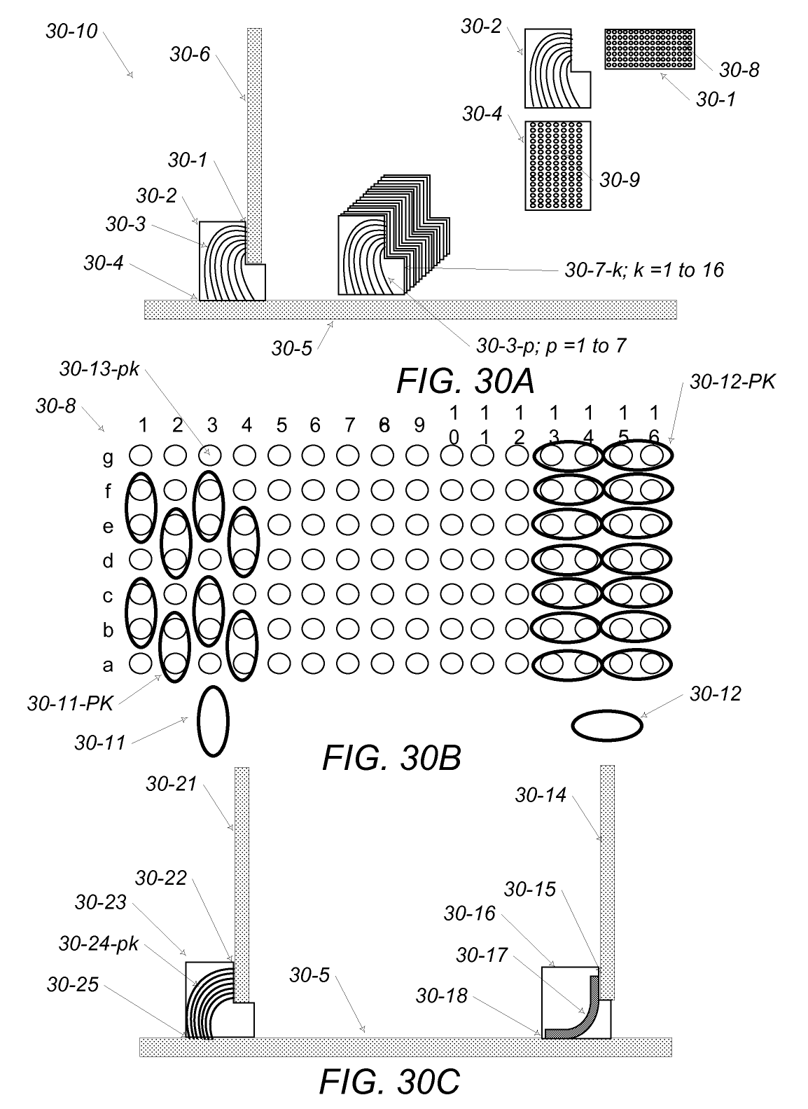

Production of PMTL enabled products merely depends on provision of strategic sets of materials, metallization, and an array of PTH and NPTH. The design can be at maximum conceived on four metal layers and three insulting layers. This opens up a very interesting prospect for mass manufacturing of CAT 5, 6, 7 Twisted pairs and coaxial type TEM transmission line on very large scale, to gradually displace the extrusion techniques. We will summarize in FIG. 29 such a Reel-to-Reel R2R process that potentially will take over on a great scale. It is believed that currently, there is tens of billions of meters of CAT 5 twisted pair Ethernet cable installation base in the world. With the advent of 10GBase-T and future 100GBase-T networking coming for data center of today and future, the numbers will only increase. Additionally, future copper based Ethernet cabling will require better shielding and lower losses, per unit length, and better way of mitigating cross talk, and connector families such as RJ 45 type evolution to accommodate higher and higher signal bits per seconds of multi giga bits per second on the routine. Twisted Pair PMTL introduced in FIGS. 6 and 7, and 8 have the greatest potential to be implemented not only in millions of high data rate back plane balanced line in the mother board, daughter board, and modules, but also provide the greatest potential to completely replace the extruded twisted pair Ethernet cables of today, with mass manufactured of R2R. These PMTL based Ethernet cables will use only 10% of copper due to TCTD method or virtually Thickening of Conductors and Thinning of Dielectric, used in the current CAT 5, 6, and 7, and shielding will come as a ready provision of manufacturing with no additional cost. Now we proceed to introduce the process of Reel-to-Reel manufacturing for the PMTL.

FIG. 29 illustrates one possible method of the manufacturing process of the PMTL. We first assume the objective of manufacturing on mass the PMTL 1-1 and 2-1 single and differential type lines, or a combination thereof. We can designate that in general these types of PMTL constructed on three insulator dielectric layers, D2,D1, and D0 (1-6,1-9,-1-11 in FIG. 1) and four metal layers we designate S3,S2,S1, and S0, as in (1-6T 1-8, 1-10, and 1-6B).

We then have some blind PTH vias like 1-5, and through vias stacks 1-2L and -2R, and NPTH via stack 1-3-L and 1-3-R, and smaller NPTH vias 1-4-T and 1-4-B. Well, these mechanisms are readily implemented using the CMOS and PCB fabrication processes. But, the PMTL only requires these basic elements to provide impeccable signal integrity that can be realized in any media. So, when one considers the requirement of manufacturing of PMTL in mass, any process that can provide the following capabilities will do.

NPTH holes along a simple path

PTH blinds along a simple straight path

Strips of conductors along the straight path

All in simple four layer stack.

That's all. These four requirements are readily implemented on a R2R process on a routine basis. As it is shown in FIG. 29, in the process 29-1, to the left, seven reels of or bobbins are provided from top left, reel 29-5, is a reel containing a metal strip S3, 29-6 reel contain rolls of dielectric material D2, reel 29-7 contains a roll of metal strip S2, 29-8 contrails rolls of dielectric D1, reel 29-9 contains a roll of metal strip S1, 29-10 contains a roll of dielectric D0, and finally 29-11 contains a roll of metal strip S0. The sheet of these materials are brought together in fan in to region between to strategic rollers 29-21 and 29-15, this includes from top to bottom, material sheets from their corresponding roll, 29-25, 29-24, 29-23, 29-22, 29-14,29-13, and 29-12, that will be pressed into a stack similar to that of FIGS. 1 and 2, as S3,D2,S2,D1,S1,D0,S0, stack of metal1, insulator1, metal2 insulator2, metal3, insulator3, metal4. the new multilayer material passes through a special box 29-20 that allows some required processing on the stack, such as pressing further, heat treating, patterning, labeling, drilling hole, and roll in between roller 29-19 and 29-16 as a stack 29-18 final product and rolled on the reel 29-17. This process can produce miles and miles of PMTL sheets on the same reel that can be cut into strip of multi PMTL buses, or separated for use. It is very simple and readily implements existing manufacturing processes.

The process of 29-1 presented in FIG. 29, is a simple representation of the basic elements, but many variations and simplification or generalization and process improvement can be implemented.

One possible variation maybe, that the center insulator layer 29-8, D1, first go through a single process where the top and bottom metals are patterned, drilled, and top dielectric 29-6, D2, and 29-10, D0, will be prepared with PTH, and NPTH holes, separately, then, the reels containing these products will be set in a process similar to 29-1 with only three reel on right, that contain the products D2,D1, D0, and compresses them into a single product sheet 29-18 and then onto reel 29-17. Many variations are possible.

Note that this process is highly versatile, so far we illustrated how to manufacture the PMTL's of FIG. 1B and 2A. But, the same process can be used to manufacture the PMTL's of FIG. 3, 4, as it would actually be easier since they only have three metal layers and two insulator layers, in the same manner, the stack of FIG. 4B can be sequentially manufactured just running two reels of PMTL of FIGS. 3 and 4A on top of one another. In the similar manner to FIGS. 1B, and 2, the differential pair of 5-1 of FIG. 5A and FIG. 5B are manufactured on mass.

So far, we have shown how to manufacture using a R2R process transmission lines which can replace any coaxial lines, there was no signal twisting required. But, the same process can be used to manufacture the twisted pairs PMTL's of FIGS. 6A and 6B. With simple current twisting providing by the zig zagging current implement in FIG. 6A, is just small variation from the R2R manufacturing process of PMTL of 1-1, and 2-1 and all those introduced in FIG. 1-5.

The manufacturing using R2R of twisted pair PMTL of FIG. 6B, may appear slightly more complex, but all the elements of its manufactures are present, the additional PTH via, and truncation of strips are readily achievable within the capabilities of the proposed R2R manufacturing process introduced in FIG. 29. So, manufacturing R2R in mass of that of FIG. 7C, is a great achievement, as it provides a mass produced CAT 7 printed circuit capability, with nearly only 10% of copper used for the present CAT 7 cables, in a quad lane Shield Twisted Pairs lanes (STP) or to make it like CAT 5, we can eliminate the via 7-2, and top, middle, and bottom ground 7-6-T, -C, and -B, and we have readily a replacement of Unshielded Twisted Pairs (UTP) cables using R2R planar technology.

In FIG. 8A we provided another type of Twisted Pair PMTL transmission line, as a combination of the use of technology of 2-1 embodiment of FIG. 2, and that of 5-1, of FIG. 5A, and those of embodiments of 6-1A and 6-1B of FIGS. 6A and B. This configuration too, since it is a combination of previously illustrated embodiment that we already know how to manufacture using the R2R process, can be therefore manufactured using the R2R process 29-1 of FIG. 29, or a variation of it.

Overall, therefore, we have demonstrated that all the PMTL's and its variations can be inexpensively manufactured on a mass production basis using at least one possible R2R process.

So, in setting up to upgrade the Ethernet cabling from those of the Alexander Graham Bell's era, we have developed a set of cables CAT 5, 6, 7 type, and corresponding connectors RJ45 type connectors that can replace all the old technology and provide better performance at lower cost for Ethernet connectivity of future, and backward connectivity to the installed base.

Now, we like to focus on several direct applications of the PMTL technology to the connectors, packaging, and Ethernet Cabling industries.

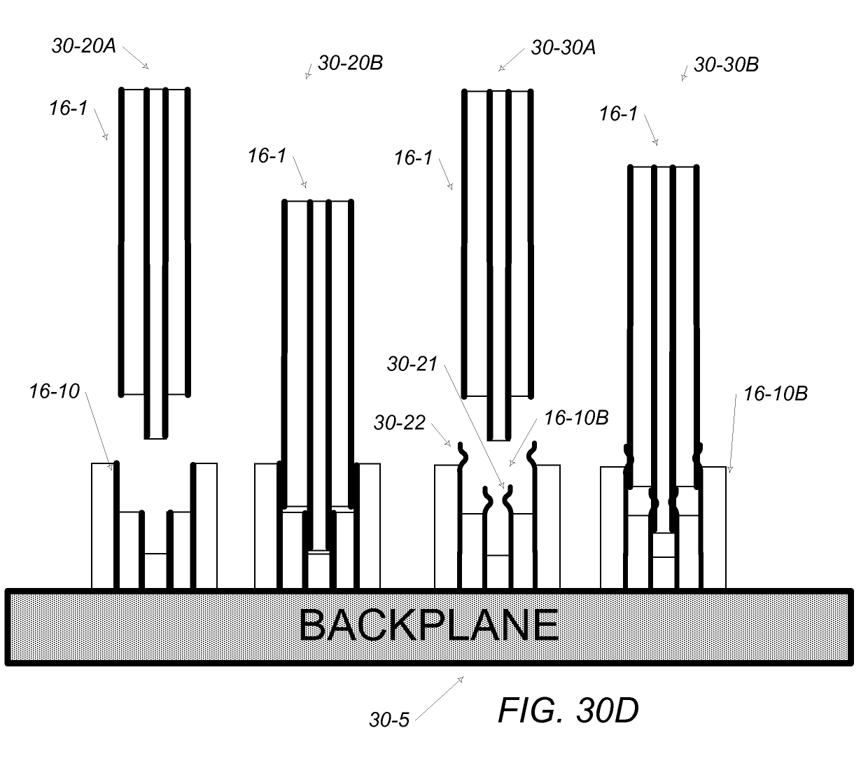

FIG. 30A shows an example of an existing connector technology known as the VITA connector standards. It is used extensively for connecting daughter boards to motherboards on many router and telecommunication switching backplanes. Here we show the PMTL base technology will make this standard even better by providing higher speed connections as well as eliminating timing skews from differential pairs, and generally using the same pin out foot print so that the new PMTL connector can be easily adapted for boards that have been designed for VITA connectors.

As is illustrated in FIG. 30A, a daughter board 30-6 is connected to mother board 30-5 using a VITA connector 30-2, the daughter board connected to the VITA connector at junction 30-1 and the VITA connector connects to Backplane 30-5 at junction 30-4. The VITA connector module has a number of parallel wafers 30-7-k, k=1 to 16, and each wafer card has a number of high speed transmission lines, namely single ended or differential pairs using CPW type transmission lines, designated by 30-3-p, p=1 to 7, for most cases. A 3D view of a typical 16 wafer card VITA is shown in the inset of FIG. 30A. Furthermore, to the upper right side of FIG. 30A, plan views of the this assembly is shown, The side view 30-2 shows each high speed transmission line from bottom to the top right as curved lines, to right, 30-8 shows the pin arrangement of 7×16 of a junction 30-1 the foot print at which the daughter board connects, and to the bottom shows the view of the foot print 30-9 at junction 30-4 is shown where the connector foot print to mother board is shown as another 16×7 pin out array. In this case all the high speed differential and single ended lines are confined on one wafer card, and since the differential lines are any two consecutive lines 30-3-p, and 30-30-(p+1), the two lines are at different radial locations, and their effective length is different to as much as 10 to 20 mils, and thus time skew is about 1.5 to 2 ps, at best, and could be worse depending on the location of the high speed line. This is better illustrated in FIG. 30B, where a large view of the 30-8 and pin out array is shown as 30-31-pk, p=a,b,c,d,e,f,g, and k=1, 2, 3, . . . , 16. The left side illustrate pairing of two pins connected to two high speed lines on each VITA wafer, with a grouping ellipse 30-11 symbol, and specifically each pairs as 30-11-PK, for example, in column 1, 1-fe, and 1-cb, is one differential pair, in column 2, 2-ef, and 2-ba, and so on . . . . Note, that each row represents a high speed line that is different in length due to the way the wafer CPW are printed at radial distanced. So, for any grouping of differential as shown with 30-11 vertical ellipse symbols, there is significant skew of nearly 2 to 3 ps.

However, if the grouping is accomplished by the horizontal ellipses 30-12, represented by 30-12-PK, to the right of FIG. 30B shows some of this type of lines with zero skew. This is highly desirable in high speed digital circuits especially as the clock rate become faster, and edge rates of digital pulsed move to fractional ps rise time. The PMTL ribbon connector technology to be introduced n FIG. 30C provides much better digital performance than any other in existence today, because of its design from ground up for high bandwidth and therefore high speed performance.

FIG. 30C shows at least two possible embodiments of a VITA type connector using the PMTL technology. In the right of FIG. 30C, a VITA type connector is shown to connect the daughter board 30-21 to mother board 30-5 using a VITA type connector 30-23 with PMTL enabled high speed flexible ribbon bus 30-24-pk, with junction to the daughter board 30-22, and junction to the motherboard 30-25, shown in FIG. 30B. Each ribbon 30-24, is indexed by p as the ribbon with radial location and bending each having k high speed PMTL lines in the bus. For example, each ribbon, provides 16 high speed line, for each of the rows a, b, c, d, e, f, and g on FIG. 30B, in contrast to the VITA wafer cards, where each card provides a column of 1-16 card each having 7 high speed lines, a,b,c,d,e,f,g. So, it should be apparent to the one skilled in the art, the PMTL VITA connector introduced here provide differential pairing 30-12 as in the right side of FIG. 30A, with no timing Skew, while the traditional VITA wafer with differential 30-12 provide skews of to 2 to 3 ps.

As the PMTL and VMTL technologies advances, it is possible to provide a 90 degrees shaped multilayer PMTL bus of form shown by 30-17, to the right of FIG. 30C, which is essentially a stack of ribbons 30-24, but all in one stack. In this case, at 30-15, a foot print similar to that of FIG. 30B is both on the ribbon and also on the daughter board 30-14, so, a connection is made between the two, also, at the junction 30-18, a similar matching pattern as in FIG. 30B is on the PMTL-VMTL bus 30-17 and Mother board 30-5, and thus a connection can be made to the mother board at this junction. All of this is packaged in a connector structure housing 30-16 which adheres as much as possible to the VITA foot prints for backward compatibility. The development of this type of skew less connecting from motherboard 30-5 and daughterboard 30-14 via the VITA type connector 30-16, can be achieved only by the application of the 3D via VMTL technology of FIG. 25G. So, this promises new advancement of connector technology that has never been possible before.

In addition to a positive impact on VITA connector technology and standard, the PMTL-VMTL technology promises significant performance enhancement to the DIP socket connectors of motherboard and backplane technology in use for DDR3 memory and DIMM packages. At least a couple of applications of the connector technology of FIG. 16 is demonstrated in FIG. 30D, one using a PMTL connector type of FIG. 16 using new elastomeric materials, and another using the conventional metallic pin based connectors.

As is shown in the left side of FIG. 30D in embodiment 30-20A, a board with embedded PMTL-VMTL 16-1 and 15-20, 15-40 can connect to a socket 16-10 on top of a backplane 30-5, as is shown in embodiment of 30-20B., as to the left of FIG. 30D, the embodiment 30-30A, shows a PMTL board 16-1 and PMTL socket 16-10B with springy pin tabs 30-22 for shield, and 30-21 for signal, and embodiment 30-30B shows the two units engaged thus connecting 16-1 to motherboard 30-5 through the socket 16-10B. The footprints of FIGS. 17, 17-1, -10,-20,-30, and -40, represent some possible embodiments of VMTL technologies illustrated in FIG. 15 as part of a backplane 30-15 in FIG. 30D.

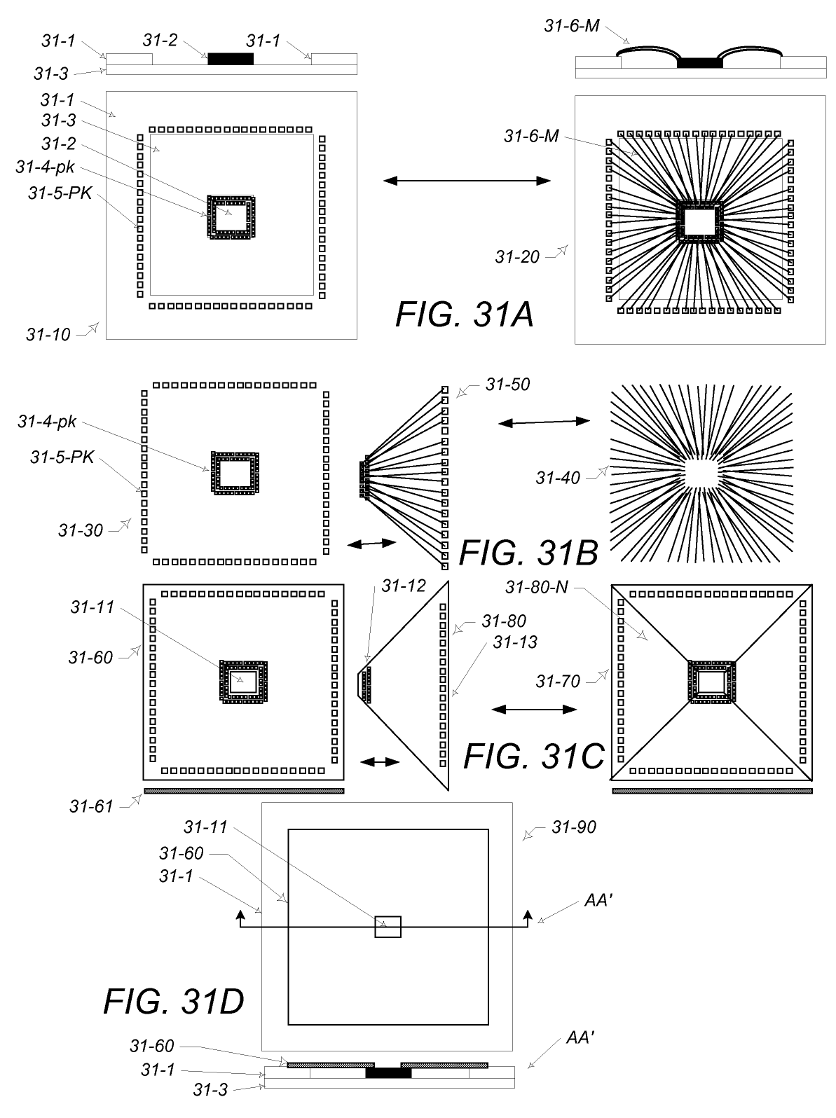

We now provide an application of the PMTL membrane technology to the package industry. FIG. 31A shows, to the left a side view of a typical chip 31-2 and package base 31-3, and package pad area 31-1, also the top view of this embodiment is shown with the bonding pad patterns on the chip die, and 31-4-pk, and the corresponding bond pad pattern 31-5-PK. To the right of FIG. 31A, the same package embodiment 31-10 is shown with wire bonds 31-6-M in place, This embodiment is designated 31-20. FIG. 31B shows 31-30, the die and package bond pad pattern 31-4-pk, and 31-5-PK to demonstrated that an efficient high speed fan out connection can be provided by PMTL membrane, to the center, 31-50 shows a fan out for just one side is shown, and 31-40 shows the wire ribbons that is necessary to connect the die to package. The PMTL membrane can accommodate this task very effectively.

FIG. 31C shows such a membrane with a fan out PMTL transmission line that provides the functionality of 31-40 of FIG. 31B, the membrane 31-60 shows the top view of the membrane with embedded PMTL with matching bond pad patterns of that of FIG. 31A in the package. 31-61 shows the side view of the thin membrane. 31-80 shows an alternative fan out sector wedge that can connect die pattern 31-12 to package bond pattern 31-12, and 31-70 shows four such 31-80 wedge membrane can be used to connect the four sectors of the package.

FIG. 31D shows a top view of a package which uses the single piece PMTL membrane connector 31-60 to connect the die to the package, and thus completely eliminate the use for highly problematic and difficult and expensive wire bonding. The 31-60 is shown flipped over the package, thus its back is shown. A sectional cut AA′ shown on the side view, demonstrates the PMTL membrane technology provided excellent connectivity, with much smaller profiles. This technology will help improving the packaging of dies and improve their performance to higher speeds that has not been possible previously. Among other things, this will help improve the performance of SiP (System in Package), and PoP (Package on Package), and other modern packaging topologies and with integrating VMTL and PMTL and membrane provide new possibilities packaging topologies, architectures for SiP and PoP, MSP which would provide interconnectivity between modules not only through PCB's and core, and 3D vias, below but also membrane signal highways bridges above, and provide a true 3D package system, all falling within the scope of this invention.

Finally, we come to the examples of applications to Ethernet cabling, such as the 10GBase-T and 100GBaset-T. The traditional 100Base-T Ethernet has been using the CAT 5 Unshielded Twisted Pairs (UTP) and the RJ45 connectors. But as Ethernet speed increases, these old technologies will be limited. New technologies are necessary to provide connectivity for 10GBase-T and the future 100GBase-T. For these applications, CAT 6 and 7, are in development to provide Shielded Twisted Pairs (STP), and better shielded RJ45 type connectors. However, these cables use a technology that was first used by Alexander Graham Bell, and have not change much since. These cabling use extrusion manufacturing processes, and use a great amount of copper, and so they are very expensive. The PMTL Twisted pair technologies introduced in the invention, provide not only transmission line cabling which use a modern R2R manufacturing technology for mass production, but promise to use only a fraction of the copper, namely estimated 10% of the copper. Additionally, the embodiments presented here can provide shielding and twisting at no additional cost, and as part of the manufacturing process. So, this makes them very attractive for the 10 G and 100 G Base-10 Ethernet cabling of future. In addition, the same PMTL connector technology can be implemented that can develop in the next generation RJ45 type connector with built in shielding, as an integral part, and not as a band aide fix to the present RJ45.

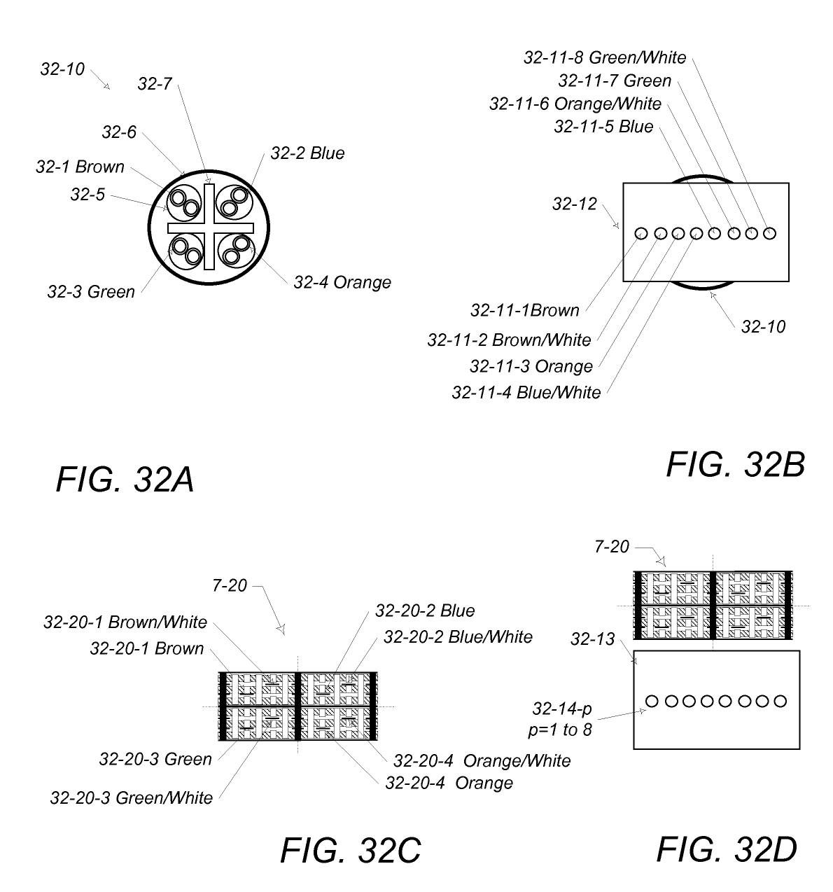

We provide here an example of how this is made possible by the PMTL technology. FIG. 32A shows the cross section of a typical twisted pair cables. In this case, in 32-10, outer shield 32-6 surrounds a collection of four twisted pairs 32-1, -2, -3, and -4, each color coded cover of Brown (and Brown and White), Blue (and Blue and White), Green (and Green and White), and Orange (and Orange and White) color coded insulators, respectively. In the best case, these twisted pairs are enclosed each in another shield 32-5, and sometimes have a spacer separator 32-7. The cable of FIG. 32A in a CAT 5e format is known to have as much as 45 nS of skew over a length of 100 m (typically this is about 25 nS according to TIA/EIA-568-BL). The printed PMTL version of this will have a much more stable skew, over 100 m length, perhaps only 10% of above, due to the manufacture and stability of the bundle, while at the same time be made fire proof and Gorilla Proof for installation and handling.

The cables 32-10 are terminated in a connector Jack, for example RJ45 connector 32-12 shown in FIG. 32B. the representative profile of cable 30-10 is shown in the back, and the wires are mapped out to the 8 linearly arranged pins of the connector 32-12, and shown from left to right, 32-11-1, 2, 3,4,5,6,7, and 8, and colors Brown, Brown/White, Orange, Blue/White, Blue, Orange/White, Green, and Green/White, respectively. This is according to one requirement for example, of 8P8C Wiring (TIA/EIA-568-A T568A).

We now demonstrate that the embodiment 7-20 of FIG. 7C can replace the cable of 32-10 of FIG. 32A, and provide same type of pin out mapping to the RJ45 type connector. As is shown in FIG. 32C, 7-20 provides 4 twisted pairs on each quadrant that can map to the same connections as a traditional twisted pairs. For example, in the first quadrant, from top left, the convention can be conductor strips 32-201, with Brown and Brown/White colors, second quadrant, 32-20-2, with Blue and Blue/White colors, and third quadrant, conductors 32-2-3, with colors Green and Green/White, and fourth quadrant, conductor strips 32-20-4 and color Orange, and Orange/White constitute a equivalent transmission line, as 32-10.

Now we demonstrate how this transmission line can map into a RJ45 type connector, in FIG. 32D. As is shown, the connector 32-13, in FIG. 32D, demonstrates connector with a linear arrangement of the pins 32-14-p, p=1 to 8, with the embodiment 7-20 above it. As the cables 7-20 can be generically manufactured in long runs, the conductors of 7-20 can be mapped into the connector 32-13 by incorporating an footprint matching section at the back of the connector to readily connects to the 7-20 footprint, and in other side provide the desired linear arrangement of FIGS. 32D and 32B, or any other desired. Thus, this makes the PMTL solution a viable alternative to future direction for the Ethernet cabling, and a backward compatible means to the installed base. Furthermore, the RJ45 will evolve into a fully and naturally shielded connector as it incorporates elements of FIG. 9-16.

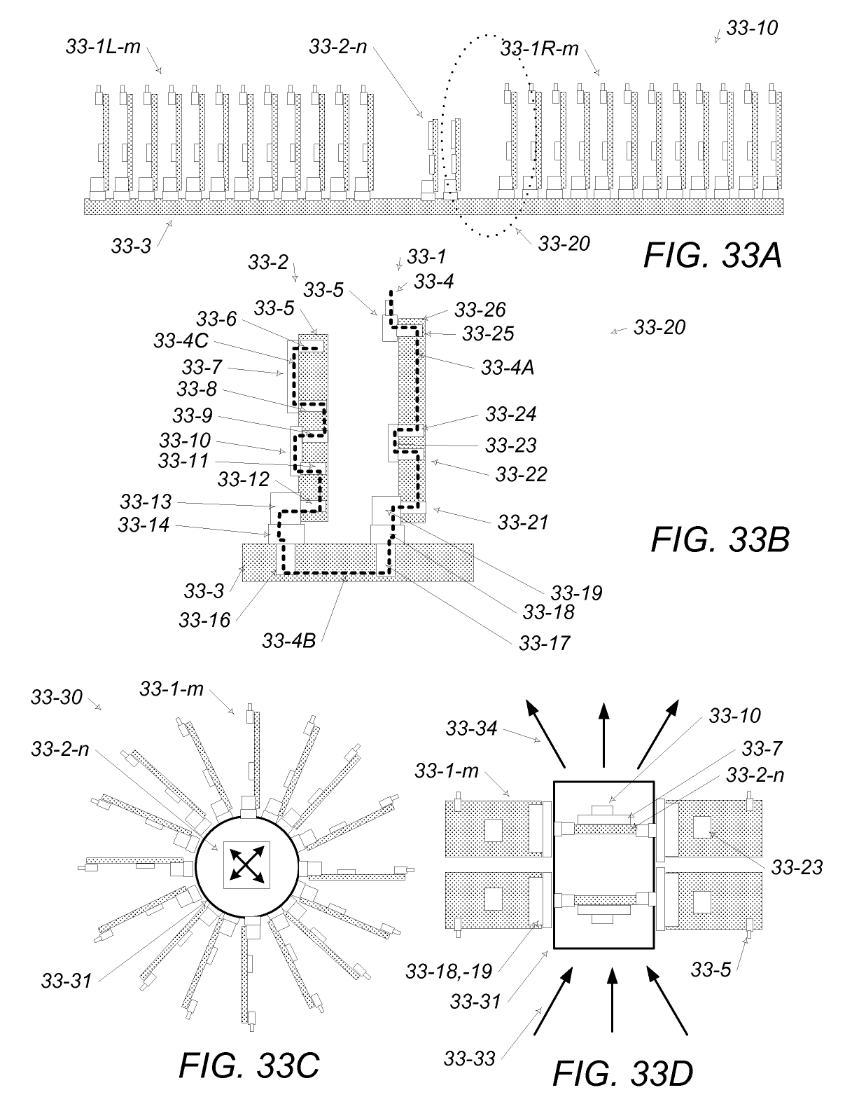

Another application of the PMTL interconnect system introduced here is in the network router improvement of exiting topologies and architectures and enabling new more advanced super router applications. One such an example is shown in FIG. 33. FIG. 33A shows a top view of typical router topology. The router 33-10 comprises of a backplane 33-3, a family of line cards 33-1L-m, and 33-1R-m, m=1, 2, 3 . . . M. on the Left and Right side, a family of central switch fabric cards designated by 33-2-n. The line card 33-1L-m, and 1R-m, receive internet traffic and connect to the switch fabric cards 33-2-n, through the backplane high speed highway lanes (such as XAUI lanes normally at 3.125 Gbps). The switch fabric 33-2-n reroute them and repackage them and send them back through the backplane to the appropriate line cards 33-1, and back to the internet FIG. 33B shows a zoomed in view of the central section of FIG. 33A to demonstrate the operation of a typical line card 33-1 and switch matrix card 33-2. This embodiment is designated as 33-20.

We first describe the operation of the switch fabric card 33-2. As is shown in FIG. 33B, from top left a daughter board 33-5 comprises of via VMTL structures 33-6 and 33-8 connecting the switch fabric chip 33-7, and a SERDES (Serialize De-Serialize) 33-10, connected to the board 33-5 by via VMTL structure 33-9 and 33-11, and the board 33-5 is then connected to the backplane 33-3 by the connector 33-13 plug and via VMTL structure 33-12, and 33-14 jack, and via VMTL structure 33-16. A signal 33-4C shown as dotted line destined for the switch matrix 33-7 or leaving it travels through the path back and forth to the back plane 33-3.

The signal 33-4B, then travels through the back plane high speed digital lanes, i.e., XAUI lanes, to the typical line card 33-1. We now describe the operation of the Line card 33-1, from top right a daughter board 33-26, signal traffic 3-4 incoming or outgoing from internet through the Fiber channel or 10GBase-T's, 33-5, gets converted to the high speed signal 33-4A, flowing from 33-5 through via VMTL structure 33-25, then to the SERDES 33-23, through the via structures 33-24 and 33-22, and then through the via VMTL structure 33-21, and connector plug 33-19, and backplane connector jack (socket) 33-18, and via VMTL structure 33-17 to the back plane 33-3, and thus connecting to the backplane traffic lanes 33-4B, i.e., like XAUI lanes.

FIG. 33B shows one typical traffic path for a pair of Line card 33-1 and switch fabric card 33-2 while FIG. 33A shows many such interactions and traffic lanes both on daughter boards and backplanes. As the number of line cards increases, the size of the back plane increases, and the relative distance and thus the latency delay between line cards and the centrally located switch fabric cards 33-2-n increases and thus the signals from the outer line cards made longer latency delays and much more weaker as the paths loss is becomes excessive. To accommodate all needed high speed interconnections, this may requires thousands of high speed lanes on the back plane, requiring larger and larger backplane to a point of diminishing return, when the high density of interconnect lanes increase the level of cross talk and excessive signal loss as well as great latency delays and timing skew and jitter limits the performance and throughput of the router. PMTL technologies introduced in this patent promise to solve these problems. For example PMTL provides at least ten times the RF bandwidth on the same FR4 backplane for the same length, while providing complete cross talk shielding. This allows the boards to become nearly ten time larger and providing larger number of Line Card, and therefore traffic, or using the SERDES and Multiplexing to further serialize the high speed lanes with more traffic thus increasing the traffic throughput from Terabit Per seconds (Tbps), to many 10's of Tpbs. For example, in a typical router with throughput of 1 Tbps, comprising of a 100 each line cards of 10 Gbps I/O traffic at 33-5, provides 100×10 Gbps=1 Tbps throughput. In order to overcome the bandwidth limits of the FR4 boards of router, each 10 Gbps is divided into four lane of XAUI with speeds of 3.125 Gbps (with overhead, with aggregate 2.5 Gbps true capacity per lane). So the backplane must house with excellent signal integrity at least 400 such XAUI lanes. As the number of the line cards increases, this number also grows to a point that the board has to be increased to mitigate crosstalk, but the loss become quickly problematic. However, using PMTL on the same FR4 backplane and also the line cards can increase the bandwidth of the FR4 XAUI lanes 3.125 Gbps, or nearly 1.5 GHz actual RF bandwidth, with RF bandwidth to excess of 15 GHz. This could easily provide means for the XAUI lanes of improved signal throughput, or sterilization of multiple XAUI lanes on a single PMTL lane. A backplane can be make longer or less crowded, as each PMTL lane can carry 10 such XAUI's in series, thus in the example above, the backplane will have only 40 XAUI lanes (instead of previous 400), to provide the same 1 Tpbs throughput, but with a router backplane of much smaller size, perhaps by a factor of 10. Or alternatively, the same size of the backplane and 400 XAUI-PMTL lanes can provide 10 Tbps traffic throughput. This process is highly scalable, as the level of PMTL bandwidth can be improved to another factor of 10, and thus provide a router with throughput of 100 Tbps, and another factor of 10, to throughput of (1 Peta=1000 Tera) 1 Pbps=1000 Tbps, or until the topology of the router of FIG. 33A becomes the limiting factor. Indeed, the published measured data of PMTL printed on Kapton has demonstrated performance from DC-50 GHz RF bandwidth, (or digital throughput of 100 Gbps), and extensive Electromagnetic simulation suggest that the performance on FR4 can easily be extended to 220 GHz, and with better quality board materials such as FR408, and others to 500 GHz, and thus with the possibility of achieving 100 Tbps throughput. Indeed, it is possible to extend the performance of such a PMTL to TEM near optical regions. Thus greatly improving the potential of copper transmission line, and providing multi 10 Gbps transmission without the use of problematic and expensive fiber optics for short range links and routers, and high speed computers, and supper computers, and data centers.

In fact, it is believed that the performance of the future computers, routers, and switches will no longer be limited by electrical parameters of copper, but by the topology, architecture, and above all by thermal issues. As the line length increase, the insertion loss roll off becomes a issue and ISI (Inter Symbol Interference) increases. In this case passive equalizers and pre-emphasis become necessary. Because PMTL uses printed circuit technologies, a integrated high pass filtering with a complementary roll up response can be designed as an integrated part of the transmission line (will be covered in a separate patent application) that can mitigate this issue. New topologies will be necessary, and one such a topology can help even solve these problems.

For all the passive interconnection elements of router of FIG. 33, we have introduced an improved high speed embodiment in this patent. Furthermore, because the PMTL can be implemented on any hard, soft, and a combination family of materials with various wideband board to board interconnection with high speed, a star router architecture can be implemented that can accommodate development of new faster computers, routers, and servers, memory banks, and data centers, etc. . . . Here we provide an example for a supper router, but other systems can be modeled after this architecture by those skilled in the art.

FIG. 33C shows a proposed supper router embodiments using a star architecture that is made possible by the used of various high speed interconnects based on the PMTL-VMTL and the corresponding teachings of this patent. Because, latency, skew, and transmission loss, and thermal issues are some of the limiting factors of high speed routers, a star topology 33-30 shown in FIG. 33C provides the central areas 33-31 where the switch fabrics 33-2-n are located, surrounded by a substantially circular arrangements of line cards 33-1-m, this way the path from each line card to the switch fabric is substantially minimal and substantially equal. A combination of various PMTL and VMTL transmission lines and its various interconnects mechanisms on hard FR4 like materials, as well as high speed flexible backplane membrane, or high speed PMLT jumper illustrated in FIGS. 22 and 24 now readily provides ample possibilities to enable this super router star architecture. The topology of 33-30 in FIG. 33C in addition to its much high speed electrical advantages also provides a natural thermal solution. This is shown in FIG. 33D in a highly simplified typical side view, that shows the central section 33-31 housing a family of switch fabric cards 33-2-n, with a stack topology of SERDES 33-10 on top of the switch fabric chip 33-7, using Through Silicon Via (TSV), This topology allows a natural air flow, either natural convection or forced, from bottom as in 33-33 and exiting from top 33-34 to cool the core of the super router. This can be achieved by a flex jumper 22-10 in FIG. 22 that can be twisted at least 90 degrees.

Line cards 33-1-m are connected around the central hub 33-31, each having a incoming/outgoing interface of optical or copper based internet connectors 33-5, and with SERDES 33-23. The topology and architecture of 33-30 is highly scalable, as the diameter of the central hub can be as large as needed to accommodate tens of 100's of lines cards 33-2-n in each row, and stacked in many tens of rows each. I.e., a 1000 of 10 Gbps line cards on each hub level, and 10 stacked level, could provide 1000×10×10=100 Tbps super router. Since this topology is easily scaled, increasing the stack by another 10 fold will provide a supper router of 1000 Tbps=1 Pbps throughput. Or alternatively, if each line card becomes 100 Gbps, a 100 of such line cards arranged in stack of 10 provides 100 Pbps throughput super router, or 1000 such 100 Gpbs line cards on stack of 10, could provide an unprecedented 1000 Pbps=1 Exa pbs (1000 Peta=1 Exa)=1 Ebps super router throughput. All of these are made possible by improving the copper interconnect using PMTL-VMTL technologies as well as adapting new router topologies and star architectures as presented in the patent FIGS. 33C and D. All these new possibilities provide new means of implementing much more advanced and more efficient routing algorithms and philosophies thus further increasing the efficiencies and throughput of new super routers. The teaching of one such a new technology has been provide in the U.S. Pat. No. 7,161,906 B2 by Dell et al, that can take advantage of the new super router architecture presented here.

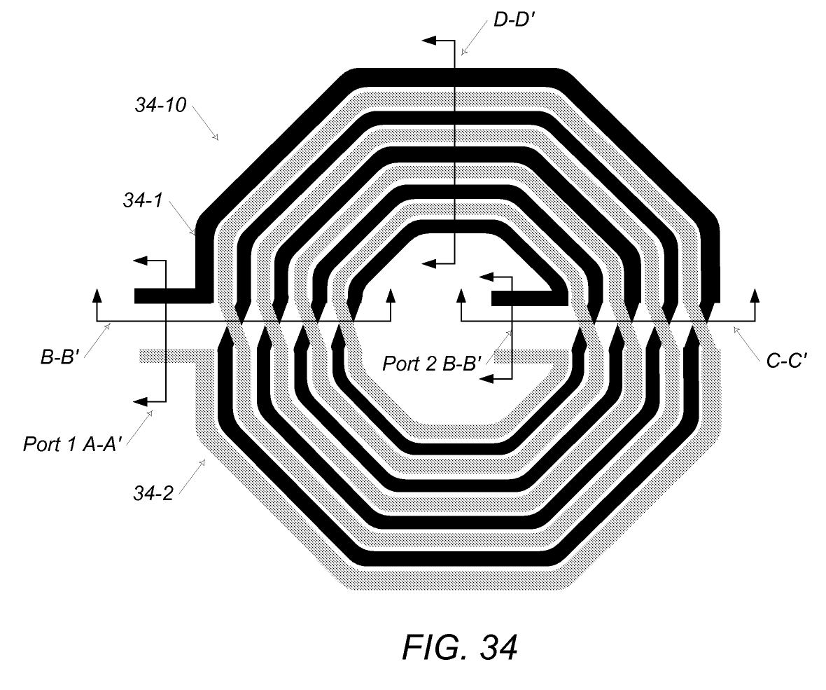

Yet, another application of the PMTL-VMTL technology is in the development of lumped inductors with high Q, and small form factors. FIG. 34 shows a typical example of at least one possible application for the PMTL technology to develop a family of inductors and transformers. Inductors are very critical elements of the network technology, as is illustrated by an article entitled “Design Considerations of Differential Inductors in CMOS Technology, by H. Y. D. Yan. Here we illustrate how PMTL technology can be used to develop balanced lumped inductors or transformer, and many other possible embodiments can be implemented from the teaching of this patent. In the configuration of FIG. 34, the spiral inductor 34-10 is comprised of two intertwined spiral traces 34-1 and 34-2 that are wound with a small gap in between each spiral. This determines the level of coupling of the two windings. The inductor is comprised of input port 1 AA′, and output port 2 at BB′, whose cross sectional cut views would resemble embodiment of 2-1 of FIG. 2A. In the present embodiment 34-10, the two spiral inductors cross over in two regions designated by a cross sectional cuts BB′ and CC′, whose cross sectional view resembles elements of crossover bridge 8-5, of FIG. 8 as shown in BB′, CC′, and DD′ in FIG. 8A, for any two spiral arm cross over. Cross sectional cuts DD′ shows a cross sectional cut of spiral inductors that resembles a variation of and a generalization of the configuration of 2-1 in FIGS. 2A and 8A. Although the embodiment of FIG. 34 shows only one possible spiral inductor configuration of PMTL, many other variations are possible that fall within the scope of this invention.

### Alternative Embodiments

Although we provided a few examples/embodiments and applications of our inventions and processes, many other variations, implementations, and applications of our technologies are possible which fall under the claims of this invention. Furthermore, some elements of the embodiments presented here will help increase the bandwidth of many popular signaling standards, such as 12C, 10GBase-T, 100GBase-T, infiniband USB, XAUI, DVI, PCIe, FC, and many others.

Some examples for the embodiments:
The method of VTCTD (Virtually Thickening Conductors, Thinning Dielectrics) of improving the performance of a transmission line by virtual thickening of the conductors and thinning the dielectrics materials, as was used in the PMTL.
The strategic use of any type of PTH (Plated Through Hole) vias, and array of NPTH (Non-PTH) to achieve conductor thickening and dielectric thinning. (VTCTD)
Different variations of the PMTL transmission lines, Broad side and edges side, and offset combination Differential pairs, Single Ended, FIG. 2-5, Twinax, Quadax etc. . . . .
Twisted Pairs PMTL transmission lines, as in FIG. 6-8
PMTL transmission line cross-over's in the same layers as in FIG. 8
Continuity Modules for cellular construction of PMTL connectors, like those of FIG. 9, for Signal Region Continuity Module, SCM, Dielectric Continuity Module (DCM) and Ground Continuity Module (GCM), substantially orthogonal to the plane of Transmission line
Connector units for Single Ended and Differential PMTL's and connector arrays.
Modular Connector Array production using the PCB processes as in FIG. 10-12.

Transition from Coaxial Transmission line to PMTL embodiments of FIG. 13.

Surface Connecting PCB footprint for PMTL-Diff (Differential) and PMTL-SE (Single Ended) using vias and other solder bumps, VMTL
PCB socket connector technology using the elements of FIGS. 9 and 11, as shown in FIG. 15A,
3D PMTL via Stack or VMTL (Vertical Micro Transmission Line) based on 3D via structures, using NPTH via thinning, and via array, of FIG. 15, 3D vertical Coaxial-like PMTL transmission line of FIG. 15D-E, and with VTCTD
Interlayer transmission line VMTL 3D via VMTL connectivity of FIGS. 15F and G. 3D via VMTL via structures for vertical inter layer stack TEM transmission line as in FIG. 15.
Alternative in-plane connectivity modules of FIG. 16, for Single Ended and Differential PMTL's (The FIG. 16 does not show the vias for clarity, but is an inherent part of it), Jack and Plugs, sockets etc. . . . (2D Arrays of these connectors)
Footprints of possible surface connectivity to PCB's, FIG. 17 VMTL to PMTL
Various possible PCB to PCB connectors of FIG. 18.
PMTL flex transmission lines arrays and connectors generalization to 2D arrays, illustrated in FIG. 19-24.
Fan out fan in 2D and 3D generalization of PMTL buses and bundles with equalization of length over and termination to 2D array connectors and connectivity to UTS, universal test sockets etc. . . . as in FIG. 25-26
Array connectivity of DUT's using wafer cards arrays as in FIG. 27-28, for DUT sockets and connectivity for testing on top of ATE's
The Reel to Reel high volume manufacturing of PMTL-VMTL transmission lines bundles as in FIG. 29
Back Plane Socket/Plug Connectivity using the PMTL in-plane connectors/arrays as illustrated in FIG. 30 for DIP PMTL-PMTL connectivity.
High Speed VITA replacement and improvement connectivity with zero Skew, as shown in FIG. 30C. using PMTL and VMTL
A PMTL base-shaped membrane package to die interconnect fan out as shown in FIG. 31 to replace and eliminate wire bonding. And provides topside die-to-die and die-to-package, interconnect, and membrane skyways for 3D packaging
Twisted pair transmission line bundles to replace current UTP and STP and connection to current RJ45 Jacks for backward compatibility and forward improvements. RJ45 integrated shielding
Further improvement of Signal Integrity of current router architecture using PMTL and VMTL the bandwidth of PMTL to serialized many high speed lanes on the daughter cards, mother cards and backplanes to improve throughput.
New Star topology super router to substantially equalized path length and shorten path loss, scalable to grow bigger or smaller with improved thermal managements as shown in FIG. 33, for possible throughput up to many 100's of Tbps.
The spiral inductor/transformer implementations using PMTL and VMTL technologies.

1. A multilayer structure for electromagnetic radiation, wave, or signal transmission line, said structure comprising:
one or more dielectric layers or sections;
one or more conducting layers or sections; and
one or more micro-chambers, sandwiched between one or more of following: said one or more dielectric layers or sections, said one or more conducting layers or sections, or both said one or more dielectric layers or sections and said one or more conducting layers or sections.

2. The multilayer structure for electromagnetic radiation, wave, or signal transmission line as recited in claim 1, wherein said one or more micro-chambers comprise one or more metals or conductors.

3. The multilayer structure for electromagnetic radiation, wave, or signal transmission line as recited in claim 1, wherein said one or more micro-chambers comprise one or more insulators.

4. The multilayer structure for electromagnetic radiation, wave, or signal transmission line as recited in claim 1, wherein said one or more micro-chambers comprise one or more dielectrics.

5. The multilayer structure for electromagnetic radiation, wave, or signal transmission line as recited in claim 1, wherein said one or more micro-chambers comprise one or more semiconductors.

6. The multilayer structure for electromagnetic radiation, wave, or signal transmission line as recited in claim 1, wherein said one or more micro-chambers comprise fattened or expanded conductor or metal.

7. The multilayer structure for electromagnetic radiation, wave, or signal transmission line as recited in claim 1, wherein said one or more micro-chambers comprise thinned or narrowed dielectric.

8. The multilayer structure for electromagnetic radiation, wave, or signal transmission line as recited in claim 1, wherein said one or more micro-chambers comprise one or more pockets of air.

9. The multilayer structure for electromagnetic radiation, wave, or signal transmission line as recited in claim 1, wherein said one or more micro-chambers comprise one or more pockets of gas.

10. The multilayer structure for electromagnetic radiation, wave, or signal transmission line as recited in claim 1, wherein said one or more micro-chambers comprise one or more pockets of liquid.

11. The multilayer structure for electromagnetic radiation, wave, or signal transmission line as recited in claim 1, wherein said one or more micro-chambers comprise one or more pockets of fluid.

12. The multilayer structure for electromagnetic radiation, wave, or signal transmission line as recited in claim 1, wherein said one or more micro-chambers comprise one or more pockets of vacuum or low pressure gas.

13. The multilayer structure for electromagnetic radiation, wave, or signal transmission line as recited in claim 1, wherein said structure comprises one or more ground layers.

14. The multilayer structure for electromagnetic radiation, wave, or signal transmission line as recited in claim 1, wherein said structure comprises one or more transmission layers.

15. The multilayer structure for electromagnetic radiation, wave, or signal transmission line as recited in claim 1, wherein said structure comprises one or more via holes or through holes.

16. The multilayer structure for electromagnetic radiation, wave, or signal transmission line as recited in claim 1, wherein said structure comprises one or more plated via holes or through holes.

17. The multilayer structure for electromagnetic radiation, wave, or signal transmission line as recited in claim 1, wherein said structure comprises one or more not-plated via holes or through holes.

18. The multilayer structure for electromagnetic radiation, wave, or signal transmission line as recited in claim 1, wherein said structure comprises one or more Vertical Micro-Transmission Lines.

19. The multilayer structure for electromagnetic radiation, wave, or signal transmission line as recited in claim 1, wherein said structure comprises one or more empty volumes filled with air, gases, or other materials.

20. The multilayer structure for electromagnetic radiation, wave, or signal transmission line as recited in claim 1, wherein said structure comprises one or more differential pair units.

21. The multilayer structure for electromagnetic radiation, wave, or signal transmission line as recited in claim 1, wherein said structure comprises one or more quad pair units.

22. The multilayer structure for electromagnetic radiation, wave, or signal transmission line as recited in claim 1, wherein said structure substantially cancels noise or increases signal-to-noise ratio.

23. The multilayer structure for electromagnetic radiation, wave, or signal transmission line as recited in claim 1, wherein said structure comprises one or more combinations, arrays, or stacks of units.

24. The multilayer structure for electromagnetic radiation, wave, or signal transmission line as recited in claim 1, wherein said structure comprises one or more zig-zag configurations or patterns.

25. The multilayer structure for electromagnetic radiation, wave, or signal transmission line as recited in claim 1, wherein said structure comprises one or more modular units.

26. The multilayer structure for electromagnetic radiation, wave, or signal transmission line as recited in claim 1, wherein said structure is matched and connected to a second structure.

27. The multilayer structure for electromagnetic radiation, wave, or signal transmission line as recited in claim 1, wherein said structure comprises one or more 3-dimensional vias.

28. The multilayer structure for electromagnetic radiation, wave, or signal transmission line as recited in claim 1, wherein said structure comprises one or more Periodic Micro-Transmission Lines.

29. The multilayer structure for electromagnetic radiation, wave, or signal transmission line as recited in claim 1, wherein said structure is a part of a transformer system.
